(19) United States
(12) Patent Application Publication
(10) Pub. No.: US 2006/0246683 A1
(43) Pub. Date: Nov. 2, 2006

(54) Integrated equipment set for forming a low K dielectric interconnect on a substrate

(75) Inventors: Judon Tony Pan, Saratoga, CA (US); Michael D. Armacost, San Jose, CA (US); Hoiman (Raymond) Hung, Cupertino, CA (US); Hongwen (Howard) Li, Palo Alto, CA (US); Arulkumar Shanmugasundram, Sunnyvale, CA (US); Moshe Sarfaty, Cupertino, CA (US); Dimitris P. Lymberopoulos, San Jose, CA (US); Mehul Naik, San Jose, CA (US)

Correspondence Address: DUGAN & DUGAN, PC, 55 SOUTH BROADWAY, TARRYTOWN, NY, 10591, US

(73) Assignee: Applied Materials, Inc.

(21) Appl. No.: 11/472,662

(22) Filed: Jun. 21, 2006

Related U.S. Application Data
(63) Continuation of application No. 10/459,194, filed on Jun. 11, 2003, now abandoned.
(60) Provisional application No. 60/387,835, filed on Jun. 11, 2002.

(51) Int. Cl. H01L 21/76

(52) U.S. Cl. 438/424

(57) ABSTRACT

A method is provided that includes (1) receiving information about a substrate processed within a low K dielectric deposition subsystem from an integrated inspection system of the low K dielectric deposition subsystem; (2) determining an etch process to perform within an etch subsystem based at least in part on the information received from the inspection system of the low K dielectric deposition subsystem; and (3) directing the etch subsystem to etch at least one low K dielectric layer on the substrate based on the etch process. Other methods, systems, apparatus, data structures and computer program products are provided.

This application is a continuation of and claims priority from U.S. patent application Ser. No. 10/459,194, filed Jun. 11, 2003, which claims priority from U.S. Provisional Patent Application Ser. No. 60/387,835, filed Jun. 11, 2002. Each of these applications is hereby incorporated by reference herein in its entirety.

### CROSS REFERENCE TO RELATED APPLICATIONS

This application is related to U.S. Provisional Patent Application Ser. No. 60/323,065, filed Sep. 18, 2001 and titled “INTEGRATED EQUIPMENT SET FOR FORMING AN INTERCONNECT ON A SUBSTRATE”, which is hereby incorporated by reference herein in its entirety.

This application also is related to U.S. Provisional Patent Application Ser. No. 60/333,901, filed Nov. 28, 2001 and titled “INTEGRATED EQUIPMENT SET FOR FORMING SHALLOW TRENCH ISOLATION REGIONS”, which is hereby incorporated by reference herein in its entirety.

### FIELD OF THE INVENTION

The present invention relates to semiconductor device manufacturing, and more specifically to an integrated equipment set for forming a low K dielectric interconnect on a substrate.

### BACKGROUND OF THE INVENTION

A typical integrated circuit contains a plurality of metal pathways that provide electrical power for powering the various semiconductor devices forming the integrated circuit, and that allow these semiconductor devices to share/exchange electrical information. Within integrated circuits, metal layers are stacked on top of one another by using intermetal or “interlayer” dielectrics that insulate the metal layers from each other.

Generally, each metal layer must form electrical contact to at least one additional metal layer. Such metal-layer-to-metal-layer electrical contact is achieved by etching a hole (i.e., a via) in the interlayer dielectric that separates the metal layers, and by filling the resulting via with a metal to create an interconnect as described further below. Metal layers typically occupy etched pathways or “lines” in the interlayer dielectric. When copper metal layers and copper interconnects are employed, because copper atoms are highly mobile in silicon dioxide and may create electrical defects in silicon, the copper metal layers and interconnect vias conventionally are encapsulated with a barrier material (e.g., to prevent copper atoms from creating leakage paths in silicon dioxide interlayers and/or defects in the silicon substrate on which the metal layers and interconnects are formed).

As is well known, an increase in device performance is typically accompanied by a decrease in device area or an increase in device density. An increase in device density requires a decrease in the via and line dimensions used to form interconnects (e.g., a larger depth-to-width ratio or a larger “aspect ratio”). Decreased via and line dimensions require tighter control over the etching process used to form each via or line, the deposition process or processes used to fill each via or line and the planarization process employed thereafter.

Another technique for improving device performance is to decrease the RC time constant associated with the metal layers employed by a semiconductor device. This may be performed, for example, by using low resistivity metal layers (e.g., copper metal layers rather than aluminum metal layers) and/or low k interlayer dielectrics (e.g., carbon doped oxide or silicon carbon interlayer dielectrics rather than silicon dioxide interlayer dielectrics). Interconnects which employ low K interlayer dielectrics are referred to herein as “low K dielectric interconnects”.

Many conventional interconnect formation techniques rely on the use of “process windows”. A process window is an estimated range of one or more parameters that typically result for a given process (e.g., an estimated range of via or line depths and/or widths that typically result for a given etch process, an estimated range of film thicknesses that typically result for a given deposition process, etc.). Accordingly, when process windows are employed, vias and lines typically are overetched to ensure that all interlayer material to be removed is removed, vias and lines typically are overfilled to ensure that the deepest or widest vias and lines are adequately filled, and substrates typically are overpolished during planarization to ensure that planarization is complete. The use of process windows thereby reduces device uniformity (due to the inherent inaccuracy of using predicted/estimated via/line dimensions, deposited film thicknesses, etc.) and decreases throughput (due to overprocessing).

To ensure that each process step used during interconnect formation (e.g., low K dielectric layer deposition, etching, barrier/seed layer deposition, electroplating, planarization, etc.) maintains its proper process window, “test” substrates may be periodically analyzed following each interconnect process step. For example, following an etch process, a test substrate may be analyzed within a stand alone metrology tool that measures via and/or line depth, width, profile, uniformity across a substrate or the like. Similarly, a stand alone metrology tool may be employed to measure deposited film thickness, and stand alone defect detection tools may be used to measure defect levels following etching, deposition and planarization. In this manner, if etched dimensions and/or deposited film thicknesses are outside of a required process window, or if too many defects result following etching, deposition and/or planarization, appropriate corrective measures may be taken so that each interconnect process (e.g., etching, deposition and/or planarization) produces results within its required process window.

The use of test substrates results in at least one major drawback. Namely, due to the time required to examine and analyze each test substrate following etching, deposition or planarization, such test wafers may only be employed periodically without significantly affecting the throughput of the various semiconductor processing tools used during interconnect formation (e.g., etching tools, deposition tools, planarization tools, etc.). Numerous substrates thereby may be processed using out of specification process windows before the out of specification process windows are identified with test substrates. High scrap costs result.

The need for more automated, direct control over semiconductor device fabrication processes has been previously recognized. For example, J. Baliga, “Advanced Process Control: Soon to be a Must”, Semiconductor International, pp. 1-10 (July 1999) discusses potential benefits of employing advanced process control (APC) during semiconductor device manufacturing. However, as this article describes, the conventional use of APC has been (1) limited to only a few areas (e.g., chemical mechanical planarization (CMP), lithography, etc.); (2) limited to relatively simple applications (e.g., CMP, lithography, etc.); and (3) employed primarily at a process level (e.g., feedback for a single process), not at a system level (e.g., not at a level that affects numerous sequential processing steps such as those employed during interconnect formation). APC has not been used at a level that affects numerous processes and also that depends on the coordination of a number of discreet subsystems and technologies. Conventional APC techniques have had little, if any, affect on overall interconnect formation strategies; and the use of test substrates and process windows during interconnect formation remains widespread.

Accordingly, a need exists for improved methods and apparatus for forming interconnects on a substrate, particularly high performance, low K dielectric interconnects.

### SUMMARY OF THE INVENTION

In a first aspect of the invention, a novel system is provided for forming a low K dielectric interconnect on a substrate. The system includes (1) a low K dielectric deposition subsystem configured to deposit one or more low K dielectric layers on a substrate, the low K dielectric deposition subsystem having an integrated inspection system configured to inspect the substrate; (2) an etch subsystem configured to receive the substrate after one or more low K dielectric layers have been deposited on the substrate and to etch the substrate to form one or more etched features in the one or more low K dielectric layers formed on the substrate, the etch subsystem having an integrated inspection system configured to inspect the substrate; and (3) a controller coupled to the low K dielectric deposition subsystem and the etch subsystem.

The controller includes computer program code configured to communicate with each subsystem and to perform the steps of (1) receiving information about a substrate processed within the low K dielectric deposition subsystem from the inspection system of the low K dielectric deposition subsystem; (2) determining an etch process to perform within the etch subsystem based at least in part on the information received from the inspection system of the low K dielectric deposition subsystem; and (3) directing the etch subsystem to etch at least one low K dielectric layer on the substrate based on the etch process. Numerous other systems, methods, computer program products and data structures also are provided. Each computer program product described herein may be carried by a medium readable by a computer (e.g., a carrier wave signal, a floppy disc, a compact disc, a DVD, a hard drive, a random access memory, etc.).

In another aspect of the invention, a system for forming a low K dielectric interconnect on a substrate is provided that includes (1) means for receiving information about a substrate processed within a low K dielectric deposition subsystem from an integrated inspection system of the low K dielectric deposition subsystem; (2) means for determining an etch process to perform within an etch subsystem based at least in part on the information received from the inspection system of the low K dielectric deposition subsystem; and (3) means for directing the etch subsystem to etch at least one low K dielectric layer on the substrate based on the etch process.

Other features and aspects of the present invention will become more fully apparent from the following detailed description, the appended claims and the accompanying drawings.

### BRIEF DESCRIPTION OF THE DRAWINGS

FIG. 1A is a schematic diagram of an inventive system for forming low K dielectric interconnects on a substrate in accordance with the present invention;

FIG. 1B illustrates an alternative embodiment for the system of FIG. 1A wherein the module controller is “distributed” among the tools of the system;

FIG. 2 is a schematic diagram of an exemplary embodiment of the module controller of FIGS. 1A and 1B;

FIG. 3 is a top plan view of an exemplary embodiment of the low K dielectric deposition tool of FIG. 1A or 1B;

FIG. 4A is a top plan view of an exemplary embodiment of the etch tool of FIG. 1A or 1B;

FIG. 4B is a top plan view of an exemplary etch and clean tool that may be employed within the inventive system of FIG. 1A or 1B;

FIG. 5 is a top plan view of an exemplary embodiment of the barrier/seed layer deposition tool of FIGS. 1A and/or 1B;

FIG. 6 is a top plan view of an exemplary embodiment of the electroplating tool of FIGS. 1A and 1B;

FIG. 7A is a top plan view of a first exemplary embodiment of the planarization tool of FIGS. 1A and 1B;

FIG. 7B is a top plan view of a second exemplary embodiment of the planarization tool of FIGS. 1A and 1B;

FIGS. 8A-P illustrate a flowchart of an exemplary process for forming low K dielectric interconnects on a substrate in accordance with the present invention;

FIGS. 9A-L illustrate cross sectional views of a semiconductor substrate during the process of FIGS. 8A-P;

FIG. 10A is a table of exemplary process parameters of a low K dielectric deposition tool that may be adjusted based on feedforward and/or feedback information in accordance with the present invention;

FIG. 10B(1) and FIG. 10B(2) are a table of exemplary process parameters of an etch tool that may be adjusted based on feedforward and/or feedback information in accordance with the present invention;

FIG. 10C is a table of exemplary process parameters of a barrier/seed layer deposition tool that may be adjusted based on feedforward and/or feedback information in accordance with the present invention;

FIG. 10D is a table of exemplary process parameters of an electroplating tool that may be adjusted based on feedforward and/or feedback information in accordance with the present invention;

FIG. 10E is a table of exemplary process parameters of a planarization tool that may be adjusted based on feedforward and/or feedback information in accordance with the present invention;

FIG. 11 is a cross-sectional view of a semiconductor substrate useful in describing a first exemplary interconnect formation process in accordance with the present invention;

FIGS. 12A-B are cross-sectional views of a semiconductor substrate useful in describing a second exemplary interconnect formation process in accordance with the present invention;

FIGS. 13A-B are cross-sectional views of a semiconductor substrate useful in describing a third exemplary interconnect formation process in accordance with the present invention; and

FIGS. 14A-C are cross-sectional views of a semiconductor substrate useful in describing a fourth exemplary interconnect formation process in accordance with the present invention.

### DETAILED DESCRIPTION

### Overview of Integrated Low K Dielectric Interconnect Manufacturing

The present invention provides integrated methods, apparatus, systems, data structures and computer program products for forming low K dielectric interconnects on a substrate. The substrate may be a semiconductor substrate (e.g., a semiconductor wafer) or any other suitable substrate such as a glass plate for flat panel displays.

In one aspect of the invention, a novel system is provided that includes a dielectric deposition subsystem and having an integrated inspection system, an etch subsystem having an integrated inspection system, a subsystem capable of depositing both a barrier layer and a seed layer (hereinafter a “barrier/seed layer deposition subsystem”) and having an integrated inspection system, an electroplating subsystem having an integrated inspection system, a planarization subsystem having an integrated inspection system and a module controller for controlling low K dielectric interconnect formation via these subsystems. Each integrated inspection system is capable of performing defect detection (e.g., to detect defect density on a surface of a substrate before and/or after a processing step) and/or metrology (e.g., to measure etch features, deposited layer thicknesses, surface planarity, etc., before and/or after a processing step).

To form a low K dielectric interconnect on a substrate, the substrate is delivered to the inventive system and is transferred to the low K dielectric deposition subsystem. Based at least in part on feedback information regarding a low K interlayer dielectric previously deposited within the low K dielectric deposition subsystem (e.g., thickness, defect density, etc., of one or more low K dielectrics that form the low K interlayer dielectric), the module controller may determine a low K dielectric deposition process (or processes) to perform within the low K dielectric deposition chamber. The module controller then directs the low K dielectric deposition subsystem to deposit one or more low K dielectric layers on the substrate so as to form a low K interlayer dielectric. For example, one or more of an oxide layer, a carbon doped oxide layer and a silicon carbon layer (with or without nitrogen or other impurities) may be deposited on the substrate within the low K dielectric deposition subsystem to form the low K interlayer dielectric.

Once the low K interlayer dielectric has been formed on the substrate, the substrate is inspected with the integrated inspection system of the low K dielectric deposition subsystem (e.g., to determine overall thickness of the low K interlayer dielectric and/or the thickness of the individual layers which form the low K interlayer dielectric, defect density, etc.) and inspection information is communicated to the module controller. The substrate then is transferred to a conventional lithography tool, and a masking layer is formed thereon and is patterned as is know in the art (e.g., to form a patterned masking layer). The substrate then is transferred to the etch subsystem.

Within the etch subsystem, the integrated inspection system of the etch subsystem may perform defect detect on the substrate (e.g., to ensure that the substrate does not have too high of a defect density) and/or metrology on the substrate (e.g., to ensure that the patterned masking layer has been properly formed/patterned as required to define interconnect regions or features in the low K interlayer dielectric following etching). Based at least in part on feedforward information about the substrate such as defect density, low K interlayer dielectric thickness, thickness of the various layers which comprise the low K interlayer dielectric or patterned masking layer density/dimension/profile, the module controller may determine an etch process to perform within the etch subsystem. The etch process also may be determined based at least in part on other information such as information received from the integrated inspection system of the etch subsystem for a substrate previously etched within the etch subsystem (e.g., feedback information such as interconnect feature density/dimensions/profile, defect density, etc., following an etch process). The module controller then directs the etch subsystem to perform the determined etch process (e.g., so as to etch the desired via and/or line features within the low K interlayer dielectric of the substrate).

Once the substrate has been etched (and the patterned masking layer has been removed as described below), the substrate is again inspected within the integrated inspection system of the etch subsystem to determine interconnect feature density and/or dimensions/profile information, defect density, etc., and this information is communicated to the module controller. The above described lithography and etch steps may need to be performed multiple times (e.g., to form lines and vias in a dual damascene structure). One or more cleaning and/or annealing steps also may be employed. Thereafter, the substrate is transferred to the barrier/seed layer deposition subsystem (e.g., after a cleaning step and annealing step as described below).

Within the barrier/seed layer deposition subsystem, the integrated inspection system of the barrier/seed layer deposition subsystem may perform defect detection on the substrate (e.g., to ensure that the substrate does not have too high of a defect density following cleaning and annealing) and/or metrology on the substrate (e.g., to ensure that the interconnect features have been properly formed/patterned and/or to determine interconnect feature density and/or dimensions/profile if not previously determined by the integrated inspection system of the etch subsystem).

Based at least in part on feedforward information about the substrate such as defect density or interconnect feature density/dimensions/profile, the module controller may determine a barrier layer deposition process and a seed layer deposition process to perform within the barrier/seed layer deposition subsystem. The barrier and/or seed layer deposition processes also may be determined based at least in part on other information such as information received from the integrated inspection system of the barrier/seed layer deposition subsystem for a substrate previously processed within the barrier/seed layer deposition subsystem (e.g., feedback information such as barrier layer thickness, seed layer thickness, defect density, etc., for a previously processed substrate). The module controller then directs the barrier/seed layer deposition subsystem to perform the determined deposition process or processes (e.g., so as to deposit a barrier layer and a seed layer on the substrate).

Once the barrier layer and the seed layer have been deposited on the substrate, the substrate is inspected within the integrated inspection system of the barrier/seed layer deposition subsystem to determine deposited layer thicknesses (e.g., the thickness of the deposited barrier layer and/or of the deposited seed layer), defect density, etc., and this information is communicated to the module controller. Thereafter, the substrate is transferred to the electroplating subsystem and a fill layer is deposited on the substrate (e.g., so as to fill remaining portions of vias and trenches to form the conductive lines and plugs of the interconnect features).

To deposit the fill layer, the module controller determines and directs the electroplating subsystem to employ an electroplating process. The electroplating process may be based at least in part on dimension and/or profile information regarding the interconnect features present on the substrate (previously measured for the substrate by the integrated inspection system of the etch or the barrier/seed layer deposition subsystem). The electroplating process also may be based at least in part on information obtained from the integrated inspection system of the electroplating subsystem for a substrate previously processed within the electroplating subsystem (e.g., information such as fill layer thickness, defect density, etc., for a previously processed substrate). The electroplating process also may be based at least in part on information gathered by the integrated inspection system of the electroplating subsystem prior to processing.

Once the fill layer has been deposited on the substrate, the substrate is inspected with the integrated inspection system of the electroplating subsystem (e.g., to determine fill layer thickness, defect density, etc.), and inspection information is communicated to the module controller. The substrate then is transferred to the planarization subsystem and is planarized.

To planarize the substrate, the module controller determines and directs the planarization subsystem to employ a planarization process that may be based at least in part on the thickness of the fill layer deposited on the substrate as obtained from the integrated inspection system of the electroplating subsystem and/or that may be based at least in part on information obtained from the integrated inspection system of the planarization subsystem for a substrate previously processed therein (e.g., information such as defect density, surface planarity following planarization, etc.) or for the incoming substrate itself. Once the substrate has been planarized, the substrate is inspected with the integrated inspection system of the planarization subsystem (e.g., to determine defect density, surface planarity, etc.), and this inspection information is communicated to the module controller.

Numerous other aspects of the invention also are provided. The module “controller” may be a single, central controller that communicates with the integrated inspection system of each subsystem, or each subsystem may include controller capabilities (e.g., the module controller may be distributed among the subsystems such that each subsystem has a controller that communicates with one or more other subsystem controllers). In at least one embodiment, each subsystem includes an embedded module controller and an automated process control module (e.g., computer program code) that may communicate with the integrated inspection system of the subsystem and with embedded module controllers of other subsystems, determine processes to perform within the subsystem based at least in part on feedback information (e.g., from the integrated inspection system of the subsystem) and/or feedforward information (e.g., from an embedded module controller of another subsystem), etc., as described in more detail below.

Because during interconnect formation, each process performed (e.g., low K dielectric layer deposition, etching, barrier/seed layer deposition, electroplating, planarization, etc.) may be based at least in part on feedforward information (e.g., patterned masking layer density, interconnect feature density/dimension/profile, defect density, deposited layer thickness, etc., for the substrate to be processed) and/or based at least in part on feedback information (e.g., defect density, interconnect feature dimensions/profile, deposited layer thickness, etc., for a substrate previously processed), the use of “estimated” process windows during low K dielectric interconnect formation may be reduced, and the accuracy and repeatability of each process step may be significantly increased. Additionally, the integrated nature of each inspection system allows substrates to be inspected without significantly affecting subsystem throughput (e.g., every substrate processed may be inspected). One or more stand alone inspection systems may be used in addition to or in place of one or more of the integrated inspection systems.

### Relevant Terminology

As used herein, an integrated inspection system refers to an inspection system that is (1) coupled to a fabrication subsystem; and (2) capable of inspecting one substrate of a batch of substrates delivered to the fabrication subsystem during at least a portion of the time that another substrate of the batch of substrates is processed within the fabrication subsystem. A fabrication subsystem may include any known semiconductor device fabrication tool, system or subsystem such as an etch tool, a deposition tool, a cleaning tool, an oxidation tool, a planarization tool or the like. A stand alone inspection system refers to an inspection system that is (1) not coupled to a fabrication subsystem; and/or (2) incapable of inspecting one substrate of a batch of substrates delivered to the fabrication subsystem during at least a portion of the time that another substrate of the batch of substrates is processed within the fabrication subsystem.

An inspection system refers to a system capable of performing defect detection or metrology. Defect detection refers to the detection, identification and/or classification of defects, contaminants, flaws, imperfections, deficiencies or the like. Metrology refers to the determination of one or more material or process parameters such as thickness, composition, index of refraction, atomic structure, mechanical properties, electrical properties, dimension, profile, gas pressure, process temperature, gas flow rates, pump rate or the like.

Determining may include selecting, calculating, computing, defining, delineating, measuring or the like. Directing may include applying, initiating, controlling, managing, assisting or the like. Configured to or adapted to may include formed to, designed to, selected to, constructed to, manufactured to, programmed to or the like. Communication may include one or two way communication, polling, or the like. Feedback information refers to information regarding a substrate (e.g., defect density, material properties such as trench depth, trench width, trench profile, thickness, etc.) that is relevant to at least the processing of a subsequent substrate. Feedforward information refers to information regarding a substrate that is relevant to at least the subsequent processing of the same substrate.

### System Apparatus Overview

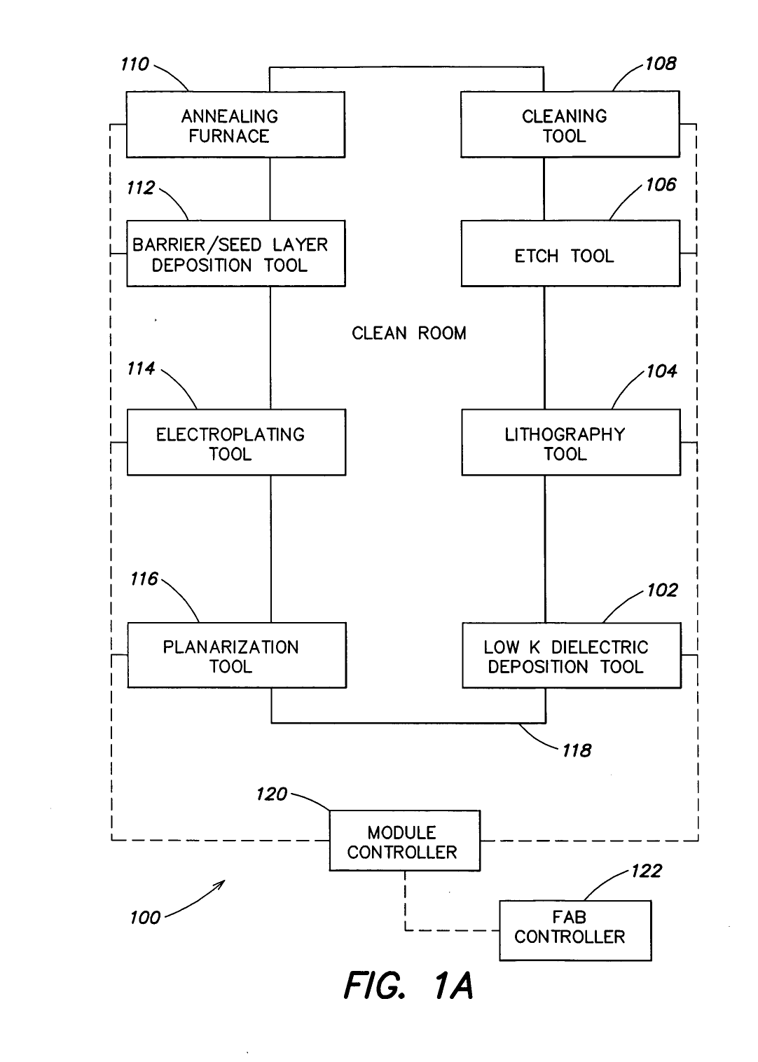

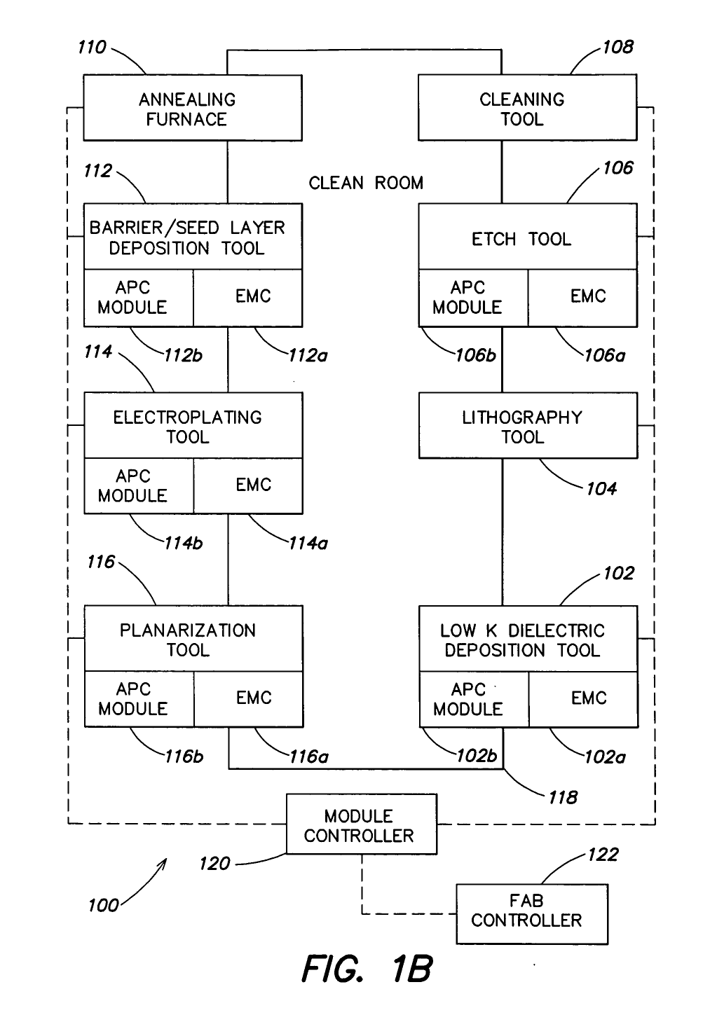

FIG. 1A is a schematic diagram of an inventive system 100 for forming low K dielectric interconnects on a substrate in accordance with the present invention. With reference to FIG. 1A, the inventive system 100 includes a low K dielectric deposition subsystem (e.g., low K dielectric deposition tool 102), a lithography tool 104, an etch subsystem (e.g., etch tool 106), a cleaning tool 108, an annealing furnace 110, a barrier/seed layer deposition subsystem (e.g., barrier/seed layer deposition tool 112), an electroplating subsystem (e.g., electroplating tool 114), and a planarization subsystem (e.g., planarization tool 116) each located at least partially within a clean room 118. Each tool 102 through 116 is in communication with a module controller 120 which is in turn in communication with a fabrication (FAB) host/controller (referred to as FAB controller 122), both described in more detail below. One or more of the tools 102-116 also may be in communication with FAB controller 122. More than one module or FAB controller also may be employed, as may additional/redundant processing tools (e.g., additional/redundant low K dielectric deposition tools, lithography tools, etch tools, cleaning tools, annealing furnaces, barrier/seed layer deposition tools, electroplating tools, and planarization tools).

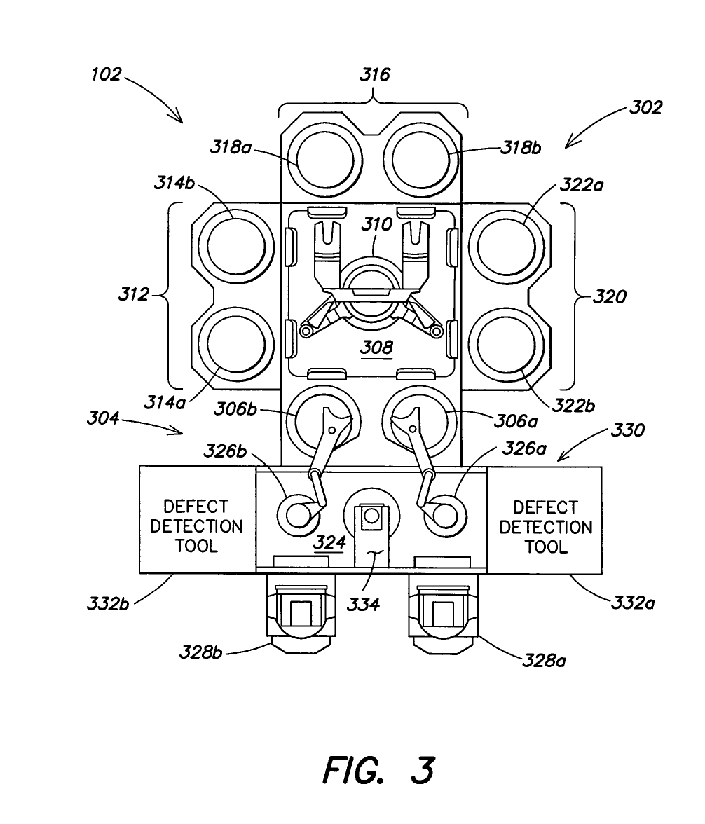

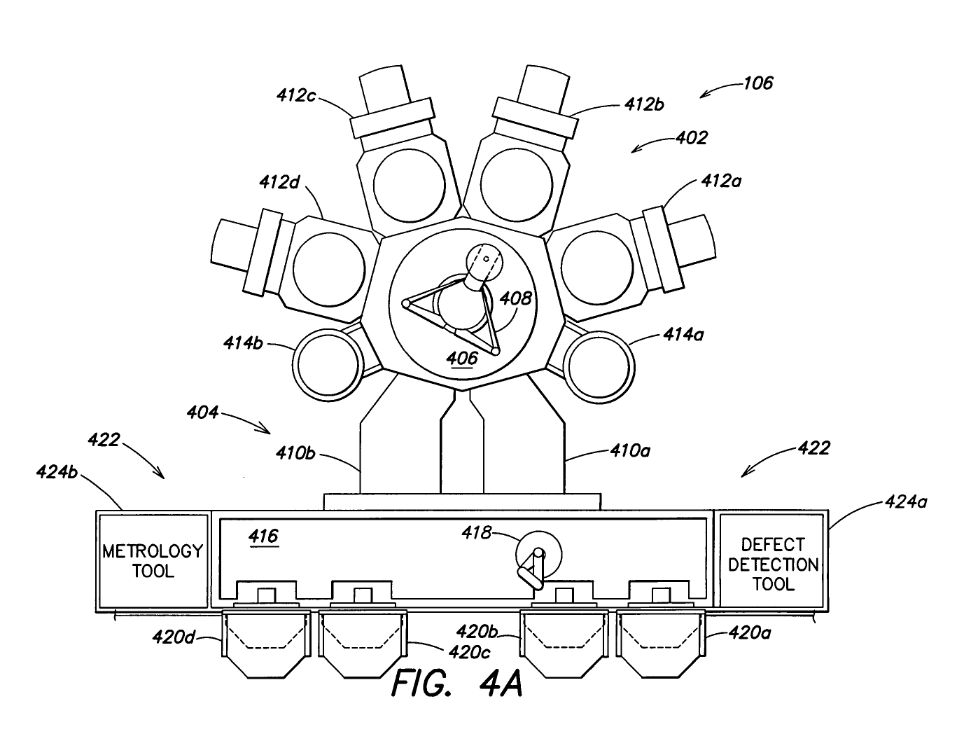

The low K dielectric deposition tool 102 may comprise any apparatus capable of depositing low K dielectric materials on a substrate and that includes an integrated inspection system for inspecting substrates processed within the low K dielectric deposition tool 102. One exemplary embodiment of the low K dielectric deposition tool 102 is described below with reference to FIG. 3.

The lithography tool 104 may comprise any apparatus capable of forming a patterned masking layer used to define vias, lines or other interconnect features during low K dielectric interconnect formation on a substrate. For example, the lithography tool 104 may include an FSI P2500 system manufactured by FSI International, Inc. for depositing an anti-reflection coating (such as a bottom anti-reflection coating (BARC) layer) and/or a photoresist layer, a DNS-80B system manufactured by Dai Nippon Screen for forming a uniform photoresist layer over the surface of a substrate, an ASML-5500/90 photoresist exposure system manufactured by ASM Lithography Inc. for exposing a photoresist layer to a desired mask pattern, and a DNS system manufactured by Dai Nippon Screen for developing the exposed photoresist layer (thereby forming the desired patterned masking layer). Such lithography tools are well known in the art; and any other conventional lithography tool may be similarly employed.

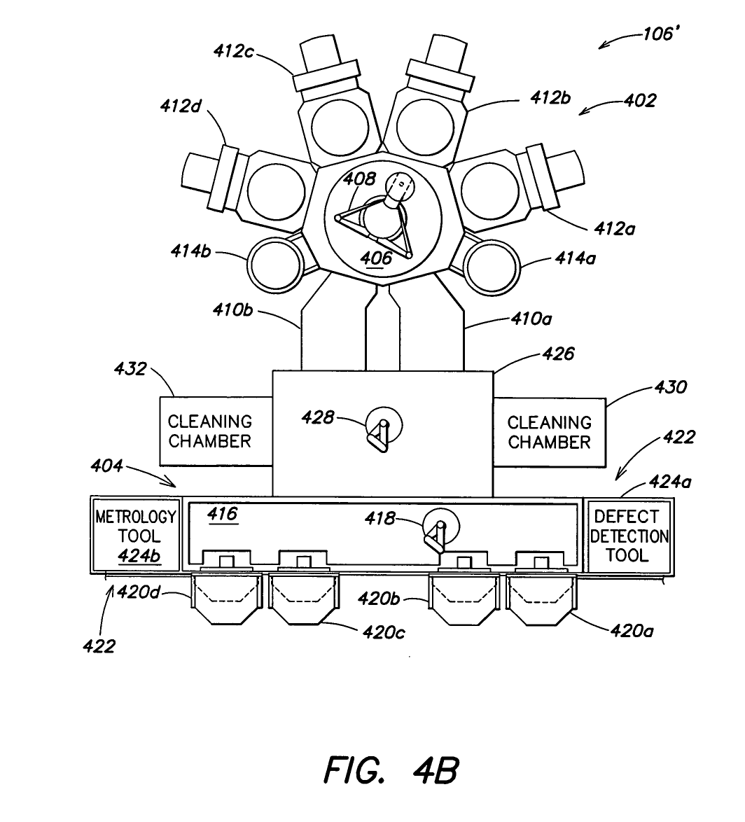

The etch tool 106 may comprise any apparatus capable of etching low K dielectric materials deposited within the low K dielectric deposition tool 102, and that includes an integrated inspection system for inspecting substrates etched within the etch tool 106. Exemplary embodiments of the etch tool 106 are described below with reference to FIGS. 4A and 4B.

The cleaning tool 108 may comprise any conventional apparatus for cleaning a substrate such as a wet chemical cleaning station that employs appropriate solvents and/or other chemicals, deionized (DI) water rinsing, Marangoni drying, megasonic techniques and/or any combination thereof to clean a single substrate or a batch of substrates. For example, the cleaning tool 108 may comprise a WPS/AKRION wet bench manufactured by Akrion. Any other conventional cleaning tool may be similarly employed.

The annealing furnace 110 may comprise any conventional apparatus for annealing a substrate. For example, the annealing furnace 110 may comprise a Canary furnace manufactured by Canary. Any other conventional annealing system may be similarly employed.

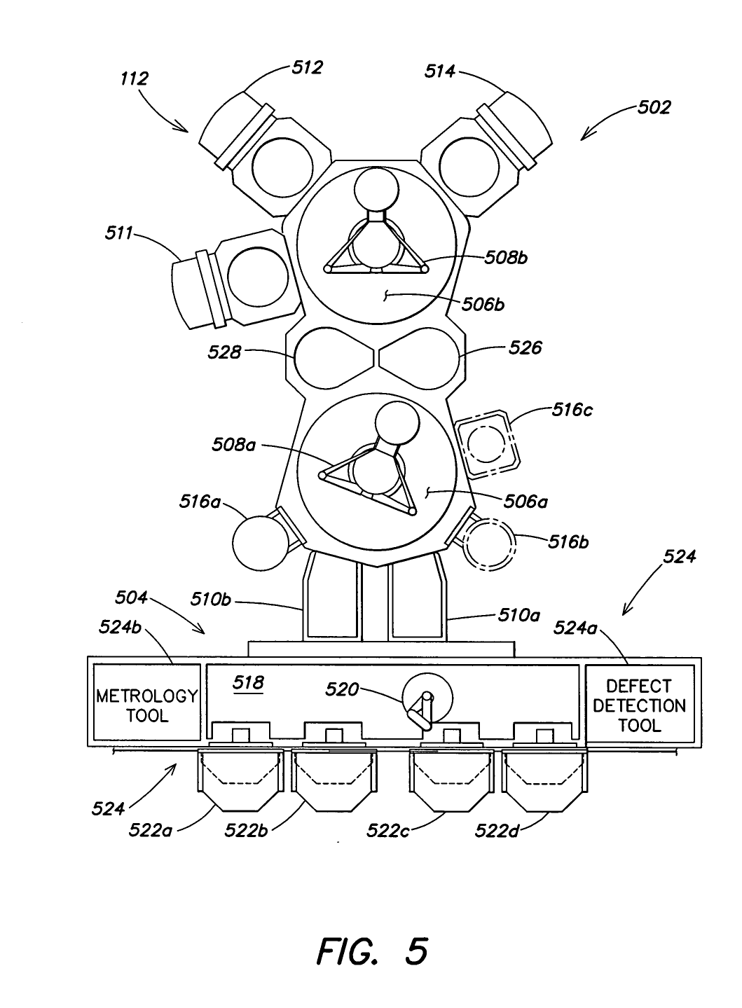

The barrier/seed layer deposition tool 112 may comprise any apparatus capable of depositing a barrier layer and a seed layer on a substrate and that includes an integrated inspection system for inspecting substrates processed within the barrier/seed layer deposition tool 112. One exemplary embodiment of the barrier/seed layer deposition tool 112 is described below with reference to FIG. 5.

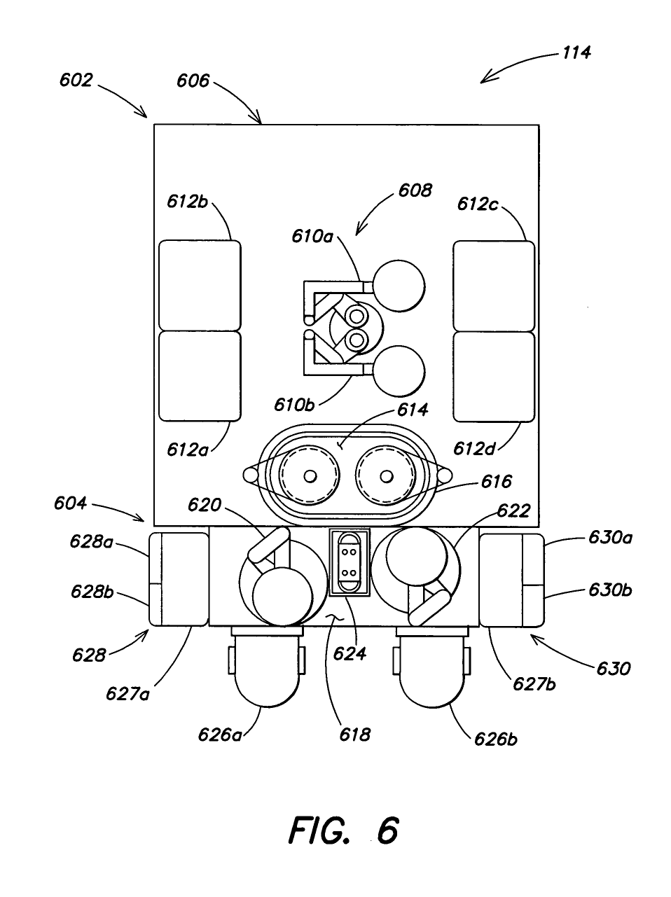

The electroplating tool 114 may comprise any apparatus capable of depositing a filler layer (e.g., copper or some other metal) within an innerconnect feature of a substrate and that includes an integrated inspection system for inspecting substrates processed within the electroplating tool 114. One exemplary embodiment of the electroplating tool 114 is described below with reference to FIG. 6.

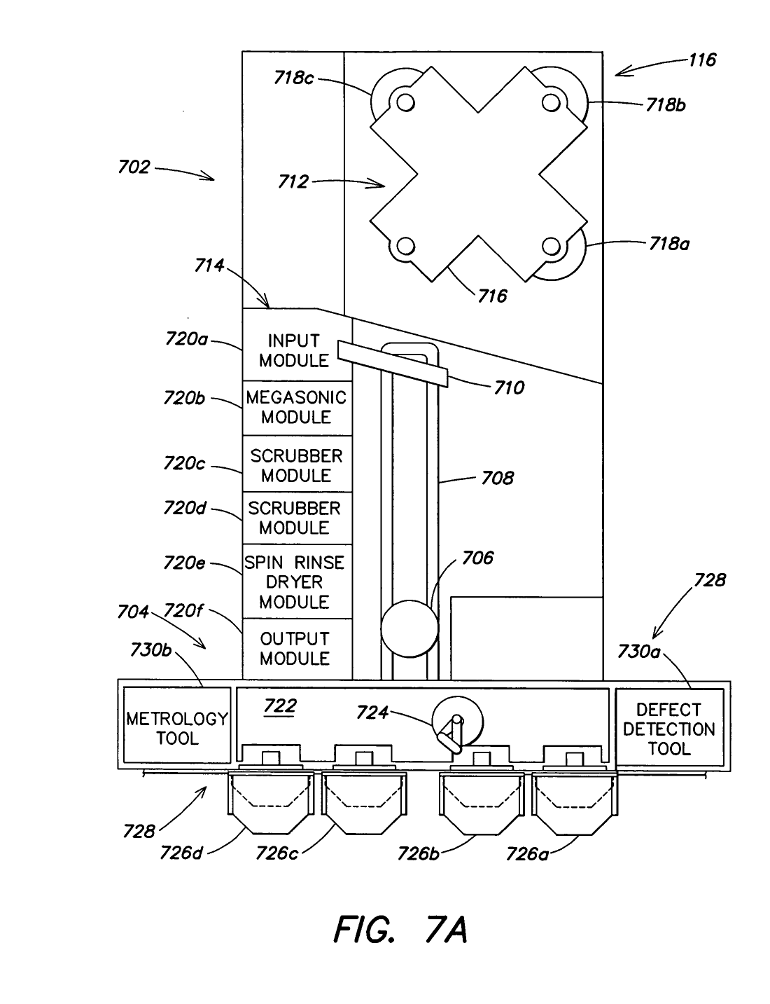

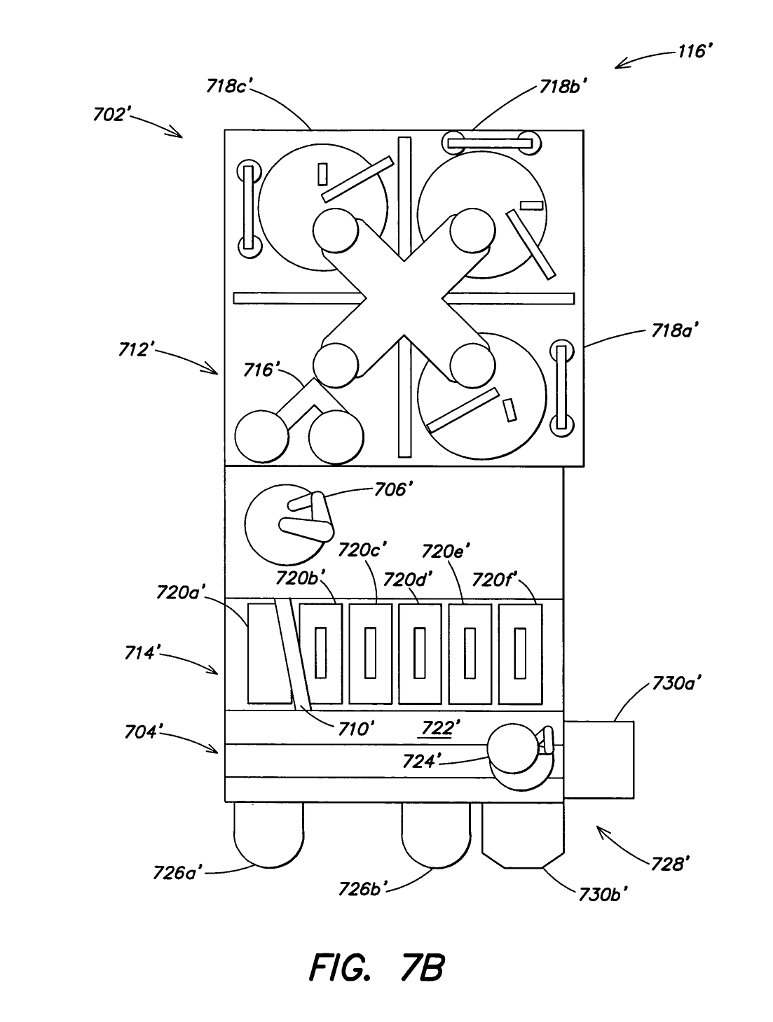

The planarization tool 116 may comprise any apparatus capable of planarizing a substrate following deposition of a filler layer on the substrate via the electroplating tool 114 and that includes an integrated inspection system for inspecting substrates processed within the planarization tool 116. Exemplary embodiments of the planarization tool 116 are described below with reference to FIGS. 7A and 7B.

The clean room 118 may comprise any suitable clean room facility such as a class one clean room. The tools 102-116 need not be located within the same clean room. For example, because a planarization tool may be a significant contamination source (e.g., due to the nature of chemical mechanical polishing), it may be preferable to employ a separate clean room for interfacing with the planarization tool 116. Substrates may be transferred between the two clean rooms via any conventional mechanism (e.g., via a technician, a conveyor system, an automated guided vehicle, etc.). Such clean rooms may be of different classes.

### System Module Controller and Programming

The FAB controller 122 may comprise any conventional fabrication controller, fabrication host, or manufacturing execution system (MES) capable of administering process flow among a plurality of processing tools (as is known in the art), but that is configured to communicate with the module controller 120 for receiving information therefrom (as described further below). The FAB controller 122, for example, may monitor wafer lots or lot numbers, work in progress, equipment quality, module quality, perform wafer/lot dispatching and document management, etc., and may be implemented as hardware, software or a combination thereof.

Note that in the embodiment of FIG. 1A, the module controller 120 is illustrated as a “central” controller that may communicate with at least the tools 102, 106 and 112-116 (e.g., with the integrated inspection system of each tool) to receive feedforward and feedback information, to determine appropriate processes to perform within each tool based on the feedforward and/or feedback information, to direct each tool to perform a process, etc., as described below. FIG. 1B illustrates an alternative embodiment for the system 100 wherein the module controller 120 is “distributed” among the tools 102, 106 and 112-116. That is, each of the tools 102, 106 and 112-116 includes an embedded module controller (EMC) 102a, 106a and 112a-116a, respectively, and an automated process control (APC) module 102b, 106b and 112b-116b, respectively. In at least one embodiment of the invention, the EMC's 102a, 106a and 112a-116a communicate with the module controller 120 to provide feedforward and/or feedback information to the module controller 120, to receive processes from the module controller 120, etc. The EMC's 102a, 106a and 112a-116a and the APC modules 102b, 106b and 112b-116b are described further below.

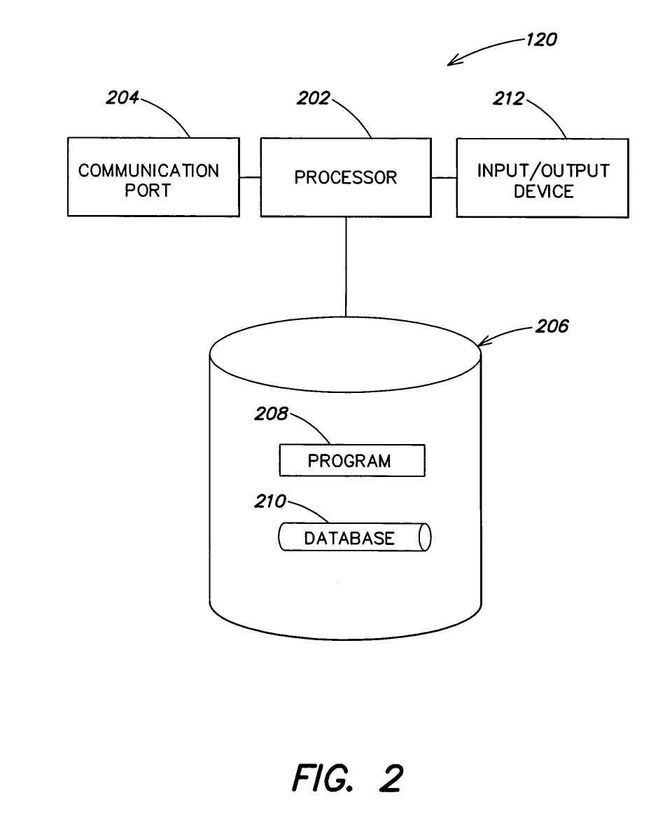

FIG. 2 is a schematic diagram of an exemplary embodiment of the module controller 120 of FIGS. 1A and/or 1B. The module controller 120 may be implemented as a system controller, as a dedicated hardware circuit, as an appropriately programmed general purpose computer, or as any other equivalent electronic, mechanical or electromechanical device.

With reference to FIG. 2 the module controller 120 comprises a processor 202, such as one or more conventional microprocessors (e.g., one or more Intel® Pentium® processors). The processor 202 is in communication with a communication port 204 through which the processor 202 communicates with other devices (e.g., with tools 102-116, with the EMC's 102a, 106a and 112a-116a, with the FAB controller 122 and/or with any other relevant device). The communication port 204 may include multiple communication channels for simultaneous communication with, for example, the low K dielectric deposition tool 102, the etch tool 106, the barrier/seed layer deposition tool 112, the electroplating tool 114, the planarization tool 116, the EMC's 102a, 106a and 112a-116a, the FAB controller 122 and/or any other relevant device (e.g., the lithography tool 104, the cleaning tool 108, the annealing furnace 110, etc.).

Those skilled in the art will understand that devices in communication with each other need only be “capable of” communicating with each other and need not be continually transmitting data to or receiving data from each other. On the contrary, such devices need only transmit data to or receive data from each other as necessary, and may actually refrain from exchanging data most the time. Further, devices may be in communication even though steps may be required to establish a communication link.

The processor 202 also is in communication with a data storage device 206. The data storage device 206 may comprise an appropriate combination of magnetic, optical and/or semiconductor memory, and may include, for example, random access memory (RAM), read only memory (ROM), a compact disk, a floppy disk, a DVD, a hard disk, or any other storage medium. The processor 202 and the data storage device 206 each may be, for example, located entirely within a single computer or other computing device, or connected to each other by a communication medium, such as a serial port cable, a telephone line or a radio frequency transceiver. Alternatively, the module controller 120 may comprise one or more computers that are connected to a remote server computer (not shown).

In the exemplary embodiment of the module controller 120 shown in FIG. 2, the data storage device 206 may store, for example, (i) a program 208 (e.g., computer program code and/or a computer program product) adapted to direct the processor 202 in accordance with the present invention, and particularly in accordance with one or more of the processes described in detail below; and (ii) a database 210 adapted to store various information employed by the module controller 120 such as process recipes for one or more of the tools 102-116, algorithms for controlling the operation of one or more of the tools 102-116 based on feedforward and/or feedback information as described further below, and/or any other relevant information (e.g. system status, processing conditions, process models, substrate history, metrology and/or defect data for each substrate, etc.). Note that rather than employing a database 210 to store process recipes, algorithms or the like, such information may be hard coded in the program 208.

The program 208 may be stored in a compressed, an uncompiled and/or an encrypted format, and may include computer program code that allows the module controller 120 to:
1. determine a low K dielectric deposition process to perform on a substrate within the low K dielectric deposition tool 102 (e.g., based on information about a substrate previously processed within the low K dielectric deposition tool 102);
2. direct the low K dielectric deposition tool 102 to deposit a low K dielectric layer on the substrate based on the low K dielectric deposition process;
3. receive information about the deposited low K dielectric layer from an integrated inspection system of the low K dielectric deposition tool 102;
4. determine an etch process to perform on a substrate within the etch tool 106 (e.g., based on information about the substrate such as masking layer pattern density/dimensions/profile, thickness of the low K interlayer dielectric deposited on the substrate within the low K dielectric deposition tool 102, etc., based on information about a substrate previously processed within the etch tool 106, etc.);
5. direct the etch tool 106 to etch the substrate based on the etch process;
6. receive information about the etched substrate from an integrated inspection system of the etch tool 106;
7. determine a cleaning process to perform on a substrate within the cleaning tool 108;
8. direct the cleaning tool 108 to clean the substrate based on the cleaning process;
9. determine an annealing process to perform on a substrate within the annealing furnace 110;
10. direct the annealing furnace to anneal the substrate based on the annealing process;
11. determine a barrier layer deposition process to perform on a substrate within the barrier/seed layer deposition tool 112 (e.g., based on information about the substrate such as interconnect feature density, dimensions and/or profile, based on information about a substrate previously processed within the barrier/seed layer deposition tool 112, etc.);
12. direct the barrier/seed layer deposition tool 112 to deposit a barrier layer on the substrate based on the barrier layer deposition process;
13. receive information about the deposited barrier layer from an integrated inspection system of the barrier/seed layer deposition tool 112;
14. determine a seed layer deposition process to perform on a substrate within the barrier/seed layer deposition tool 112 (e.g., based on information about the substrate such as interconnect feature density, dimensions and/or profile, based on information about a substrate previously processed within the barrier/seed layer deposition tool 112, etc.);
15. direct the barrier/seed layer deposition tool 112 to deposit a seed layer on the substrate based on the seed layer deposition process;
16. receive information about the deposited seed layer from an integrated inspection system of the barrier/seed layer deposition tool 112;
17. determine an electroplating process to perform on a substrate within the electroplating tool 114 (e.g., based on information received from the inspection system of the barrier/seed layer deposition tool 112 about interconnect features of the substrate and/or a barrier layer and/or a seed layer deposited on the substrate, based on information regarding a substrate previously processed within the electroplating tool 114, etc.);
18. direct the electroplating tool 114 to deposit a fill layer on the substrate based on the electroplating process (e.g., to fill the interconnect features of the substrate);
19. receive information about the fill layer deposited on the substrate from an integrated inspection system of the electroplating tool 114;
20. determine a planarization process to perform on a substrate within the planarization tool 116 (e.g., based on information received from the inspection system of the electroplating tool 114 about a deposited fill layer, based on information obtained regarding a substrate previously processed within the planarization tool 116, etc.);
21. direct the planarization tool 116 to planarize the substrate based on the planarization process; and/or
22. receive information from an integrated inspection system of the planarization tool 116 regarding the substrate.
   Numerous additional functions and/or processes may be performed via the module controller 120 as described further below. The module controller 120 may include any peripheral devices (e.g., keyboards, computer displays, pointing devices, etc., represented generally as input/output device 212) required to implement the above functionality.

Note that instructions of the program 208 may be read into a main memory (not shown) of the processor 202 from a computer readable medium other than the data storage device 206 such as from a ROM or from a RAM. While execution of sequences of instructions in the program 208 causes the processor 202 to perform the process steps described herein, hardwired circuitry may be used in place of, or in combination with, software instructions for implementation of the processes of the present invention. Thus, embodiments of the present invention are not limited to any specific combination of hardware and software. The EMC's 102a, 106a and 112a-116a and/or the APC modules 102b, 106b and 112b-116b may be configured similarly to the module controller 120.

### Low K Dielectric Deposition Subsystem

FIG. 3 is a top plan view of an exemplary embodiment of the low K dielectric deposition tool 102 of FIG. 1A or 1B. With reference to FIG. 3, the low K dielectric deposition tool 102 comprises a processing tool 302 coupled to a factory interface 304 via loadlocks 306a, 306b. The processing tool 302 includes a transfer chamber 308 which houses a dual blade substrate handler 310. The transfer chamber 308 is coupled to loadlocks 306a, 306b, a first set 312 of low K dielectric deposition chambers 314a, 314b, a second set 316 of low K dielectric deposition chambers 318a, 318b and a third set 320 of anti-reflection coating deposition chambers 322a, 322b. Fewer or more low K dielectric deposition chambers and/or anti-reflection coating deposition chambers may be employed, and the module controller 120 may communicate with and/or control the processes performed within each chamber.

Loadlock chambers 306a-b may comprise any conventional loadlock chambers capable of transferring substrates from the factory interface 304 to the transfer chamber 308. The low K dielectric deposition chambers 314a-b, 318a-b may comprise any conventional processing chambers capable of depositing low K dielectrics on a substrate. The anti-reflection coating deposition chambers 322a-b, if employed, may include any conventional processing chambers capable of deposition anti-reflection coatings on a substrate (e.g., for lithographic purposes). In at least one embodiment of the invention, the processing tool 302 is a Producer® low K dielectric deposition tool (based on a Producer™ platform) manufactured by Applied Materials, Inc. Any other low K dielectric deposition system may be similarly employed.

The factory interface 304 includes a buffer chamber 324 which houses a first substrate handler 326a and a second substrate handler 326b and which is coupled to a plurality of loadports 328a-b. It will be understood that in general, any number of substrate handlers may be located within the buffer chamber 324, and that any number of loadports may be coupled to the buffer chamber 324.

### Integrated Inspection for Low K Dielectric Deposition Subsystem

As shown in FIG. 3, the low K dielectric deposition tool 102 includes an integrated inspection system 330. In the exemplary embodiment of FIG. 3, the integrated inspection system 330 includes one or more defect detection tools 332a, 332b and a metrology tool 334 coupled to and located within, respectively, the buffer chamber 324 of the factory interface 304. Alternatively, the integrated inspection system 330 may include only one of the defect detection tools 332a, 332b, or more defect detection tools and/or the metrology tools. One or more of the defect detection tools 332a, 332b and the metrology tool 334 may be coupled to the processing tool 302 rather than to the factory interface 304 (e.g., by coupling the defect detection tools 332a, 332b and/or the metrology tool 334 adjacent the loadlocks 306a, 306b).

### Defect Detection for Low K Dielectric Deposition Subsystem

The defect detection tools 332a, 332b may comprise any conventional defect detection tools capable of detecting and/or characterizing defects on a surface of a substrate. In at least one embodiment of the invention, the defect detection tools 332a, 332b comprise the Excite™ or IPM™ defect detection tool manufactured by Applied Materials, Inc. and described in U.S. patent application Ser. No. 09/110,870, filed Jul. 7, 1998 and titled “A PIXEL BASED MACHINE FOR PATTERNED WAFERS”, which is hereby incorporated by reference herein in its entirety. The defect detection tools 332a, 332b may, for example, merely provide a measure of defect density on a substrate surface or may provide detailed information about any detected defects such as defect characterization and/or classification information. The defect detection tools 332a, 332b may provide such information to the module controller 120 (and/or to the EMC 106a of the system of FIG. 1B).

### Metrology for Low K Dielectric Deposition Subsystem

The metrology tool 334 may comprise any conventional metrology tool capable of measuring the thickness, thickness uniformity, refractive index, other film properties, or other relevant information for one or more low K dielectric layers. In at least one embodiment of the invention, the metrology tool 334 comprises a reflectometry-based thickness measurement tool such as a NanoSpec 9000 or 9000B measurement tool manufactured by Nanometrics. Other metrology tools also may be employed.

The metrology tool 334 also may be configured to inspect a substrate after processing within any of the sets 312, 316 and 320 of processing chambers (e.g., by performing metrology on each new layer formed within the processing tool 302), or after processing has been completed within all sets 312, 316 and 320 of processing chambers (e.g., by performing metrology on the composite low K interlayer dielectric formed within the processing tool 302).

### Operation of Low K Dielectric Deposition Subsystem

In operation, two cassettes or “carriers” of substrates are delivered to the factory interface 304 of the low K dielectric deposition tool 102. In particular, the substrate carriers are delivered to the loadports 328a-b. Each loadport 328a-b may or may not be configured with pod opening capability for opening sealed substrate carriers. Once the substrate carriers have been loaded into the appropriate loadport 328a-b of the factory interface 304, the first substrate handler 326a retrieves a substrate from the substrate carrier loaded into the loadport 328a and transfers the substrate to the first loadlock 306a. The second substrate handler 326b also retrieves a substrate from the substrate carrier loaded into the loadport 328b and transfers the substrate to the second loadlock 306b.

Thereafter the substrate handler 310 of the processing tool 302 retrieves the substrate from the first loadlock 306a and the substrate from the second loadlock 306b and transfers the substrates to the (first) low K dielectric deposition chambers 314a, 314b, respectively. A first low K dielectric layer (e.g., silicon carbide with or without impurity doping) is then deposited on each substrate within the low K dielectric deposition chambers 314a, 314b (e.g., in accordance with one or more of the inventive processes described below).

Following deposition within the low K dielectric deposition chambers 314a, 314b, the substrates are transferred (via the substrate handler 310) to the (second) low K dielectric deposition chambers 318a, 318b, respectively. A second low K dielectric layer (e.g., carbon doped oxide) is then deposited on each substrate within the low K dielectric deposition chambers 318a, 318b (e.g., in accordance with one or more of the inventive processes described below).

Following deposition within the low K dielectric deposition chambers 318a, 318b, the substrates are transferred (via the substrate handler 310) to the anti-reflective coating deposition chambers 322a, 322b, respectively (if employed). An anti-reflective coating (e.g., silicon oxynitride) is then deposited on each substrate within the anti-reflective coating deposition chambers 322a, 322b by any conventional deposition technique.

Thereafter, the substrates are transferred to first and second loadlocks 306a, 306b, respectively. The first substrate handler 326a of the factory interface 304 retrieves the substrate from the first loadlock 306a and transfers the substrate to one of the defect detection tool 332a and the metrology tool 334. The second substrate handler 326a of the factory interface 304 retrieves the substrate from the second loadlock 306b and transfers the substrate to one of the defect detection tool 332b and the metrology tool 334. Assuming each substrate is first transferred to a defect detection tool, the defect detection tool 332a performs defect detection on the substrate it receives from the first loadlock 306a (e.g., to determine the defect density on the surface of the substrate, identify or otherwise characterize defects on the surface of the substrate, etc.) and communicates information regarding the results of the defect detection to the module controller 120 (and/or to the EMC 102a in the system of FIG. 1B). The defect detection tool 332b similarly performs defect detection on the substrate it receives from the second loadlock 306b (e.g., to determine the defect density on the surface of the substrate, identify or otherwise characterize defects on the surface of the substrate, etc.) and communicates information regarding the results of the defect detection to the module controller 120 (and/or to the EMC 102a in the system of FIG. 1B). Each substrate is then inspected with the metrology tool 334 (e.g., after transfer from the defect detection tool 332a, 332b to the metrology tool 334 via the substrate handler 326a, 326b). As stated, only one defect detection tool need be employed, and one substrate may be inspected by one of the defect detection tools 332a, 332b at the same time the other substrate is inspected via the metrology tool 334.

The metrology tool 334 analyzes the substrate to determine such information as the thickness, thickness uniformity, refractive index, other film properties or other relevant information for one or more low K dielectric layers deposited within the processing tool 302. The metrology tool 334 similarly may determine such information for any anti-reflection coating formed within the processing tool 302. The metrology tool 334 provides this information to the module controller 120 (and/or to the EMC 102a in the system of FIG. 1B). The substrate handler 326a or 326b of the factory interface 304 retrieves each substrate inspected by the metrology tool 334 and returns the substrate to a substrate carrier (located within one of the loadports 328a-b).

It will be understood that more than two substrates may be processed at a time within the low K dielectric deposition tool 102. For example, while two substrates are being processed within the first set 312 of low K dielectric deposition chambers 314a, 314b, up to four other substrates may be simultaneously processed within the second set 316 of low K dielectric deposition chambers 318a, 318b and the third set 320 of anti-reflection coating deposition chambers 322a, 322b. Likewise, substrates may be processed within the chambers 314a-322b while defect detection is performed within the defect detection tools 332a, 332b or while metrology is performed within the metrology tool 334 on other substrates. In this manner, because of the integrated nature of the defect detection tools 332a, 332b and the metrology tool 334, defect detection measurements and/or metrology measurements have little affect on the throughput of the low K dielectric deposition tool 102. Defect detection and/or metrology therefore may be performed on every substrate processed within the low K dielectric deposition tool 102 (if desired). Further, substrates may be inspected via the defect detection tools 332a, 332b and/or the metrology tool 334 before being processed within one of the chambers 314a-332b.

Either the module controller 120 or the FAB controller 122 may comprise computer program code for performing the various substrate transfer operations described above. The EMC 102a also may comprise such computer program code.

### Etch Subsystem

FIG. 4A is a top plan view of an exemplary embodiment of the etch tool 106 of FIG. 1A or 1B. With reference to FIG. 4A, the etch tool 106 comprises a processing tool 402 coupled to a factory interface 404. The processing tool 402 includes a transfer chamber 406 which houses a first substrate handler 408. The transfer chamber 406 is coupled to a first loadlock 410a, a second loadlock 410b, a first etch chamber 412a, a second etch chamber 412b, a third etch chamber 412c, a fourth etch chamber 412d, a first auxiliary processing chamber 414a and a second auxiliary processing chamber 414b. Fewer or more etch chambers or auxiliary processing chambers may be employed, and the module controller 120 may communicate with and/or control the processes performed within each chamber.

Loadlock chambers 410a-b may comprise any conventional loadlock chambers capable of transferring substrates from the factory interface 404 to the transfer chamber 406. The etch chambers 412a-d may comprise any conventional processing chambers capable of etching low K dielectrics formed on a substrate (e.g., eMax chambers manufactured by Applied Materials, Inc.). The auxiliary processing chambers 414a-b, if employed, may include, for example, cooldown chambers, substrate orientors, degas chambers, inspections chambers, ashing chambers or the like. In at least one embodiment of the invention, the processing tool 402 is a Centura® Dielectric Etch and Strip tool (based on a Centura™ platform) manufactured by Applied Materials, Inc. Any other etching system may be similarly employed.

The factory interface 404 includes a buffer chamber 416 which houses a second substrate handler 418 and which is coupled to a plurality of loadports 420a-d. It will be understood that in general, any number of substrate handlers may be located within the buffer chamber 416, and that any number of loadports may be coupled to the buffer chamber 416.

### Integrated Inspection for Etch Subsystem

As shown in FIG. 4A, the etch tool 106 includes an integrated inspection system 422. In the exemplary embodiment of FIG. 4A, the integrated inspection system 422 includes a defect detection tool 424a and a metrology tool 424b both coupled to the buffer chamber 416 of the factory interface 404. Alternatively, the integrated inspection system 422 may include only one of the defect detection tool 424a and the metrology tool 424b, or may be coupled to the processing tool 402 rather than to the factory interface 404 (e.g., by coupling the defect detection tool 424a and/or the metrology tool 424b to the transfer chamber 406 such as at the location of one or more of the auxiliary processing chambers 414a-b).

### Defect Detection for Etch Subsystem

The defect detection tool 424a may comprise any conventional defect detection tool capable of detecting and/or characterizing defects on a surface of a substrate. In at least one embodiment of the invention, the defect detection tool 424a comprises the Excite™ or IPM™ defect detection tool manufactured by Applied Materials, Inc. and described in previously incorporated U.S. patent application Ser. No. 09/110,870, filed Jul. 7, 1998. The defect detection tool 424a may, for example, merely provide a measure of defect density on a substrate surface or may provide detailed information about any detected defects such as defect characterization and/or classification information. The defect detection tool 424 may provide such information to the module controller 120 (and/or to the EMC 106a of the system of FIG. 1B).

### Metrology for Etch Subsystem

The metrology tool 424b may comprise any conventional metrology tool capable of measuring via and/or line depth, width, profile, and/or other critical dimension information. In at least one embodiment of the invention, the metrology tool 424b comprises a laser based metrology tool wherein laser light is scattered off of a substrate surface and analyzed to determine via/line depth, via/line profile, via/line width and/or other critical dimension information as is known in the art.

The metrology tool 424b also may be configured to inspect a substrate prior to etching so as to determine the density of a patterned masking layer used to define vias or lines formed in a low K dielectric material. The metrology tool 424b can then provide information regarding the patterned masking layer to the module controller 120, and based on this information the module controller 120 may determine an appropriate etch process (e.g., a “baseline” etch process selected from a plurality of etch processes stored by the module controller 120) for the substrate as described further below. In the embodiment of FIG. 1B, the EMC 106a additionally or alternatively may perform such functions.

### Operation of Etch Subsystem

In operation, a cassette or carrier of substrates is delivered to the factory interface 404 of the etch tool 106. In particular, the substrate carrier is delivered to one of the loadports 420a-d. Each loadport 420a-d may or may not be configured with pod opening capability for opening sealed substrate carriers. Once the substrate carrier has been loaded into the appropriate loadport 420a-d of the factory interface 404, the substrate handler 418 retrieves a substrate from the substrate carrier and transfers the substrate to the first loadlock 410a. Thereafter the substrate handler 408 of the processing tool 402 retrieves the substrate from the first loadlock 410a and transfers the substrate to one of the etch chambers 412a-d. The substrate is then etched within the etch chamber (e.g., in accordance with one or more of the inventive processes described below) and is transferred to the second loadlock 410b. A patterned masking layer formed on the substrate (e.g., a patterned photoresist layer) used to define vias and/or lines during etching also may be removed within the etch chamber or within a separate etch chamber (as described below) before the substrate is transferred to the second loadlock 410b. An auxiliary ashing chamber (not shown) similarly may be used to remove the patterned masking layer. Prior to etching within the etch chamber and/or after etching within the etch chamber the substrate may be processed within one or both of the auxiliary processing chambers 414a-b (e.g., for substrate orientation purposes, for degassing, for cooldown, etc.).

The substrate handler 418 of the factory interface 404 retrieves the substrate from the second loadlock 410b and transfers the substrate to one of the defect detection tool 424a and the metrology tool 424b. Assuming the substrate is first transferred to the defect detection tool 424a, the defect detection tool 424a performs defect detection (e.g., determines the defect density on the surface of the substrate, identifies or otherwise characterizes defects on the surface of the substrate, etc.) and communicates information regarding the results of the defect detection to the module controller 120 (and/or to the EMC 106a in the system of FIG. 1B). The substrate handler 418 of the factory interface 404 retrieves the substrate from the defect detection tool 424a and transfers the substrate to the metrology tool 424b.

The metrology tool 424b analyzes the substrate to determine such information as via/line depth, via/line width, via/line profile and/or other critical dimension information. The metrology tool 424b then provides this information to the module controller 120 (and/or to the EMC 106a in the system of FIG. 1B). The substrate handler 418 of the factory interface 404 retrieves the substrate from the metrology tool 424b and returns the substrate to a substrate carrier (located within one of the loadports 420a-d).

It will be understood that more than one substrate may be processed at a time within the etch tool 106. For example, while one substrate is being processed within the etch chamber 412a, up to three other substrates may be simultaneously processed within the etch chambers 412b-d. Likewise, substrates may be processed within the etch chambers 412a-d while defect detection is performed within the defect detection tool 424a or while metrology is performed within the metrology tool 424b on a different substrate. In this manner, because of the integrated nature of the defect detection tool 424a and the metrology tool 424b, defect detection measurements and/or metrology measurements have little affect on the throughput of the etch tool 106. Defect detection and/or metrology therefore may be performed on every substrate processed within the etch tool 106 (if desired). Further, substrates may be inspected via the defect detection tool 424a and/or the metrology tool 424b before being processed within one of the etch chambers 412a-d.

Either the module controller 120 or the FAB controller 122 may comprise computer program code for performing the various substrate transfer operations described above. The EMC 106a also may comprise such computer program code.

### Alternative Etch Subsystem

In at least one embodiment of the invention, the cleaning tool 108 may be part of an etch tool, and may share use of the integrated inspection system of the etch tool. FIG. 4B is a top plan view of an exemplary etch and clean tool 106′ that may be employed within the inventive system of FIG. 1A or 1B. The etch and clean tool 106′ is similar to the etch tool 106 of FIG. 4A, but includes an additional buffer chamber 426 having a substrate handler 428 disposed therein, and two cleaning chambers 430 and 432 coupled to the buffer chamber 426. Each cleaning chamber 430, 432 may comprise any conventional apparatus for cleaning a substrate such as a wet chemical cleaning station that employs an appropriate solvent or other chemical, de-ionized (DI) water rinsing, Marangoni drying, megasonic techniques and/or any combination thereof to clean a substrate. Such cleaning chambers are well known in the art and are not described in further detail herein.

### Barrier/Seed Layer Deposition Subsystem

FIG. 5 is a top plan view of an exemplary embodiment of the barrier/seed layer deposition tool 112 of FIGS. 1A and/or 1B. With reference to FIG. 5, the barrier/seed layer deposition tool 112 comprises a processing tool 502 coupled to a factory interface 504. The processing tool 502 includes a buffer chamber 506a and a transfer chamber 506b which house a first substrate handler 508a and a second substrate handler 508b, respectively. The buffer chamber 506a is coupled to a first loadlock 510a and a second loadlock 510b. The transfer chamber 506b is coupled to the buffer chamber 506a, a pre-clean chamber 511, a barrier layer deposition chamber 512 and a seed layer deposition chamber 514.

The buffer chamber 506a also may be coupled to a first auxiliary processing chamber 516a, a second auxiliary processing chamber 516b and/or a third auxiliary processing chamber 516c. Fewer or more barrier layer deposition chambers, seed layer deposition chambers, preclean chambers or auxiliary processing chambers may be employed, and the module controller 120 may communicate with and/or control the processes performed within each chamber.

Loadlock chambers 510a-b may comprise any conventional loadlock chambers capable of transferring substrates from the factory interface 504 to the buffer chamber 506a. The pre-clean chamber 511 may comprise any conventional processing chamber capable of cleaning an interconnect feature (e.g., to remove a metal oxide such as copper oxide from an underlying metal layer to be connected to with the interconnect) such as a conventional high density plasma (HDP) etch chamber.

The barrier layer deposition chamber 512 may comprise any conventional processing chamber capable of depositing a barrier layer on a substrate such as a self-ionizing plasma (SIP) physical vapor deposition (PVD) chamber, any other suitable PVD chamber or the like. In at least one embodiment, the barrier layer deposition chamber 512 is a Ta/TaN SIP PVD chamber.

The seed layer deposition chamber 514 may comprise any conventional processing chamber capable of depositing a seed layer on a substrate such as an SIP PVD chamber, any other suitable PVD chamber or the like. In at least one embodiment, the seed layer deposition chamber 514 is a copper SIP PVD chamber. The auxiliary processing chambers 516a-c, if employed, may include, for example, cooldown chambers, substrate orienters, degas chambers, inspections chambers or the like.

In at least one embodiment of the invention, the processing tool 502 is based on an Endura™ platform manufactured by Applied Materials, Inc. Any other barrier/seed layer deposition system configuration may be similarly employed.

The factory interface 504 includes a buffer chamber 518 which houses a third substrate handler 520 and which is coupled to a plurality of loadports 522a-d. It will understood that in general, any number of substrate handlers may be located within the buffer chamber 518, and that any number of loadports may be coupled to the buffer chamber 518.

### Integrated Inspection for Barrier/Seed Layer Deposition Subsystem

As shown in FIG. 5, the barrier/seed layer deposition tool 502 includes an integrated inspection system 524. In the exemplary embodiment of FIG. 5, the integrated inspection system 524 includes a defect detection tool 524a and a metrology tool 524b both coupled to the buffer chamber 518 of the factory interface 504. Alternatively, the integrated inspection system 524 may include only one of the defect detection tool 524a and the metrology tool 524b, or may be coupled to the processing tool 502 rather than to the factory interface 504 (e.g., by coupling the defect detection tool 524a and/or the metrology tool 524b to the buffer chamber 506a such as at the location of one or more of the auxiliary processing chambers 516a-c).

### Defect Detection for Barrier/Seed Layer Deposition Subsystem

The defect detection tool 524a may comprise any conventional defect detection tool capable of detecting, characterizing and/or classifying defects on a surface of a substrate. In at least one embodiment of the invention, the defect detection tool 524a comprises the Excite™ or integrated particle monitor (IPM™) defect detection tool manufactured by Applied Materials, Inc. and described in previously incorporated U.S. patent application Ser. No. 09/110,870, filed Jul. 7, 1998 and titled “A PIXEL BASED MACHINE FOR PATTERNED WAFERS”. The defect detection tool 524a may, for example, merely provide a measure of defect density on a substrate surface or may provide detailed information about any detected defects such as defect characterization or classification information. The defect detection tool 524a may provide such information to the module controller 120 (and/or to the EMC 112a in the system of FIG. 1B).

### Metrology for Barrier/Seed Layer Deposition Subsystem

The metrology tool 524b may comprise any conventional metrology tool capable of measuring barrier layer and/or seed layer thickness or other relevant barrier and/or seed layer information. Exemplary metrology tools include x-ray, thermal, sonic, laser, optical interference, light scattering or eddy-current based metrology tools, four point probes, etc. The metrology tool 524b also may measure the dimensions of interconnect features present on a substrate (e.g., line or via depth, width, profile, and/or other critical dimension information). In at least one embodiment of the invention, the metrology tool 524b comprises an x-ray reflectometry system that examines the x-ray interference pattern produced by a film to determine film thickness, density, roughness, etc. One such system is the METAPROBEX reflectometer manufactured by Thermawave, Inc., although other systems may be employed. For determining interconnect feature information, the metrology system 524b may include a laser based metrology tool wherein laser light is scattered off of a substrate surface and analyzed to determine interconnect feature density, depth, profile, width and/or other critical dimension information as is known in the art.

The metrology tool 524b can provide information regarding interconnect feature density and/or dimensions/profile to the module controller 120, and based on this information the module controller 120 may determine an appropriate barrier layer and/or seed layer process for a substrate as described further below. In the embodiment of FIG. 1B, the EMC 112a additionally or alternatively may perform such functions.

### Operation of Barrier/Seed Layer Deposition Subsystem

In operation, a cassette or carrier of substrates is delivered to the factory interface 504 of the barrier/seed layer deposition tool 112. In particular, the substrate carrier is delivered to one of the loadports 522a-d. Each loadport 522a-d may or may not be configured with pod opening capability for opening sealed substrate carriers. Once the substrate carrier has been loaded into the appropriate loadport 522a-d of the factory interface 504, the substrate handler 520 retrieves a substrate from the substrate carrier and transfers the substrate to the first loadlock 510a. Thereafter the substrate handler 508a of the processing tool 502 retrieves the substrate from the first loadlock 510a and transfers the substrate to a degas chamber (e.g., one of the auxiliary chambers 516a-c) where the substrate is degassed. After the substrate is degassed, the substrate handler 508a transfers the substrate to a first pass-through 526 of the processing tool 502.

The substrate handler 508b of the processing tool 502 retrieves the substrate from the first pass-through 526 and transfers the substrate to the preclean chamber 511 where the substrate is precleaned (e.g., to remove metal oxide from a base of each interconnect feature formed on the substrate) as is known in the art. The substrate then is transferred to the barrier layer deposition chamber 512.

Within the barrier layer deposition chamber 512, a barrier layer is deposited on the substrate (e.g., in accordance with one or more of the inventive processes described below) and the substrate is transferred to the seed layer deposition chamber 514. Within the seed layer deposition chamber 514, a seed layer is similarly deposited on the substrate.

Thereafter, the substrate is transferred to a second pass-through 528 of the processing tool 502 by the substrate handler 508b and the substrate handler 508a then transfers the substrate to the loadlock 510b. After barrier layer and/or seed layer deposition, the substrate may be processed within one or more of the auxiliary processing chambers 516a-c (e.g., for substrate orientation purposes, for degassing, for cooldown, etc.).

After the substrate has been returned to the second loadlock 510b, the substrate handler 520 of the factory interface 504 retrieves the substrate from the second loadlock 510b and transfers the substrate to one of the defect detection tool 524a and the metrology tool 524b. Assuming the substrate is first transferred to the defect detection tool 524a, the defect detection tool 524a performs defect detection on the substrate (e.g., determines the defect density on the surface of the substrate, identifies or otherwise characterizes or classifies defects on the surface of the substrate, etc.) and communicates information regarding the results of the defect detection to the module controller 120 (and/or to the EMC 112a in the system of FIG. 1B). Following defect detection, the substrate handler 520 of the factory interface 504 retrieves the substrate from the defect detection tool 524a and transfers the substrate to the metrology tool 524b.

The metrology tool 524b analyzes the substrate to determine such information as barrier layer thickness, seed layer thickness, and/or other critical dimension information. The metrology tool 524b then provides this information to the module controller 120 (and/or to the EMC 112a in the system of FIG. 1B). Thereafter, the substrate handler 520 of the factory interface 504 retrieves the substrate from the metrology tool 524b and returns the substrate to a substrate carrier (located within one of the loadports 522a-d).

It will be understood that more than one substrate may be processed at a time within the barrier/seed layer deposition tool 112. For example, while one substrate is being processed within the barrier layer deposition chamber 512, up to two other substrates may be simultaneously processed within the chambers 511 and 514. Likewise, substrates may be processed within the chambers 511-514 while defect detection is performed within the defect detection tool 524a or while metrology is performed within the metrology tool 524b on a different substrate. In this manner, because of the integrated nature of the defect detection tool 524a and the metrology tool 524b, defect detection measurements and/or metrology measurements have little affect on the throughput of the barrier/seed layer deposition tool 112. Defect detection and/or metrology therefore may be performed on every substrate processed within the barrier/seed layer deposition tool 112 (if desired).

Either the module controller 120 or the FAB controller 122 may comprise computer program code for performing the various substrate transfer operations described above. The EMC 112a also may comprise such computer program code.

Note that while the operation of the barrier/seed layer deposition tool 112 has been described with regard to performing defect detection and/or metrology on a deposited barrier layer and a deposited seed layer only after both layers have been deposited, the defect detection tool 524a and the metrology tool 524b may perform defect detection and metrology, respectively, on a deposited barrier layer before a seed layer is formed over the barrier layer.

The metrology tool 524a also may be employed to measure the dimensions of interconnect features of a substrate (e.g., via and/or line width, depth, profile, etc.) prior to barrier layer deposition, and to communicate such dimension information to the module controller 120 and/or to the EMC 112a. This information then may be used to determine a barrier layer deposition process and/or a seed layer deposition process to perform within the barrier layer deposition chamber 512 and/or the seed layer deposition chamber 514, respectively, as described further below. Interconnect feature density may be similarly determined and employed.

In an embodiment wherein the tool 112 employs the EMC 112a and the APC module 112b (FIG. 1B), all or part of the information obtained from the integrated inspection system 524 may be communicated to the EMC 112a of the tool 112. In this manner, the EMC 112a and the APC module 112b may at least partially control the processes performed within the chambers 512, 514 based on information from the integrated inspection system 524 (as described below).

### Electroplating Subsystem

FIG. 6 is a top plan view of an exemplary embodiment of the electroplating tool 114 of the inventive system 100 of FIGS. 1A and 1B. With reference to FIG. 6, the electroplating tool 114 comprises a processing tool 602 coupled to a factory interface 604. The processing tool 602 includes a chamber 606 which houses a first substrate handler 608. The first substrate handler 608 has two individually controllable robot arms 610a, 610b. The chamber 606 also includes a first electroplating chamber 612a, a second electroplating chamber 612b, a third electroplating chamber 612c, and a fourth electroplating chamber 612d. The chamber 606 further includes an integrated bevel cleaner 614 and a spin rinse dryer 616 (in a stacked configuration, although other configurations may be employed).

The electroplating chambers 612a-d may comprise any conventional electroplating chambers capable of depositing a fill layer on the substrate (e.g., a metal layer such as copper or aluminum that “fills” interconnect features such as vias or lines etched within an interlayer dielectric). In at least one embodiment, each electroplating chamber 612a-d is capable of depositing a copper fill layer on a substrate via the interaction of a copper sulfide base solution with a sulfuric acid (H₂SO₄) solution as is known in the art.

The integrated bevel cleaner 614 may comprise any conventional tool for removing deposited layers from an edge of a substrate. In at least one embodiment, the integrated bevel cleaner 614 directs an etchant solution (e.g., H₂SO₄ and hydrogen peroxide) toward a beveled edge of a substrate to remove metal layers therefrom. The use of an etchant solution for substrate edge cleaning is well known and is not described further herein. The spin rinse dryer 616 may comprise any conventional spin rinse dryer capable of cleaning, rinsing and/or drying a substrate following edge cleaning.

It will be understood that the processing tool 602 may be based on any equipment platform. For example, the processing tool 602 may be an Electra integrated electrochemical process (IECP™) system manufactured by Applied Materials, Inc. Suitable electroplating chambers/systems are also described in U.S. Pat. Nos. 6,113,771 and 6,258,220 which are hereby incorporated by reference herein in their entirety. Other systems/platforms may be employed.

The factory interface 604 includes a buffer chamber 618 which houses a second substrate handler 620, a third substrate handler 622 and an orienter 624, and which is coupled to a plurality of loadports 626a-b. It will understood that in general, any number of substrate handlers may be located within the buffer chamber 618, and that any number of loadports may be coupled to the buffer chamber 618. A first anneal chamber 627a and a second anneal chamber 627b also are coupled to the buffer chamber 618.

### Integrated Inspection for Electroplating Subsystem

As shown in FIG. 6, the electroplating tool 114 includes a first integrated inspection system 628 and a second integrated inspection system 630. In the exemplary embodiment of FIG. 6, the first integrated inspection system 628 includes a defect detection tool 628a and a metrology tool 628b both coupled to the first anneal chamber 627a. The second integrated inspection system 630 includes a defect detection tool 630a and a metrology tool 630b both coupled to the second anneal chamber 627b. Alternatively, each integrated inspection system may include only one of a defect detection tool and a metrology tool, or may be coupled to the processing tool 602 rather than to the factory interface 604.

### Defect Detection for Electroplating Subsystem

Each defect detection tool 628a, 630a may comprise any conventional defect detection tool capable of detecting, characterizing and/or classifying defects on a surface of a substrate. In at least one embodiment of the invention, each defect detection tool 628a, 630a comprises the Excite™ or IPM™ defect detection tool manufactured by Applied Materials, Inc. and described in previously incorporated U.S. patent application Ser. No. 09/110,870, filed Jul. 7, 1998. Each defect detection tool 628, 630a may, for example, merely provide a measure of defect density on a substrate surface or may provide detailed information about any detected defects such as defect characterization or classification information. Each defect detection tool 628a, 630 may provide such information to the module controller 120 (and/or to the EMC 114a in the system of FIG. 1B).

### Metrology for Electroplating Subsystem

The metrology tools 628b, 630b may comprise any conventional metrology tools capable of measuring the thickness of a deposited fill layer (e.g., an electroplated metal layer) such as x-ray, thermal, sonic, laser, optical interference, light scattering or eddy-current based metrology subsystems, four point probes, etc. In at least one embodiment of the invention, each metrology tool 628b, 630b comprises an x-ray reflectometry system that examines the x-ray interference pattern produced by a film to determine film thickness, density, roughness, etc. One such system is the METAPROBEX reflectometer manufactured by Thermawave, Inc., although other systems may be employed. The defect detection tools 628a, 630a and/or the metrology tools 628b, 630b may share chambers with the anneal chambers 627a, 627b or may use separate chambers.

### Operation of Electroplating Subsystem

In operation, a substrate carrier is delivered to the factory interface 604 of the electroplating tool 114. In particular, the substrate carrier is delivered to one of the loadports 626a-b. Each loadport 626a-b may or may not be configured with pod opening capability for opening sealed substrate carriers. Once the substrate carrier has been loaded into the appropriate loadport 626a-b, one of the substrate handlers 620, 622 retrieves a substrate from the substrate carrier and transfers the substrate to the orienter 624. The orienter 624 orients the substrate (e.g., by locating a flat or notch on the substrate as is known in the art).

Thereafter the substrate handler 608 of the processing tool 602 retrieves the substrate from the orienter 624 and transfers the substrate to one of the electroplating chambers 612a-d. A metal fill layer then is deposited on the substrate (e.g., in accordance with one or more of the inventive processes described below) and the substrate is transferred to the integrated bevel cleaner 614 (by one of the robot arms 610a, 610b of the substrate handler 608).

Once the substrate has been transferred to the integrated bevel cleaner 614, the integrated bevel cleaner 614 cleans the edge (bevel) of the substrate (e.g., via an etchant). Following edge cleaning, the substrate is transferred to the spin rinse dryer 616 wherein the substrate is (1) cleaned (e.g., to remove residue from the edge cleaning process); (2) rinsed; and/or (3) dried.

Following the spin-rinse-dry process, the substrate is transferred to one of the anneal chambers 627a, 627b of the factory interface 604 (e.g., via one of the substrate handlers 620, 622). Assuming the substrate is transferred to the first anneal chamber 627a, the substrate is annealed within the first anneal chamber 627a. In at least one embodiment, the substrate is annealed in forming gas, nitrogen or argon at 250° C. for about 30 seconds, and the substrate then is rapidly cooled (e.g., within about 30 seconds). Such annealing stabilizes copper grain structure and copper resistivity. Other annealing processes also may be employed such as laser annealing, pedestal annealing, high pressure annealing or the like.

Following annealing, defection detection and/or metrology are performed on the substrate (e.g., via the defect detection tool 628a and the metrology tool 628b), in any order. For example, the defect detection tool 628a may perform defect detection on the substrate (e.g., to determine the defect density of the surface of the electroplated fill layer, to identify or otherwise characterize or classify defects on the surface of the electroplated fill layer, etc.) and may communicate information regarding the results of the defect detection to the module controller 120 (and/or to the EMC 114a in the system of FIG. 1B).

The metrology tool 628b may analyze the substrate to determine such information as electroplated fill layer thickness and may provide this information to the module controller 120 (and/or to the EMC 114a in the system of FIG. 1B). The substrate handler 620 then retrieves the substrate from the anneal chamber 627a and returns the substrate to a substrate carrier (located within one of the loadports 626a-b).

It will be understood that more than one substrate may be processed at a time within the electroplating tool 114. For example, while one substrate is being processed within the electroplating chamber 612a, up to three other substrates may be simultaneously processed within the electroplating chambers 612b-d. Likewise, substrates may be processed within the chambers 612a-d while defect detection is performed by the defect detection tools 628a, 630a, while metrology is performed by the metrology tools 628b, 630b, or while anneal processes are performed on different substrates (within the anneal chambers 627a, 627b). In this manner, because of the integrated nature of the defect detection tools 628a, 630a and the metrology tools 628b, 630b, defect detection measurements and/or metrology measurements have little affect on the throughput of the electroplating tool 114. Defect detection and/or metrology therefore may be performed on every substrate processed within the electroplating tool 114 (if desired).

Either the module controller 120 or the FAB controller 122 may comprise computer program code for performing the various substrate transfer operations described above. The EMC 114a also may comprise such computer program code.

### Planarization Subsystem

FIG. 7A is a top plan view of a first exemplary embodiment of the planarization tool 116 of FIGS. 1A and 1B. In general, the planarization tool 116 may comprise any tool or apparatus capable of planarizing a substrate as is known in the art and configured in accordance with the present invention as described below.

With reference to FIG. 7A, the planarization tool 116 includes a processing tool 702 coupled to a factory interface 704. In the exemplary embodiment of FIG. 7A, the processing tool 702 comprises a Mirra Mesa™ planarization tool manufactured by Applied Materials, Inc; (e.g., a 200 mm substrate planarization tool) and described in U.S. patent application Ser. No. 09/547,189, filed Apr. 11, 2000 and titled “METHOD AND APPARATUS FOR TRANSFERRING SEMICONDUCTOR SUBSTRATES USING AN INPUT MODULE”, which is hereby incorporated by reference herein in its entirety. It will be understood that any other planarization apparatus may be similarly employed.

The processing tool 702 includes a robot 706 that is movable along a track 708, an input shuttle 710, a polishing system 712 and a cleaning system 714. The polishing system 712 includes a load cup 716, a first polishing platen 718a (e.g., a bulk polishing platen), a second polishing platen 718b (e.g., an endpoint on barrier layer polishing platen) and a third polishing platen 718c (e.g., a barrier layer buff polishing platen). The cleaning system 714 includes an input module 720a, a megasonic module 720b, a first scrubber module 720c, a second scrubber module 720d, a spin rinse dryer module 720e and an output module 720f.

Factory interface 704 includes a buffer chamber 722, a substrate handler 724 located within the buffer chamber 722 and a plurality of loadports 726a-d coupled to the buffer chamber 722. An integrated inspection system 728 also is coupled to the buffer chamber 722 as shown. In general, any number of substrate handlers and/or loadports may be employed within the factory interface 704.

### Integrated Inspection for Planarization Subsystem

In the exemplary embodiment of FIG. 7A, the integrated inspection system 728 includes a defect detection tool 730a and a metrology tool 730b both coupled to the buffer chamber 722 of the factory interface 704. Alternatively, the integrated inspection system 728 may include only one of the defect detection tool 730a and the metrology tool 730b.

### Defect Detection for Planarization Subsystem

The defect detection tool 730a may comprise any conventional defect detection tool capable of detecting, characterizing and/or classifying defects on a surface of a substrate. In at least one embodiment of the invention, the defect detection tool 730a comprises the Excite™ or IPM™ defect detection tool manufactured by Applied Materials, Inc. and described in previously incorporated U.S. patent application Ser. No. 09/110,870, filed Jul. 7, 1998. The defect detection tool 730a may, for example, merely provide a measure of defect density on a substrate surface or may provide detailed information about any detected defects such as defect characterization or classification information. The defect detection tool 730a may provide such information to the module controller 120 (and/or to the EMC 116a in the system of FIG. 1B).

### Metrology for Planarization Subsystem

The metrology tool 730b may comprise any conventional metrology tool capable of measuring the planarity of a planarized substrate. In at least one embodiment of the invention, the metrology tool 730b may comprise a reflectometry-based thickness measurement tool such as a NanoSpec 9000 or 9000B measurement tool manufactured by Nanometrics, or a Novascan 840, 2200 or 3000 measurement tool manufactured by Nova Measuring Instruments; or an eddy-current based thickness measurement tool such as described in U.S. patent application Ser. No. 09/574,008, filed May 19, 2000 and titled “EDDY CURRENT SENSING OF METAL REMOVAL FOR CHEMICAL MECHANICAL POLISHING”; 09/900,664, filed Jul. 6, 2001 and titled “COMBINED EDDY CURRENT SENSING AND OPTICAL MONITORING FOR CHEMICAL MECHANICAL POLISHING”; 09/918,591, filed Jul. 27, 2001 and titled “CHEMICAL MECHANICAL POLISHING OF A METAL LAYER WITH POLISHING RATE MONITORING”; and 09/847,867, filed May 2, 2001 and titled “INTEGRATED ENDPOINT DETECTION SYSTEM WITH OPTICAL AND EDDY CURRENT MONITORING”, all of which are hereby incorporated by reference herein in their entirety.

### Operation of Planarization Subsystem

In operation, a substrate carrier is delivered to the factory interface 704 of the planarization tool 116. In particular, the substrate carrier is delivered to one of the loadports 726a-d. Each loadport 726a-d may or may not be configured with pod opening capability for opening sealed substrate carriers. Once the substrate carrier has been loaded into the appropriate loadport 726a-d, the substrate handler 724 retrieves a substrate from the substrate carrier and transfers the substrate to the robot 706. Thereafter the robot 706 transfers the substrate to the load cup 716 of the polishing system 712 via the track 708. The substrate is then polished within the polishing system 712 (e.g., in accordance with one or more of the inventive processes described below employing one or more of the polishing platens 718a-c) and is transferred to the input module 720a of the cleaning system 714 via the input shuttle 710.

The substrate is cleaned in the megasonic module 720b, scrubbed within one or both of the scrubber modules 720c-d and dried in the spin rinse dryer module 720e. The substrate then is transferred to the output module 720f and from the output module 720f to the substrate handler 724 (via the robot 706).

The substrate handler 724 transfers the substrate to one of the defect detection tool 730a and the metrology tool 730b. Assuming the substrate is first transferred to the defect detection tool 730a, the defect detection tool 730a performs defect detection (e.g., determines the defect density on the surface of the substrate, identifies or otherwise characterizes or classifies defects on the surface of the substrate, etc.) and communicates information regarding the results of the defect detection to the module controller 120 (and/or to the EMC 116a in the system of FIG. 1B). The substrate handler 724 retrieves the substrate from the defect detection tool 730a and transfers the substrate to the metrology tool 730b.

The metrology tool 730b analyzes the substrate to determine such information as surface planarity and provides this information to the module controller 120 (and/or to the EMC 116a in the system of FIG. 1B). The substrate handler 724 retrieves the substrate from the metrology tool 730b and returns the substrate to a substrate carrier (located within one of the loadports 726a-d).

It will be understood that more than one substrate may be processed at a time within the planarization tool 116. For example, while one substrate is being processed within the polishing system 712 (e.g., on one platen), other substrates may be simultaneously processed within the polishing system 712 (e.g., on other platens) and/or cleaned within the cleaning system 714. Likewise, substrates may be processed within the polishing system 712 and/or the cleaning system 714 while defect detection is performed within the defect detection tool 730a or while metrology is performed within the metrology tool 730b on a different substrate. In this manner, because of the integrated nature of the defect detection tool 730a and the metrology tool 730b, defect detection measurements and/or metrology measurements have little affect on the throughput of the planarization tool 116. Defect detection and/or metrology therefore may be performed on every substrate processed within the planarization tool 116 (if desired).

Either the module controller 120 or the FAB controller 122 may comprise computer program code for performing the various substrate transfer operations described above. The EMC 116a also may comprise such computer program code.

### Alternative Planarization Subsystem

FIG. 7B is a top plan view of a second exemplary embodiment of the planarization tool 116 of FIGS. 1A and 1B (referred to as planarization tool 116′ for convenience). The planarization tool 116′ of FIG. 7B is similar to the planarization tool 116 of FIG. 7A, and includes a processing tool 702′ coupled to a factory interface 704′. In the exemplary embodiment of FIG. 7B, the processing tool 702′ comprises a Reflexion planarization tool manufactured by Applied Materials, Inc. (e.g., a 300 mm substrate planarization tool) and described in U.S. patent application Ser. No. 09/244,456, filed Feb. 4, 1999 and titled “APPARATUS AND METHODS FOR CHEMICAL MECHANICAL POLISHING WITH AN ADVANCEABLE POLISHING SHEET”, which is hereby incorporated by reference herein in its entirety.

The processing tool 702′ includes a substrate handler 706′ (e.g., a “wet” robot), an input shuttle 710′, a polishing system 712′ and a cleaning system 714′. The polishing system 712′ includes a load cup 716′, a first polishing platen 718a′ (e.g., a bulk polishing platen), a second polishing platen 718b′ (e.g., an endpoint on barrier layer polishing platen) and a third polishing platen 718c′ (e.g., a barrier layer buff polishing platen). The cleaning system 714′ includes an input module 720a′, a megasonic module 720b′, a first scrubber module 720c′, a second scrubber module 720d′, a spin rinse dryer module 720e′ and an output module 720f′.

Factory interface 704′ includes a buffer chamber 722′, a substrate handler 724′ located within the buffer chamber 722′ and a plurality of loadports 726a′-b′ coupled to the buffer chamber 722′. An integrated inspection system 728′ also is coupled to the buffer chamber 722′ as shown. In general, any number of substrate handlers and/or loadports may be employed within the factory interface 704′.

### Integrated Inspection for Alternative Planarization Subsystem

In the exemplary embodiment of FIG. 7B, the integrated inspection system 728′ includes a defect detection tool 730a′ and a metrology tool 730b′ both coupled to the buffer chamber 722′ of the factory interface 704′. Alternatively, the integrated inspection system 728′ may include only one of the defect detection tool 730a′ and the metrology tool 730b′.

### Defect Detection for Alternative Planarization Subsystem

The defect detection tool 730a′ may comprise any conventional defect detection tool capable of detecting, characterizing and/or classifying defects on a surface of a substrate. In at least one embodiment of the invention, the defect detection tool 730a′ comprises the Excite™ or IPM™ defect detection tool manufactured by Applied Materials, Inc. and described in previously incorporated U.S. patent application Ser. No. 09/110,870, filed Jul. 7, 1998. The defect detection tool 730a′ may, for example, merely provide a measure of defect density on a substrate surface or may provide detailed information about any detected defects such as defect characterization or classification information. The defect detection tool 730a′ may provide such information to the module controller 120 (and/or to the EMC 116a in the system of FIG. 1B).

### Metrology for Alternative Planarization Subsystem

The metrology tool 730b′ may comprise any conventional metrology tool capable of measuring the planarity of a planarized substrate. In at least one embodiment of the invention, the metrology tool 730b′ may comprise a reflectometry-based thickness measurement tool such as a NanoSpec 9000 or 9000B measurement tool manufactured by Nanometrics, or a Novascan 840, 2200 or 3000 measurement tool manufactured by Nova Measuring Instruments; or an eddy-current based thickness measurement tool such as described in previously incorporated U.S. patent application Ser. No. 09/574,008, filed May 19, 2000 and titled “EDDY CURRENT SENSING OF METAL REMOVAL FOR CHEMICAL MECHANICAL POLISHING”; 09/900,664, filed Jul. 6, 2001 and titled “COMBINED EDDY CURRENT SENSING AND OPTICAL MONITORING FOR CHEMICAL MECHANICAL POLISHING”; 09/918,591, filed Jul. 27, 2001 and titled “CHEMICAL MECHANICAL POLISHING OF A METAL LAYER WITH POLISHING RATE MONITORING”; and 09/847,867, filed May 2, 2001 and titled “INTEGRATED ENDPOINT DETECTION SYSTEM WITH OPTICAL AND EDDY CURRENT MONITORING”.

### Operation of Alternative Planarization Subsystem

In operation, a substrate carrier is delivered to the factory interface 704′ of the planarization tool 116′. In particular, the substrate carrier is delivered to one of the loadports 726a′-b′. Once the substrate carrier has been loaded into the appropriate loadport 726a′-b′, the substrate handler 724′ retrieves a substrate from the substrate carrier and transfers the substrate to the input shuttle 710′. Thereafter the substrate handler 706′ transfers the substrate from the input shuttle 710′ to the load cup 716′ of the polishing system 712′. The substrate is then polished within the polishing system 712′ (e.g., in accordance with one or more of the inventive processes described below employing one or more of the polishing platens 718a′-c′) and is transferred to the input module 720a′ of the cleaning system 714′ via the substrate handler 706′ and the input shuttle 710′.

The substrate is cleaned in the megasonic module 720b′, scrubbed within one or both of the scrubber modules 720c′-d′ and dried in the spin rinse dryer module 720e′. The substrate then is transferred to the output module 720f′ and from the output module 720f′ to the substrate handler 724′ (via the robot 706′).

The substrate handler 724′ transfers the substrate to one of the defect detection tool 730a′ and the metrology tool 730b′. Assuming the substrate is first transferred to the defect detection tool 730a′, the defect detection tool 730a′ performs defect detection (e.g., determines the defect density on the surface of the substrate, identifies or otherwise characterizes/classifies defects on the surface of the substrate, etc.) and communicates information regarding the results of the defect detection to the module controller 120 (and/or to the EMC 116a in the system of FIG. 1B). The substrate handler 724′ retrieves the substrate from the defect detection tool 730a′ and transfers the substrate to the metrology tool 730b′.

The metrology tool 730b′ analyzes the substrate to determine such information as surface planarity and provides this information to the module controller 120 (and/or to the EMC 116a in the system of FIG. 1B). The substrate handler 724′ retrieves the substrate from the metrology tool 730b′ and returns the substrate to a substrate carrier (located within one of the loadports 726a′-b′).

As with the planarization tool 116 of FIG. 7A, more than one substrate may be processed at a time within the planarization tool 116′. For example, while one substrate is being processed within the polishing system 712′ (e.g., on one platen), other substrates may be simultaneously processed within the polishing system 712′ (e.g., on other platens) and/or cleaned within the cleaning system 714′. Likewise, substrates may be processed within the polishing system 712′ and/or the cleaning system 714′ while defect detection is performed within the defect detection tool 730a′ or while metrology is performed within the metrology tool 730b′ on a different substrate. In this manner, because of the integrated nature of the defect detection tool 730a′ and the metrology tool 730b′, defect detection measurements and/or metrology measurements have little affect on the throughput of the planarization tool 116′; and defect detection and/or metrology may be performed on every substrate processed within the planarization tool 116′ (if desired).

Either the module controller 120 or the FAB controller 122 may comprise computer program code for performing the various substrate transfer operations described above. The EMC 116a also may comprise such program code.

### Exemplary Integrated Process and Operation of Integrated System and Method for Forming Low K Dielectric Interconnects

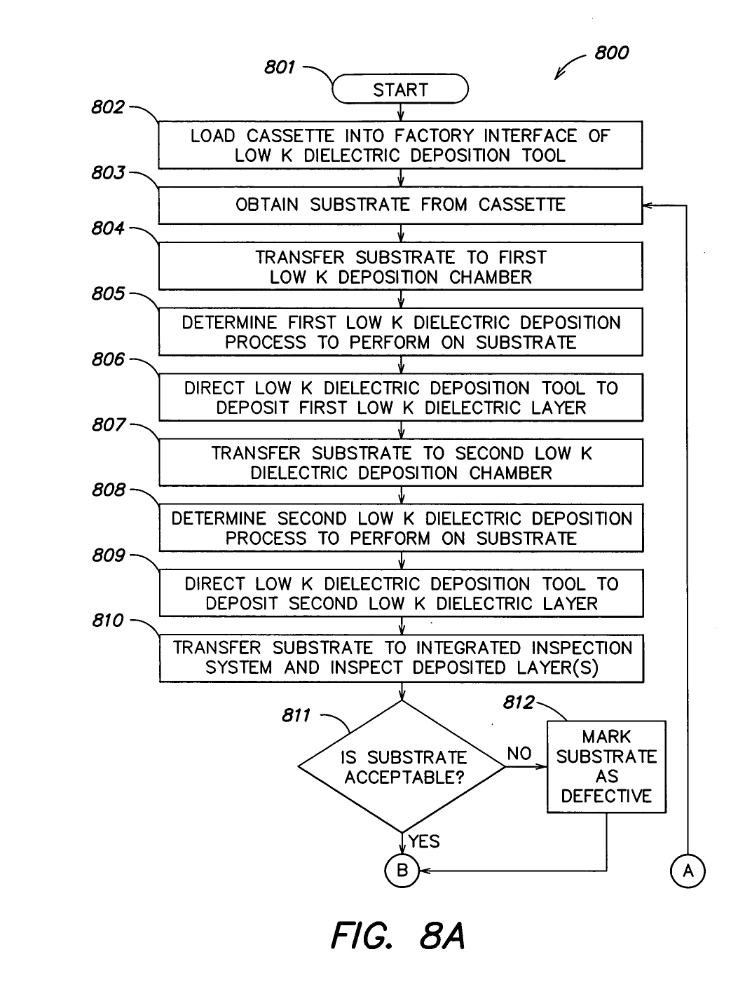

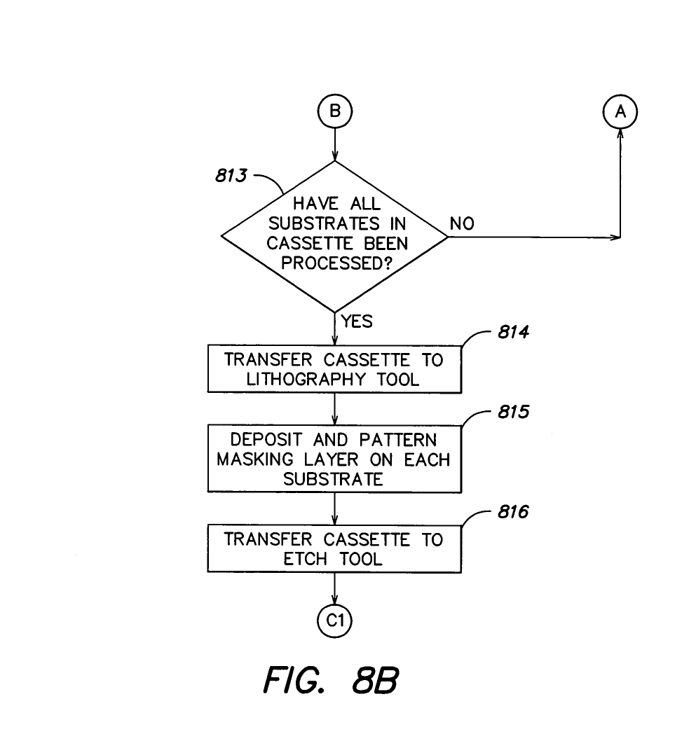

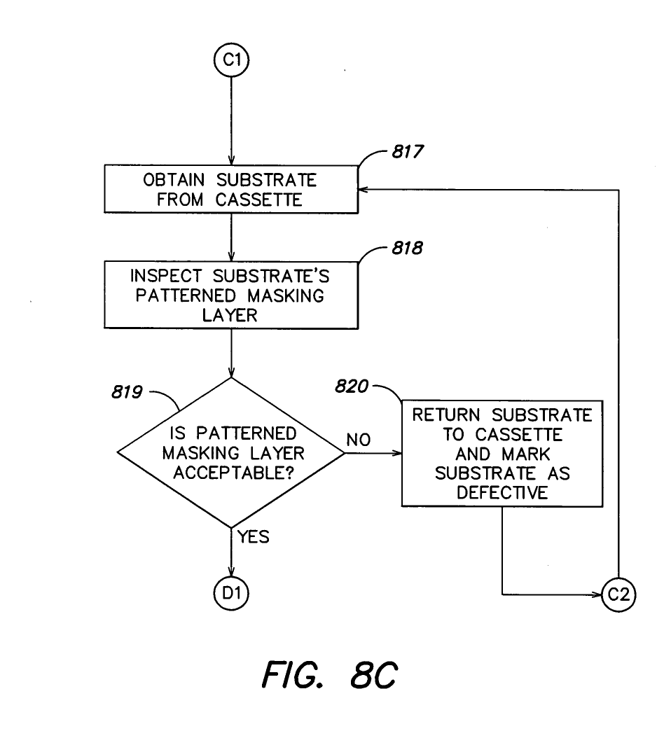

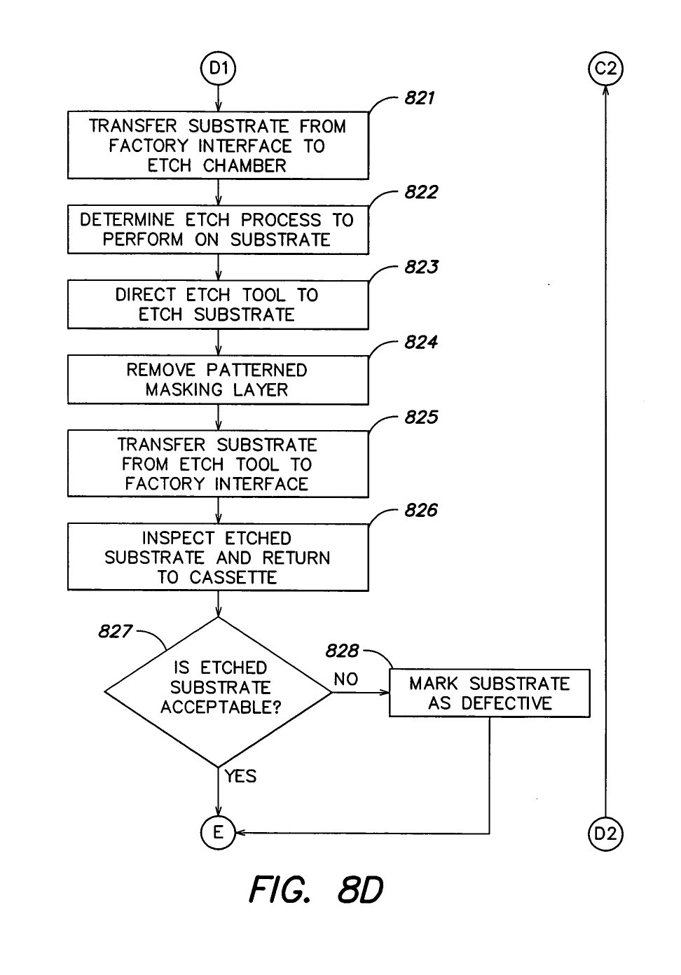

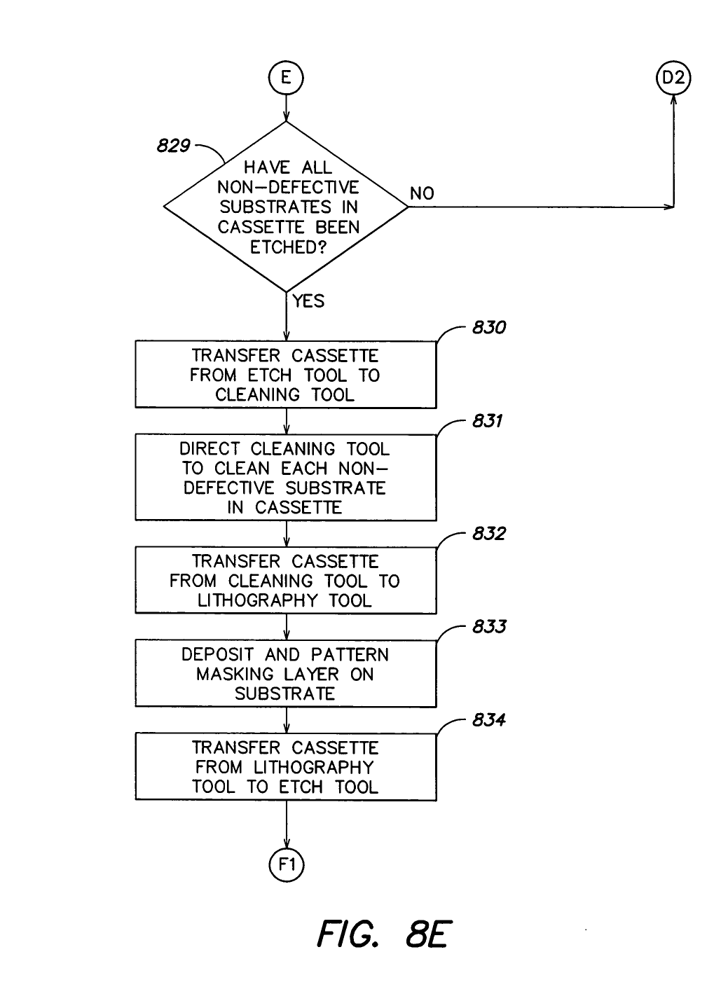

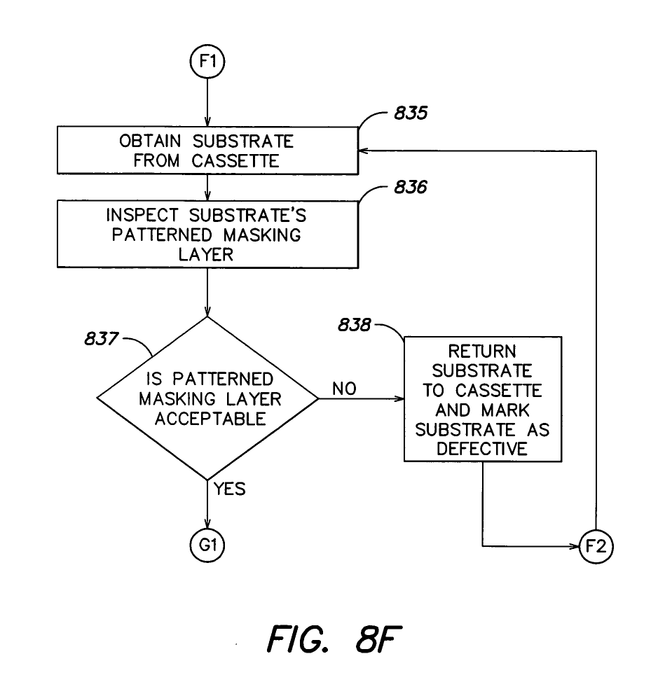

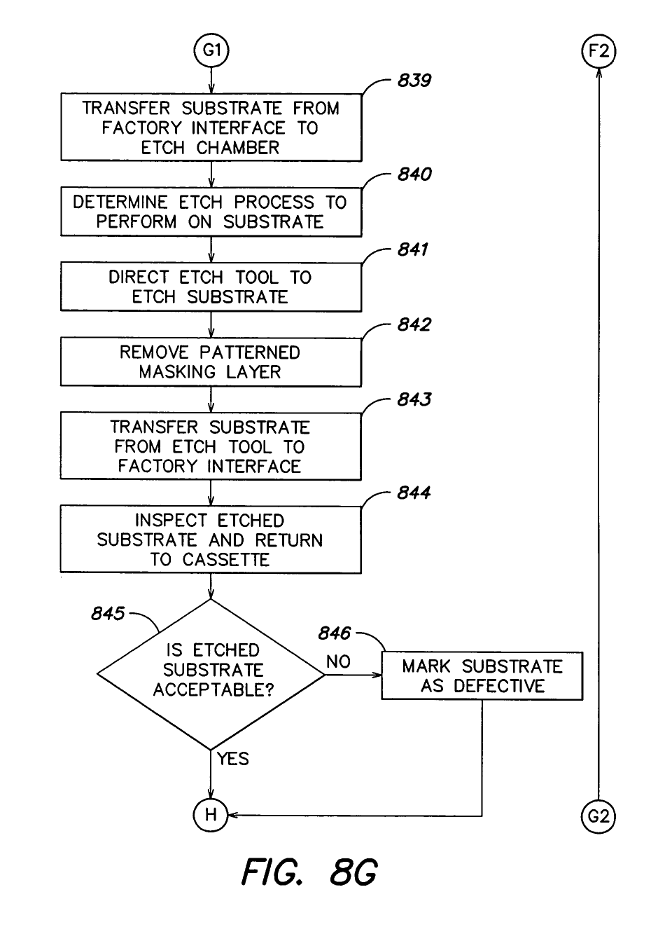

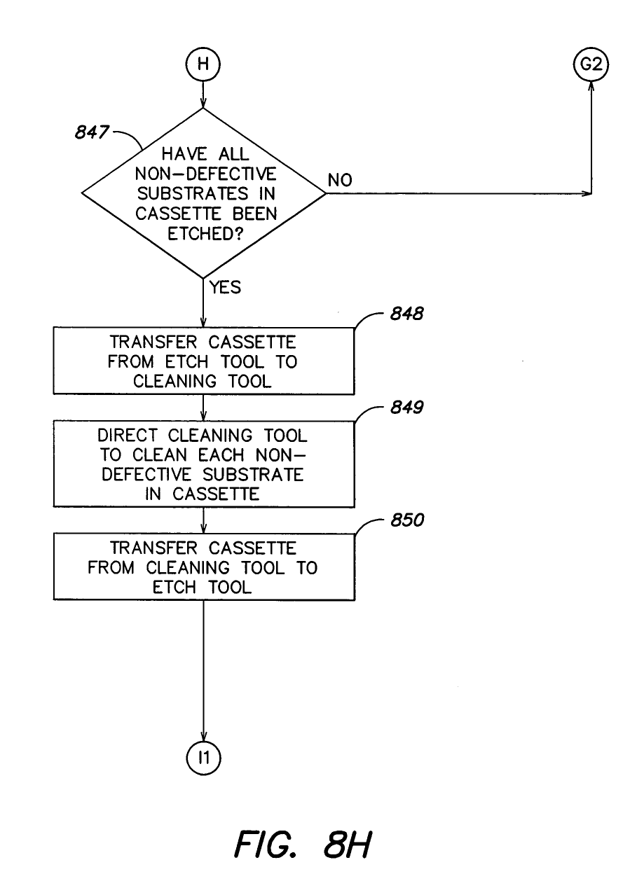

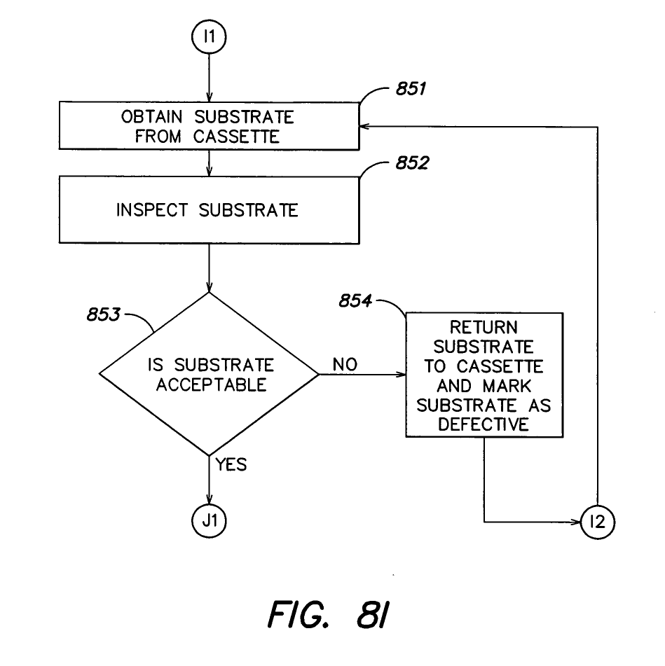

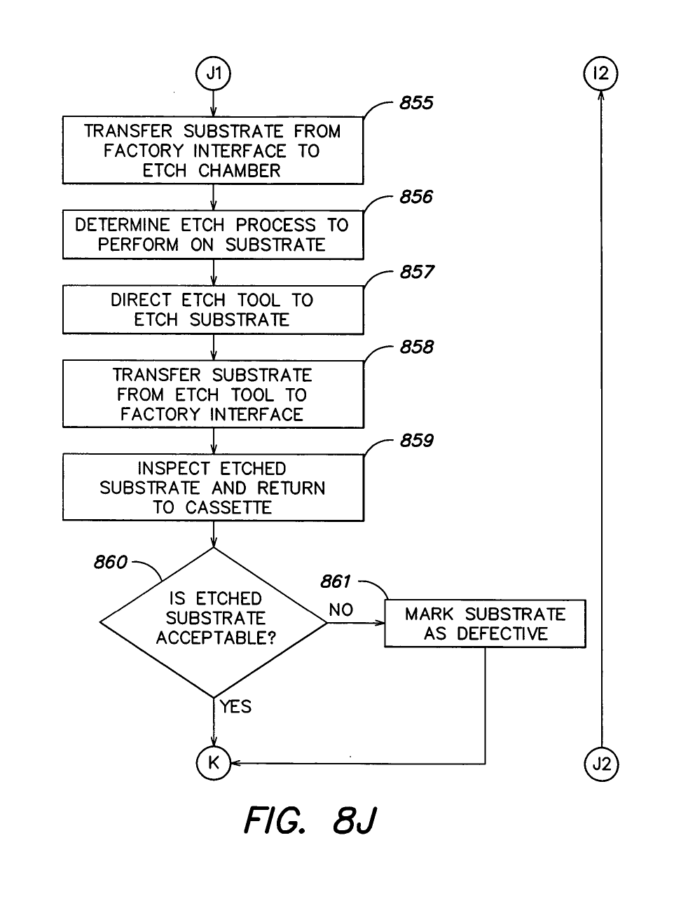

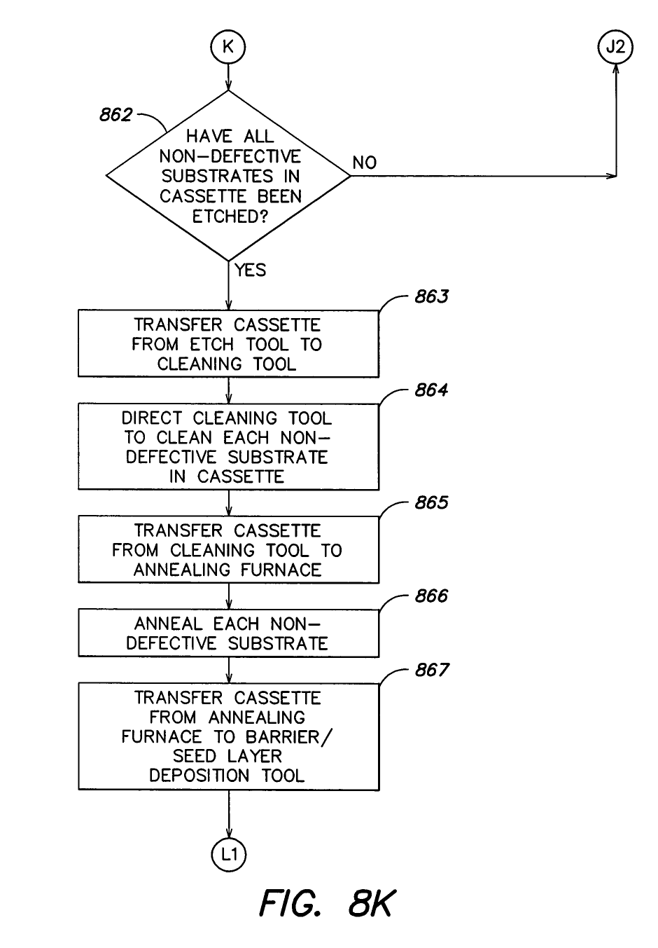

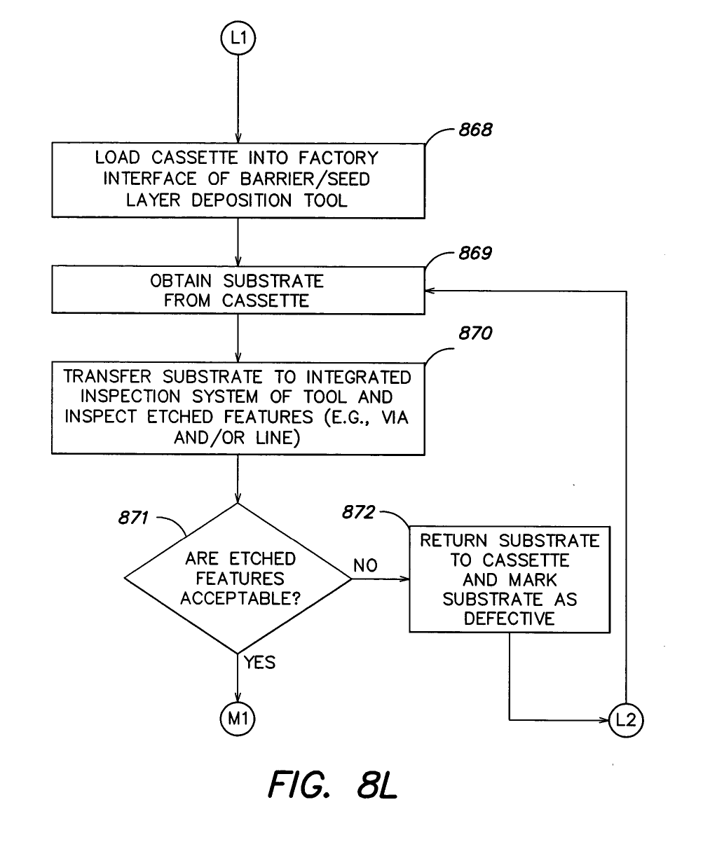

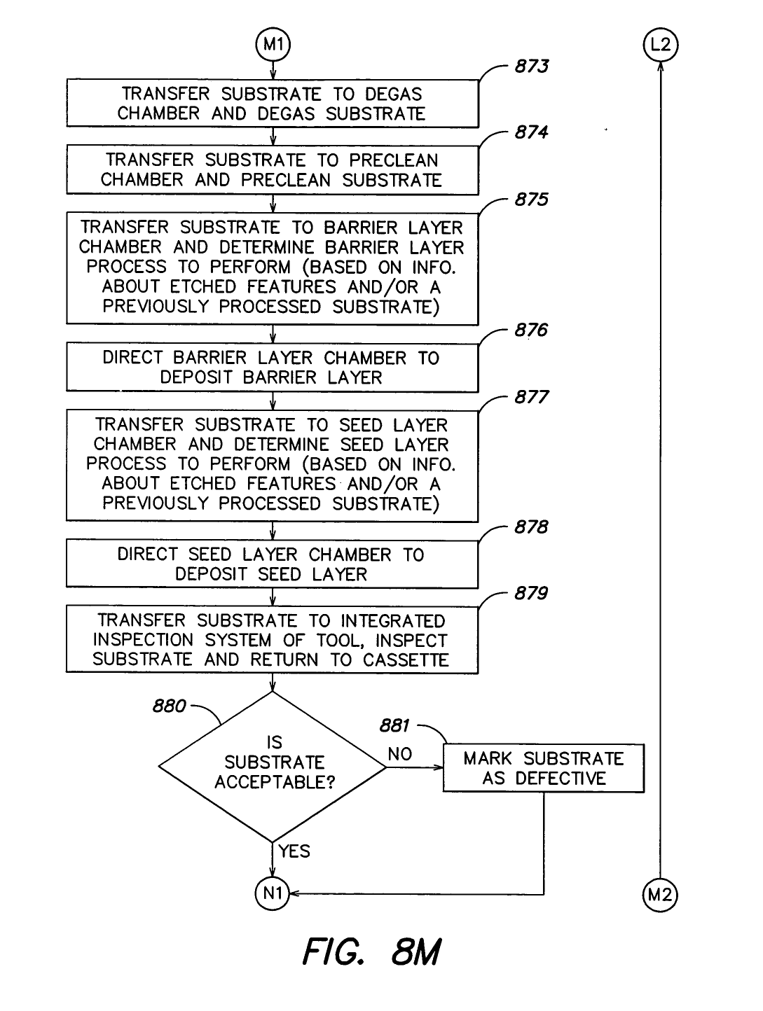

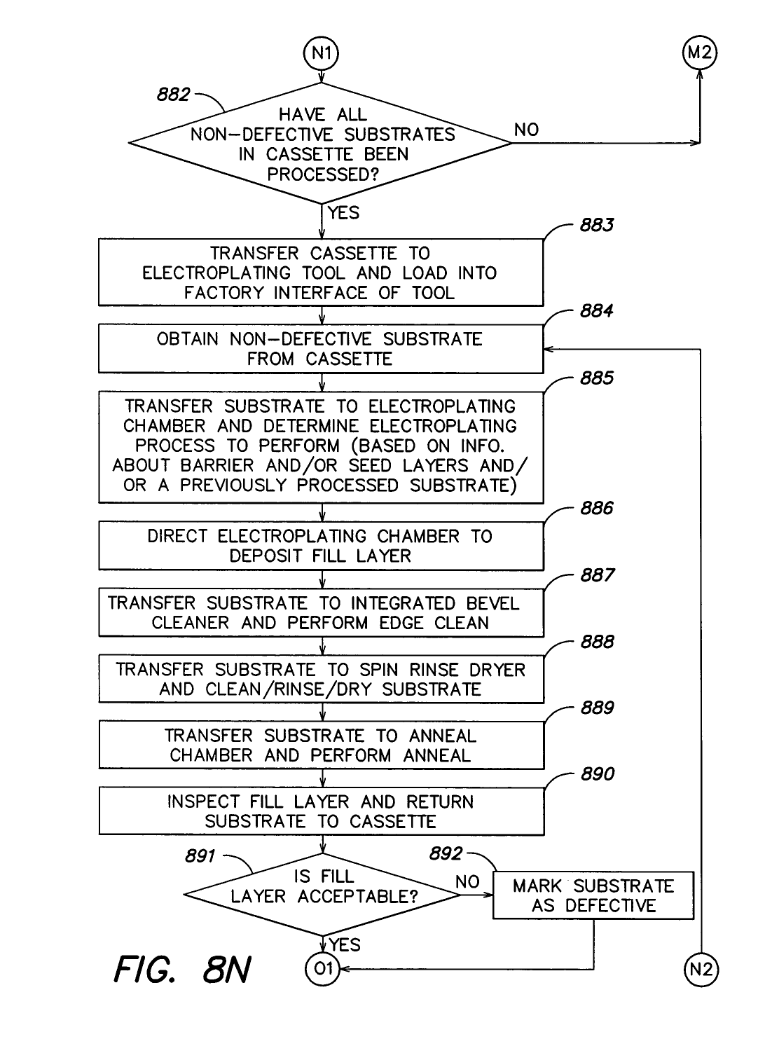

FIGS. 8A-P illustrate a flowchart of an exemplary process 800 for forming low K dielectric interconnects on a substrate in accordance with the present invention. The exemplary process 800 will be described with reference to FIGS. 1A-7B, and FIGS. 9A-L which illustrate cross sectional views of a semiconductor substrate during the process 800 of FIGS. 8A-P. For convenience purposes only, the process 800 is described with reference to the module controller 120 (without use of the EMC's 102a-116a and the APC modules 102b-116b). It will be understood that all or a portion of the process 800 may be similarly performed using one or more of the EMC's 102a-116a and the APC modules 102b-116b alone or in combination with the module controller 120.

With reference to FIGS. 8A-P, the process 800 begins with step 801. In step 802 the inventive system 100 receives a substrate cassette (e.g., via a delivery mechanism such as an overhead conveyor system, an automated guided vehicle, etc.) and loads the substrate cassette into the factory interface 304 of the low K dielectric deposition tool 102. For example, the substrate cassette may be loaded into one of the loadports 328a-b of the factory interface 304. For convenience, process flow within the low K dielectric deposition tool 102 will be described only with regard to a single substrate cassette in which substrates are processed employing loadport 328a, substrate handler 326a, loadlock 306a, chambers 314a, 318a and 322a, defect detection tool 332a and metrology tool 334. In will be understood that substrates may be simultaneously processed therewith employing loadport 328b, substrate handler 326b, loadlock 306b, chambers 314a, 318b and 322b, defect detection tool 332b and metrology tool 334.

In step 803, a substrate is extracted from the substrate cassette (at loadport 328a) by the substrate handler 326a and in step 804, the substrate is transferred to the first low K dielectric deposition chamber 314a (e.g., via the substrate handler 326a, the loadlock 306a and the substrate handler 310). The module controller 120 then determines a first low K dielectric deposition process to perform on the substrate (step 805).

The first low K dielectric deposition process may be based on, for example, information obtained from the integrated inspection system 330 of the low K dielectric deposition tool 102 for a low K dielectric layer previously deposited within the first low K dielectric deposition chamber 314a or 314b (e.g., information such as deposited dielectric layer thickness, dielectric constant, uniformity, stress level, index of refraction, other film properties, etc., for a given deposition process, defect density or the like). This type of information constitutes one example of feedback information. It will be understood that the first low K dielectric deposition process may be determined based on any other information, and may be determined at any time (e.g., before step 805).

The module controller 120 may determine a low K dielectric deposition process (or any other process described herein) in any suitable manner. For example, the module controller 120 may store (e.g., in the data storage device 206) a library of low K dielectric deposition processes each of which has been optimized for a particular low K dielectric interconnect feature density, interconnect feature dimension, interconnect feature profile, etc. Based on information about interconnect features to be formed and/or based on feedback information regarding one or more low K dielectric layers previously deposited within the first low K dielectric deposition chamber 314a or 314b, the module controller 120 may determine a low K dielectric deposition process by selecting the “most optimal” process from the library of stored low K dielectric deposition processes. Based on interconnect feature density, dimensions, profile, etc., to be formed on the substrate or based on feedback information regarding one or more low K dielectric layers previously deposited within the first low K dielectric deposition chamber 314a or 314b, the module controller 120 may adjust various process parameters of a selected low K dielectric deposition process to better match the low K dielectric interconnect that is to be formed.

Exemplary process parameters that may be adjusted for a low K dielectric deposition process include chamber base pressure, processing pressure, processing temperature, processing time, processing power, gas flow rates, deposition time, etc., which may affect one or more of thickness, dielectric constant, stress level, refractive index, defect density and uniformity of the deposited low K dielectric layer.

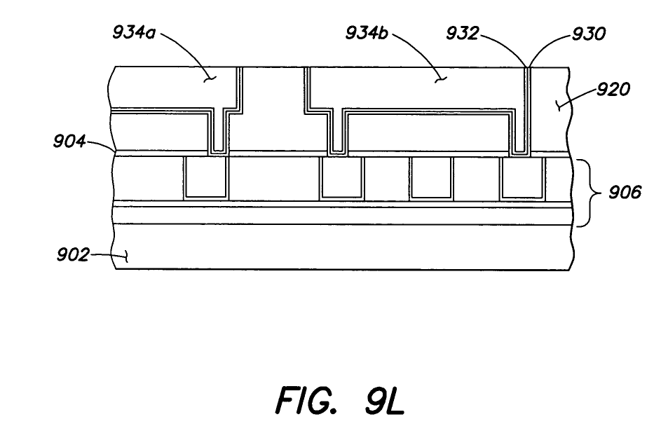

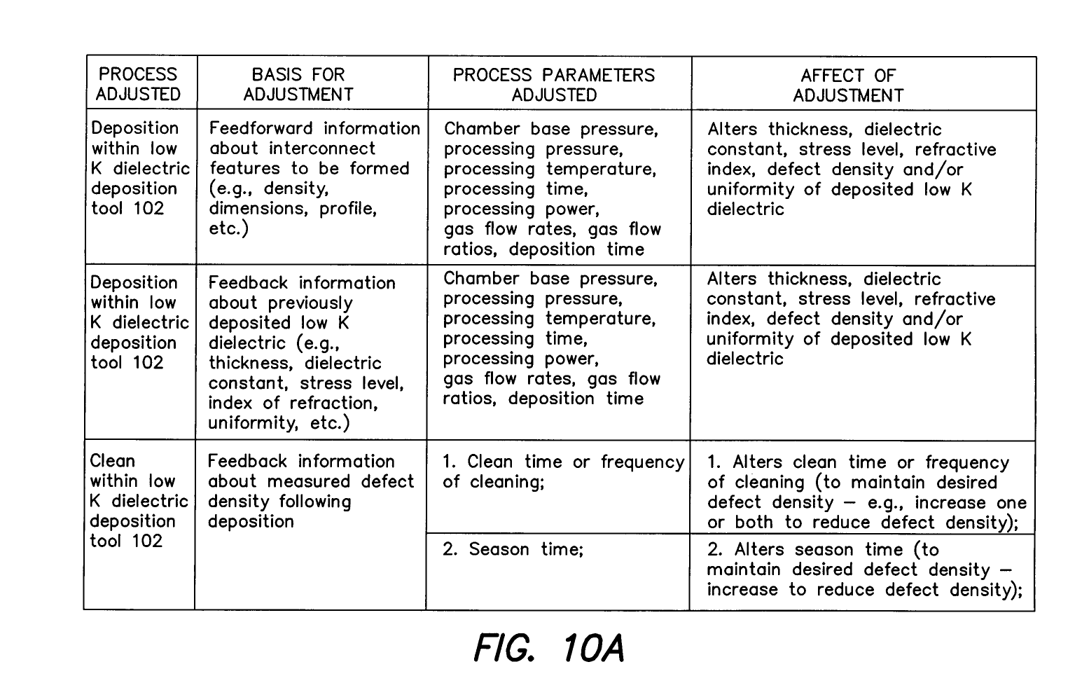

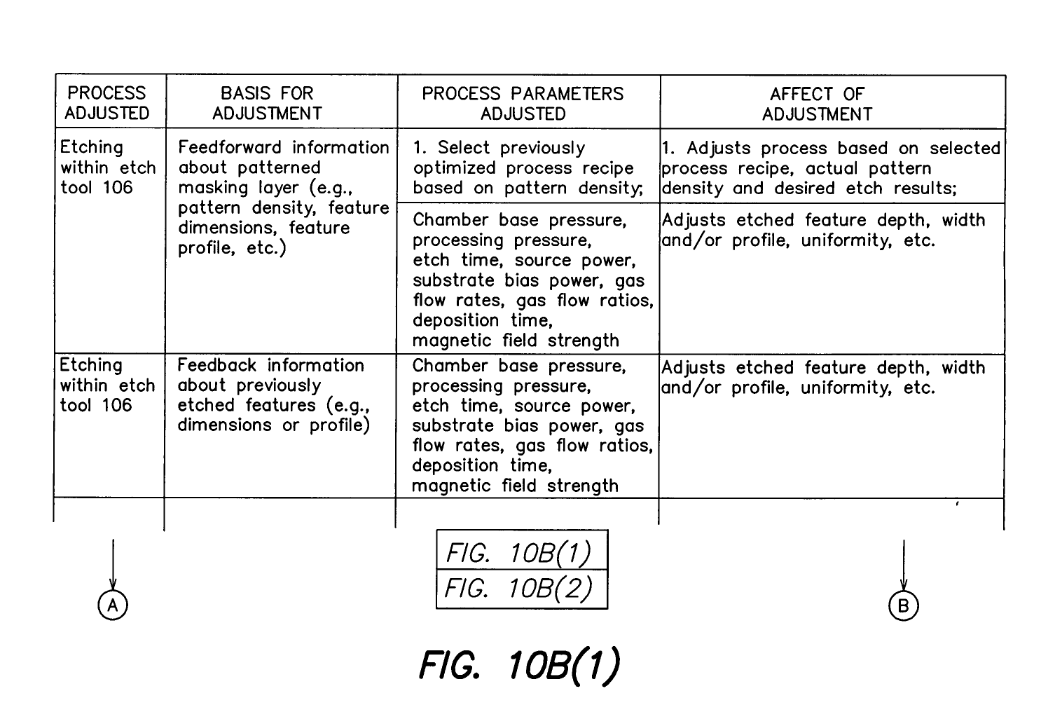

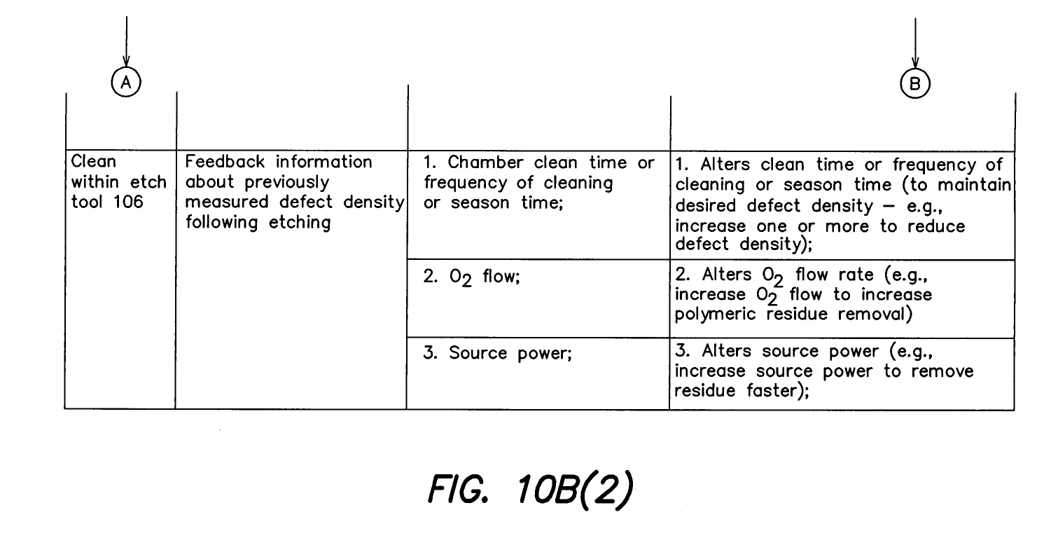

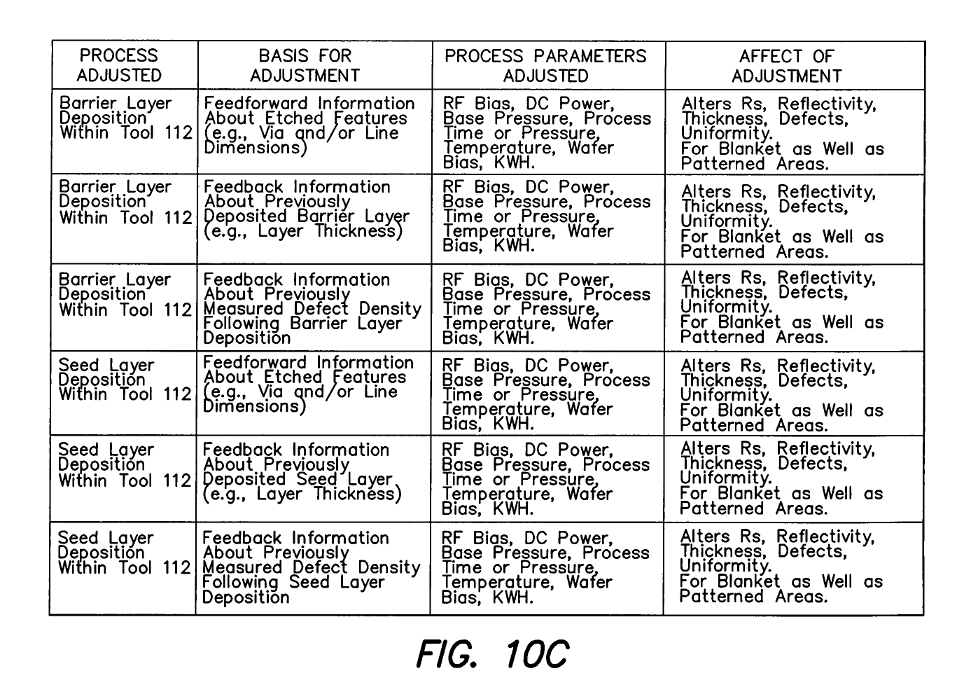

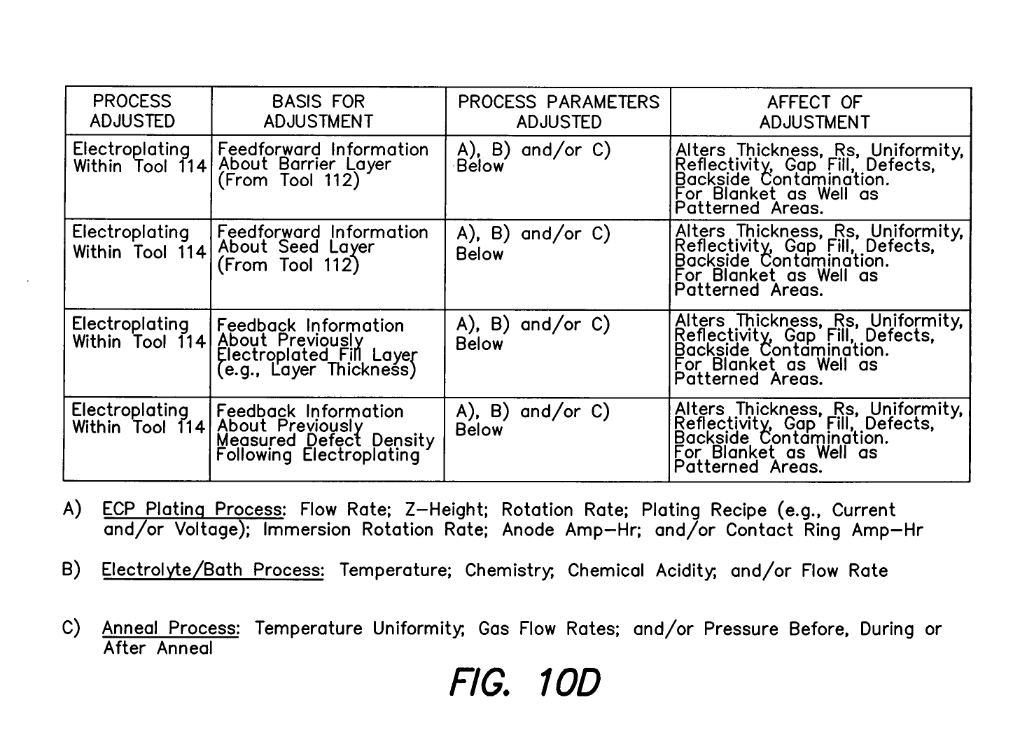

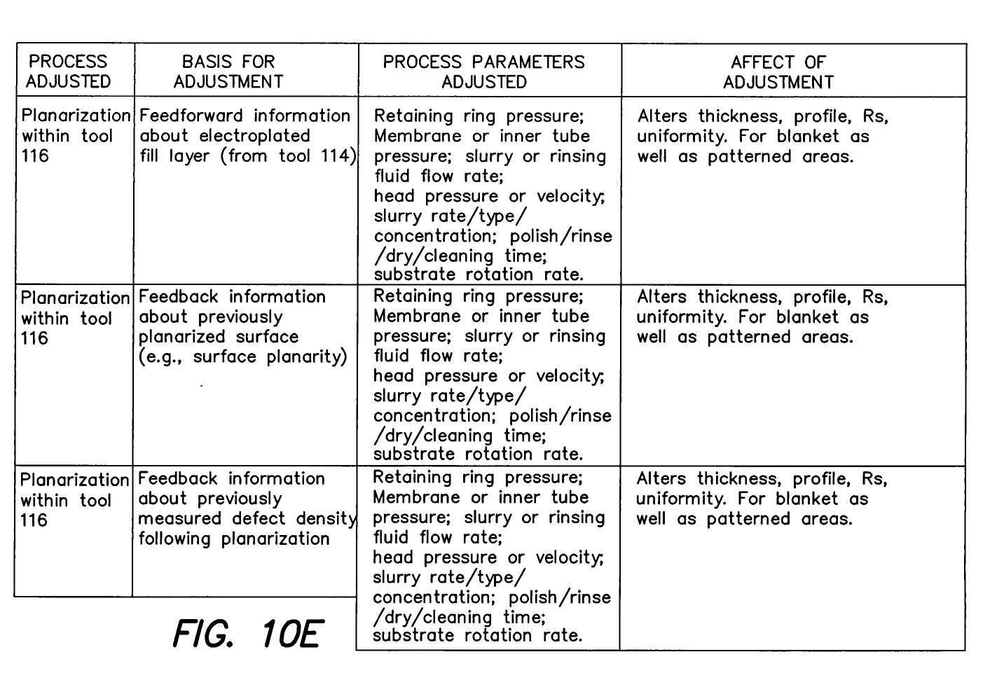

The module controller 120 may employ one or more algorithms (in addition to or in place of process libraries) for determining appropriate process parameters based on to be formed interconnect feature density, dimensions, profile, or other similar information. Likewise one or more process parameters may be adjusted based on feedback information regarding a low K dielectric layer previously deposited on a substrate (e.g., if the previously deposited layer is too thin, too thick, has too high of a defect density, or some other undesirable characteristic). FIG. 10A illustrates exemplary process parameters of a low K dielectric deposition process that may be adjusted based on feedforward and feedback information. These process parameters may be adjusted alone or in combination when determining a low K dielectric deposition process. Once a low K dielectric deposition process has been determined, in step 806, the module controller 120 directs the first low K dielectric deposition chamber 314a to deposit a first low K dielectric layer on the substrate based on the process.

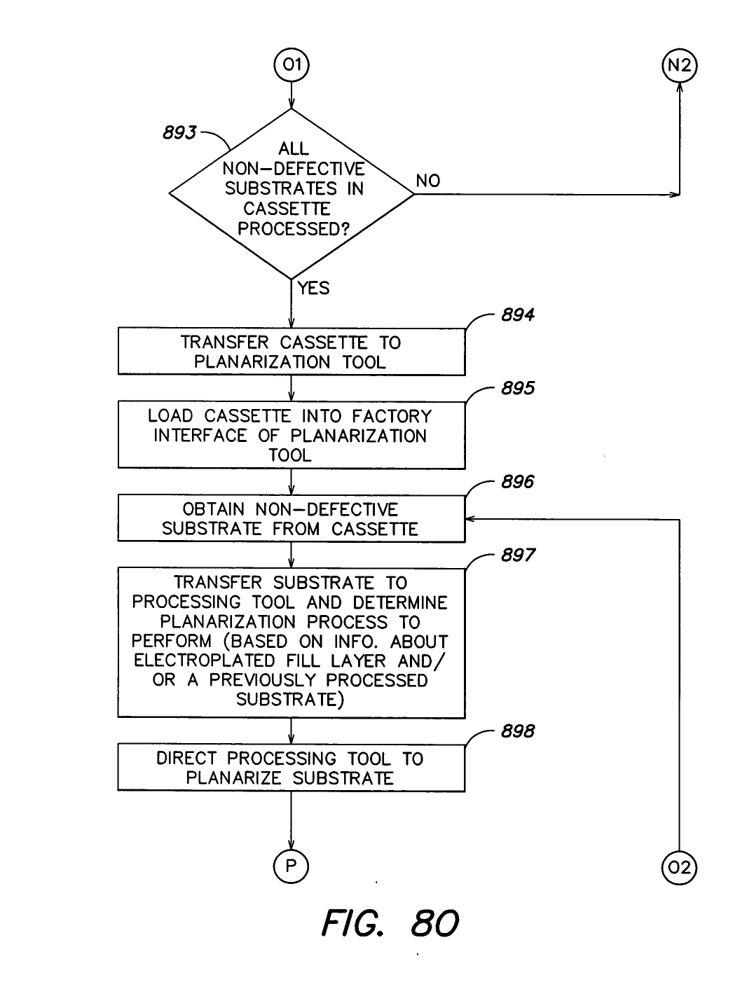

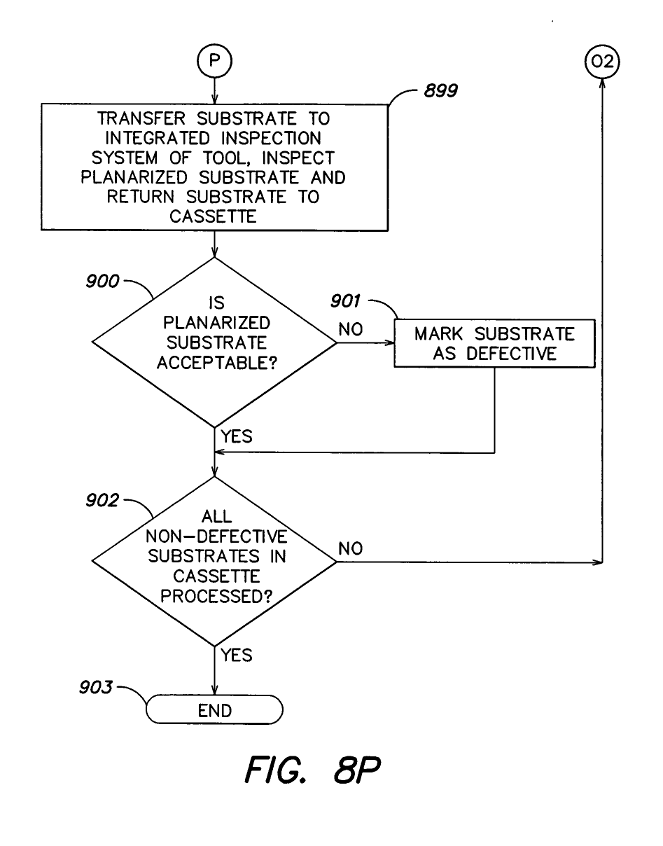

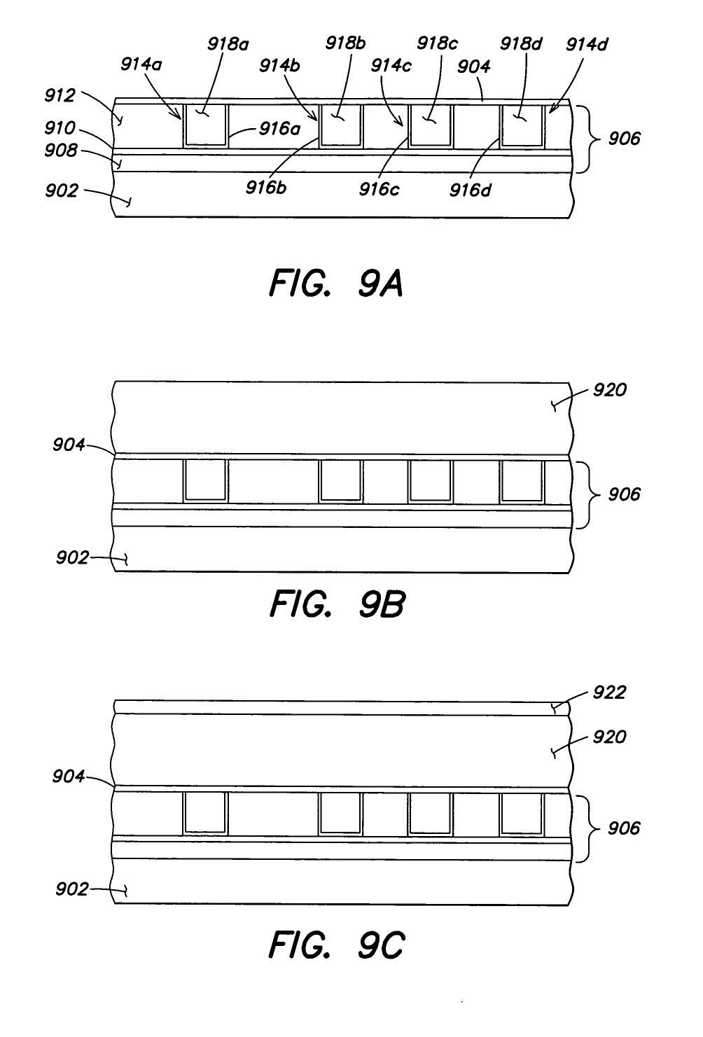

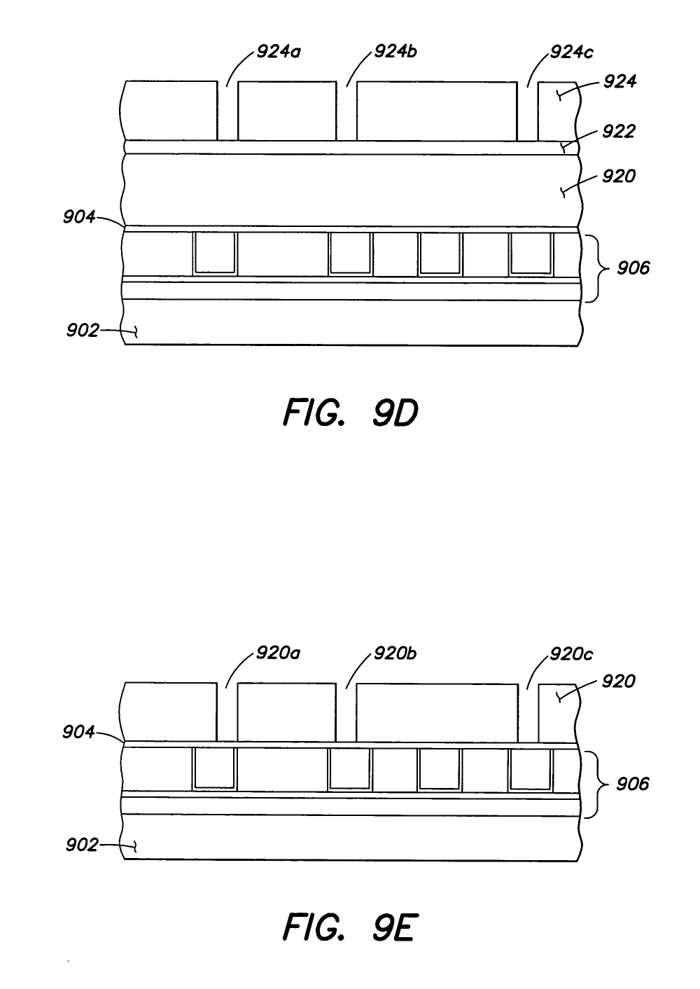

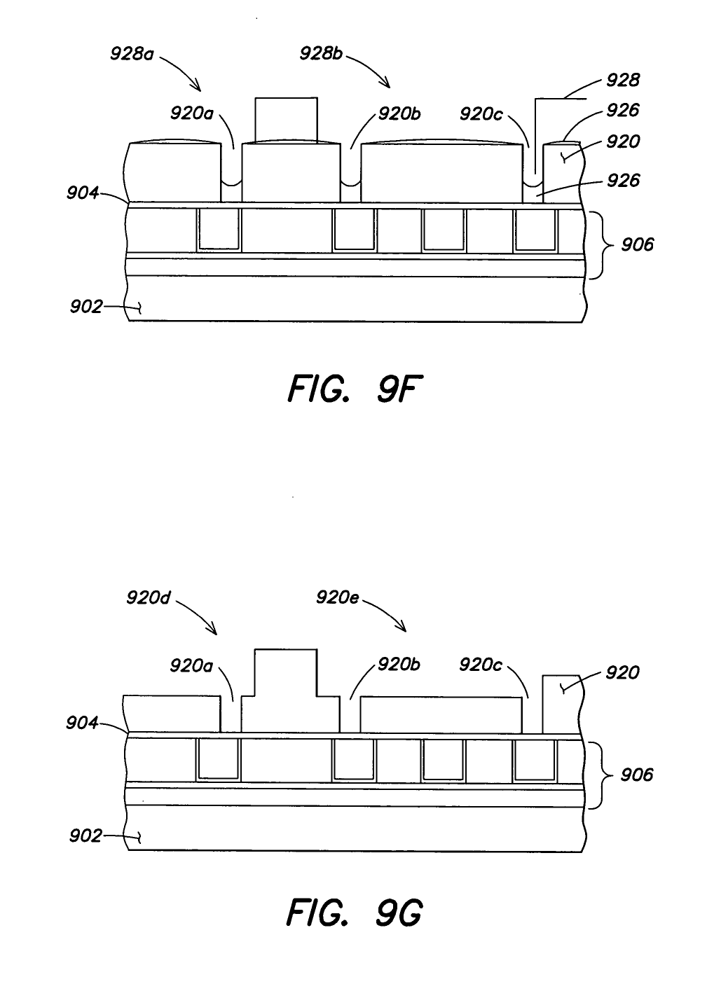

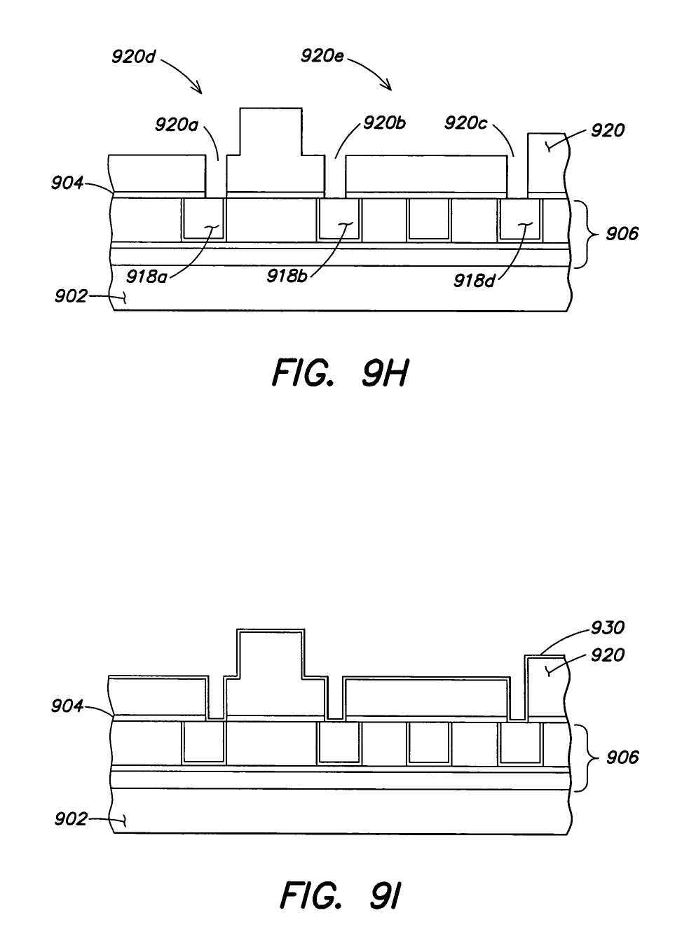

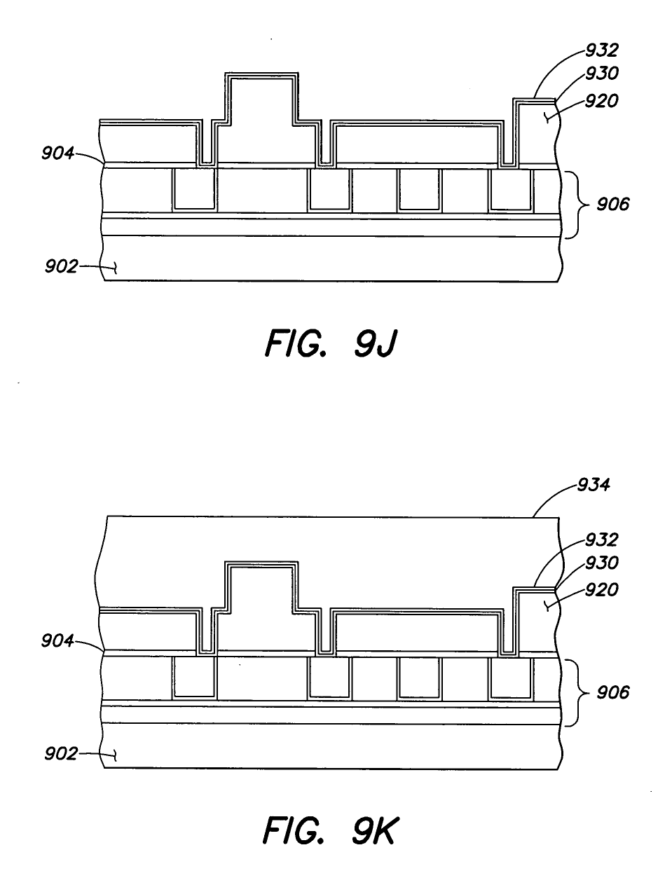

FIG. 9A illustrates an exemplary silicon substrate 902 having a first dual damascene or “T2” low K dielectric layer 904 formed over a single damascene or “T1” structure 906. The single damascene structure 906 may be formed within the inventive system 100 via a process similar to process 800. As shown in FIG. 9A, the single damascene structure 906 includes an oxide layer 908 formed on the silicon substrate 902, a first T1 low K dielectric layer 910 formed on the oxide layer 908, a second T1 low K dielectric layer 912 formed on the first T1 low K dielectric 910 and copper lines 914a-d formed within the second T1 low K dielectric layer 912. Each copper line 914a-d includes a barrier layer 916a-d which surrounds a copper plug 918a-d as shown. Each copper line 914a-d may include a copper seed layer (not separately shown in FIG. 9A).

The oxide layer 908 may be, for example, formed within the low K dielectric deposition tool 102 (e.g., by employing one or more oxide deposition chambers within the processing tool 302 of FIG. 3), as may be the first and second T1 low K dielectric layers 910, 912. In at least one embodiment, the oxide layer 908 comprises approximately 10,000 angstroms of undoped silicon oxide deposited by conventional methods. The oxide layer 908 may have, for example, a wafer-to-wafer thickness uniformity variation of less than about 5%, a within wafer uniformity variation of less than about 5%, a defect density of less than about thirty 0.2 micron or larger particles per 200 mm wafer, and a refractive index of about 1.46.

The first T1 low K dielectric layer 910 may comprise, for example, approximately 500 angstroms of a chemical vapor deposited (CVD) silicon carbide (e.g., Blok™). Such a dielectric layer may be deposited at a temperature of about 350° C. and a pressure of about 8.7 Torr for a time of less than about 1 minute; and may have, for example, a dielectric constant of about 4.8, a within wafer thickness uniformity variation of less than about 5%, a wafer-to-wafer uniformity variation of less than about 6%, a defect density of less than about thirty 0.2 micron or larger particles per 200 mm wafer, a stress level of about −2.5×10⁹ dyne/cm² compressive and a refractive index of about 1.95 (at a wavelength of 633 nanometers).

The second T1 low K dielectric layer 912 may comprise, for example, approximately 6500 angstroms of a CVD carbon doped oxide (e.g., Black Diamond™ (BD)). Such a dielectric layer may be deposited at a temperature of about 350° C. and a pressure of about 4 Torr for about 1 minute; and may have, for example, a dielectric constant of about 3.0, a within wafer thickness uniformity variation of less than about 5%, a wafer-to-wafer uniformity variation of less than about 6%, a defect density of less than about thirty 0.2 microns per 200 mm wafer, a stress level of about 5-6×10⁸ dyne/cm² compressive and a refractive index of about 1.42 (at a wavelength of 633 nanometers). The barrier layers 916a-d, the copper seed layers (not shown), and the copper plugs 918a-d may be formed similarly to those described below with reference to the process 800. Other thicknesses, dielectric constants, uniformities, defect densities, stress levels, refractive indices and materials also may be employed, as may other process parameters.

In at least one embodiment, the first T2 low K dielectric layer 904 comprises approximately 700 angstroms of a CVD silicon carbide (e.g., Blok™). Such a dielectric layer may be deposited at a temperature of about 350° C. and a pressure of about 8.7 Torr for a time of less than about 1 minute; may have, for example, a dielectric constant of about 4.8, a within wafer thickness uniformity variation of less than about 5%, a wafer-to-wafer uniformity variation of less than about 6%, a defect density of less than about thirty 0.2 microns per 200 mm wafer, a stress level of about −2.5×10⁹ dyne/cm² compressive and a refractive index of about 1.95 (at a wavelength of 633 nanometers). Other thicknesses, dielectric constants, uniformities, defect densities, stress levels, refractive indices and materials also may be employed, as may other process parameters.

Referring again to the process 800 of FIG. 8A, in step 807, following deposition of the first T2 low K dielectric layer 904 the substrate is transferred from the first low K dielectric deposition chamber 314a to the second low K dielectric deposition chamber 318a, and in step 808 the module controller 120 determines a second low K dielectric deposition process to perform on the substrate. The second low K dielectric deposition process may be based on, for example, information obtained from the integrated inspection system 330 of the low K dielectric deposition tool 102 for a low K dielectric layer previously deposited within the second low K dielectric deposition chamber 318a or 318b (e.g., information such as deposited dielectric layer thickness, dielectric constant, uniformity, stress level, index of refraction, other film properties, etc., for a given deposition process, defect density or the like). It will be understood that the second low K dielectric deposition process may be determined based on any other information, and may be determined at any time (e.g., before step 808).

As with the first low K dielectric deposition process, the module controller 120 may store a library of second low K dielectric deposition processes each of which has been optimized for a particular interconnect feature density, interconnect dimension, interconnect profile, etc. Based on information about the interconnect features which are to be formed on the substrate and/or based on the first low K dielectric layer deposited on the substrate within the first low K dielectric deposition chamber 314a or 314b, the module controller 120 may determine a second low K dielectric layer deposition process and/or vary process parameters accordingly. Likewise one or more process parameters may be adjusted based on feedback information regarding a second low K dielectric layer previously deposited on a substrate within the low K dielectric deposition tool 102 (e.g., if the previously deposited low K dielectric layer is too thin, too thick, has too high of a defect density, etc.).

Exemplary process parameters that may be adjusted for a low K dielectric deposition process include chamber base pressure, processing pressure, processing temperature, processing time, processing power, gas flow rates, deposition time, etc., which may affect one or more of thickness, dielectric constant, stress level, refractive index, defect density and uniformity of the deposited low K dielectric layer. The above process parameters are summarized in FIG. 10A and may be adjusted alone or in combination when determining a low K dielectric deposition process to perform.

Once a second low K dielectric deposition process has been determined, in step 809, the module controller 120 directs the second low K dielectric deposition chamber 318a to deposit a second low K dielectric layer on the substrate based on the process.

FIG. 9B illustrates the substrate 902 having a second T2 low K dielectric layer 920 formed over the first T2 low K dielectric layer 904 within the second low K dielectric deposition chamber 318a. In at least one embodiment, the second T2 low K dielectric layer 920 comprises approximately 11000 angstroms of a CVD carbon doped oxide (e.g., Black Diamond™ (BD)). Such a dielectric layer may be deposited at a temperature of about 350° C. and a pressure of about 4 Torr for about 1 minute; and may have, for example, a dielectric constant of about 3.0, a within wafer thickness uniformity variation of less than about 5%, a wafer-to-wafer uniformity variation of less than about 6%, a defect density of less than about thirty 0.2 microns per 200 mm wafer, a stress level of about 5-6×10⁸ dyne/cm² compressive and a refractive index of about 1.42 (at a wavelength of 633 nanometers). Other thicknesses, dielectric constants, uniformities, defect densities, stress levels, refractive indices and materials also may be employed, as may other process parameters.

In step 810, the substrate is transferred from the second low K dielectric deposition chamber 318a to the factory interface 304 (unless an anti-reflection coating is first deposited on the substrate within one of the chambers 322a, 322b), and the substrate is inspected via the integrated inspection system 330. For example, the substrate may be inspected via the defect detection tool 332a to determine the number of defects present on the surface of the substrate following low K dielectric layer deposition within the second low K dielectric deposition chamber 318a and/or may be inspected within the metrology tool 334 to determine the thickness, dielectric constant, uniformity, stress level, refractive index, etc., of the first and/or the second low K dielectric layers deposited within the low K dielectric deposition tool 102 (e.g., the first and second T2 low K dielectric layers 904, 920). Similar information may be obtained regarding any anti-reflection coating deposited on the substrate within the anti-reflection coating deposition chambers 322a, 322b. Information regarding the substrate then is communicated to the module controller 120; and the substrate is returned to the substrate cassette from which it was extracted.

In step 811 the module controller 120 determines whether the substrate is acceptable (e.g., if the defect density on the surface of the substrate is within an acceptable limit, if one or more of the deposited low K dielectric layers have an acceptable thicknesses, uniformities, indices of refraction, stress levels, etc.). If one or more of the deposited low K dielectric layers are not acceptable, in step 812, the module controller 120 marks the substrate as defective and the process 800 proceeds to step 813; otherwise following step 811, the process 800 proceeds directly to step 813.

In step 813, the module controller 120 determines if all substrates in the substrate cassette have been processed. If all substrates in the substrate cassette have not been processed, the process 800 returns to step 803 to obtain another substrate from the cassette to process as described previously; otherwise the process 800 proceeds to step 814.

In step 814, the substrate cassette is transferred from the low K dielectric deposition tool 102 to the lithography tool 104. As stated, the lithography tool 104 may include, for example, an FSI P2500 system manufactured by FSI International, Inc. for depositing an anti-reflection coating such as a bottom anti-reflection coating (BARC) layer, a DNS-80B system manufactured by Dai Nippon Screen for forming a uniform photoresist layer over the surface of a substrate, an ASML-5500/90 photoresist exposure system manufactured by ASM Lithography Inc. for exposing a photoresist layer to a desired mask pattern, and a DNS system manufactured by Dai Nippon Screen for developing the exposed photoresist layer (thereby forming the desired patterned masking layer). Such lithography tools are well known in the art; and any other conventional lithography tool may be similarly employed.

In step 815, a masking layer is deposited on and is patterned for each non-defective substrate within the substrate cassette. In at least one embodiment of the invention, in step 815, each non-defective substrate is processed as follows:
1. approximately 800 angstroms of BARC are deposited on the substrate (e.g., a BARC layer 922 in FIG. 9C);
2. approximately 6600 angstroms of photoresist (e.g., TOK P419 manufactured by TOK or a similar resist) are deposited on the substrate (e.g., a photoresist layer 924 shown patterned in FIG. 9D); and
3. the photoresist is patterned (e.g., exposed and developed) to form one or more patterned masking layer features (e.g., patterned masking layer features 924a-c in FIG. 9D) for subsequent etching of the second T2 low K dielectric layer 920 as described below.
   It will be understood that one or more conventional soft or hard bake or other curing procedures may be employed during patterned masking layer formation. Other lithographic processes also may be employed.

Once each non-defect substrate within the substrate cassette has had a masking layer formed thereon, in step 816, the substrate cassette is transferred to the etch tool 106; and the substrate cassette is loaded into the factory interface 404 of the etch tool 106. For example, the substrate cassette may be loaded into one of the loadports 420a-d of the factory interface 404.

In step 817, a substrate is extracted from the substrate cassette and in step 818, the patterned masking layer of the substrate (e.g., the patterned masking layer 924 formed on the substrate by the lithography tool 104 as previously described, and used to define the regions of the second T2 low K dielectric layer 920 to be etched) is inspected via the integrated inspection system 422. Assuming the etch tool 106 of FIG. 4A is employed within the system 100, steps 817 and 818 may be performed by employing the substrate handler 418 to extract a substrate from the substrate cassette (located within one of the loadports 420a-d), and by transferring the substrate to the metrology tool 424b via the substrate handler 418. Thereafter the metrology tool 424b may inspect the substrate's patterned masking layer and may communicate information about the patterned masking layer to the module controller 120. For example, the metrology tool 424b may communicate information such as pattern density, patterned masking layer feature information (e.g., size, profile or the like), etc., for the features 924a-b of FIG. 9D to the module controller 120.

An integrated metrology tool (not shown) similarly may be coupled to the lithography tool 104 and employed to measure and communicate patterned masking layer information to the module controller 120 in place of or in addition to the metrology tool 424b of the etch tool 106. Likewise, a standalone metrology tool (not shown) may also be employed. One such stand alone metrology tool is the SEM 7830 SI critical dimension scanning electron microscope (CD-SEM) manufactured by Applied Materials, Inc.

After information regarding the substrate's patterned masking layer has been communicated to the module controller 120 (in step 818), in step 819 the module controller 120 determines whether the patterned masking layer formed on the substrate is acceptable. For example, the module controller 120 may determine that the patterned masking layer (e.g., the patterned photoresist layer 924) is overpatterned (e.g., has features 924a-c that will result in second T2 low K dielectric layer 920 features that are too wide) or underpatterned (e.g., has features 924a-c that will result in second T2 low K dielectric layer 920 features that are too narrow). If the patterned masking layer on the substrate is not acceptable, the substrate is returned to the substrate cassette and marked as a defective substrate (step 820) and the process 800 proceeds to step 821; otherwise the process 800 proceeds directly to step 821. Defective substrates, for example, may be sorted and returned to the lithography tool 104 for re-processing after all substrates within the substrate cassette have been processed within the etch tool 106. In at least one embodiment, the target width for the features 924a-c is about 0.27-0.29 microns with a uniformity variation of less than 10%, although any other suitable feature dimensions/uniformity variations may be employed.

In step 821, the substrate is transferred from the factory interface 404 to one of the etch chambers 412a-d (e.g., via the substrate handler 408). In step 822, the module controller 120 determines an etch process to perform on the substrate within the appropriate etch chamber 412a-d based on, for example, the information obtained about the patterned masking layer formed on the substrate (e.g., pattern density information, dimensions and/or profile of features of the patterned masking layer which may influence etch dimensions/profile, etc.). This type of information constitutes one example of feedforward information. It will be understood that the etch process may be determined based on patterned masking layer information (or other feedforward information) at any time after the information is received from the metrology tool 424b (or any other metrology tool).

The etch process alternatively or additionally may be based on, for example, information obtained from the integrated inspection system 422 for a substrate previously etched within one of the etch chambers 412a-d (e.g., information such as etched feature dimensions/profile that resulted for a given etch process). This type of information constitutes feedback information.

The module controller 120 may determine an etch process (or any other process described herein) in any suitable manner. For example, the module controller 120 may store (e.g., in the data storage device 206) a library of etch processes each of which has been optimized for a particular patterned masking layer density, feature dimensions, feature profile, etc. Based on feedforward information about the patterned masking layer, and/or based on other feedforward information, the module controller 120 may determine an etch process by selecting the “most optimal” process from the library of stored etch processes. Based on actual patterned masking layer density, feature dimensions, feature profile or other feedforward information, the module controller 120 may adjust various process parameters of a selected etch process to better match the characteristics of the substrate.

Exemplary process parameters that may be adjusted for an etch process include source power, substrate bias power, processing pressure, processing temperature, processing time, process gas flow rates, etc., which may affect one or more of etched feature dimensions (e.g., width or depth), etched feature profile, etch rate, etch uniformity, etc.

In one exemplary embodiment, when the BARC layer 922 and the photoresist layer 924 are employed (e.g., as shown in FIG. 9D), an O₂ etch process is employed to etch the BARC layer 922, and a CF₄, N₂, CO, Ar, and/or CHF₃ etch process is employed to etch the second T2 low K dielectric layer 920 to expose the underlying first T2 low K dielectric layer 904. In such an etch process, the module controller 120 may, for example, based on feedforward information about a patterned masking layer and/or feedback information about a previously etched substrate, adjust etched feature dimensions/profile by adjusting CHF₃, O₂ and/or other etch gas flow rates, chamber pressure (e.g., processing pressure), etch time, source power, substrate bias power, etc., during etching of the second T2 low K dielectric layer 920.

In another embodiment, the module controller 120 may compare a dimension of a feature of a patterned masking layer (i.e., a feedforward feature dimension) to a target feature dimension (e.g., a desired or ideal feature dimension of a patterned masking layer). For example, the module controller 120 may compare the feedforward feature dimension to a range of acceptable feature dimensions or some other applicable control limit (CL), such as a device specification. Assuming the feedforward feature dimension is within the desired/acceptable range, the module controller 120 then may determine if an etch process suitable for etching a substrate having a patterned masking layer with the target feature dimension may be adjusted to correct for any deviation between the feedforward feature dimension and the target feature dimension (e.g., whether any required process adjustment is within the range or control limit of acceptable process adjustments). If so, then the module controller 120 may adjust the etch process accordingly.

Assuming the feedforward feature dimension is width, if the feedforward feature width of the patterned masking layer is smaller or larger than the target feature width, then the module controller 120 may increase or decrease etch gas (e.g., CHF₃, O₂, etc.) and/or other gas (e.g., Ar, N₂, etc.) flow rates and/or ratios during etching of the second T2 low K dielectric layer 920 and/or the BARC layer 922 to compensate for the smaller or larger than desired patterned masking layer feature width. The module controller 120 also may compensate for smaller or larger patterned masking layer feature width by increasing or decreasing overetch time, chamber pressure, bias power, source power and/or the like during etching of the second T2 low K dielectric layer 920 and/or the BARC layer 922. Other techniques may be similarly employed.

In another embodiment, an etch process may be determined based on feedback information regarding a previously etched substrate. A characteristic of an etched feature of the previously etched substrate (i.e., a feedback etched feature characteristic) is compared to a target etched feature characteristic (e.g., a desired or ideal etched feature characteristic). The module controller 120 then may determine an etch process based on the etch process used to etch the previous substrate (e.g., by adjusting certain etch parameters of the process). For example, assume the feedback etched feature characteristic is etched feature width. If the feedback etched feature width (of the previously etched substrate) is smaller or larger than the target etched feature width, then the module controller 120 may increase or decrease etched feature width for subsequently etched substrates by increasing or decreasing etch gas and/or other gas flow rates and/or ratios during etching of the second T2 low K dielectric layer 920 and/or the BARC layer 922. The module controller 120 similarly may compensate by increasing or decreasing overetch time, chamber pressure, bias power, source power and/or the like during etching of the second T2 low K dielectric layer 920 and/or the BARC layer 922. Other techniques may be similarly employed.

As another example, assume that the feedback etched feature characteristic is etched feature profile. If the etched feature profile of the previously etched substrate is less or more vertical than the target profile, then the module controller 120 may increase or decrease etched feature profile angle for subsequently etched substrates by adjusting etch gas and/or other gas flow rates and/or ratios during etching of the second T2 low K dielectric layer 920. Other exemplary feedback information that may be employed to affect an etch process includes (1) etch depth to affect etch time (e.g., which may be increased to increase etch depth); and/or (2) within-wafer etch uniformity to affect magnetic field strength (e.g., to improve uniformity as described further below).

The module controller 120 may employ one or more algorithms (in addition to or in place of process libraries) for determining appropriate process parameters based on patterned masking layer density, feature dimensions, feature profile, or other feedforward information. Likewise one or more process parameters may be adjusted via algorithms based on feedback information regarding a substrate previously etched within the etch tool 106 (e.g., if previously formed etch features were too deep, too shallow, too narrow, too wide, had an undesirable profile, if a previously etched substrate had too high of a defect density, or some other undesirable characteristic).

In one embodiment, feedback information regarding the defect density of a previously etched substrate may be employed to affect the length of time and/or how often an etch chamber is cleaned following etching or seasoned following chamber maintenance, O₂ flow or source power during patterned masking layer removal (e.g., during ashing), etc., so as to reduce defect density, polymeric residue and the like. For example, defect density feedback information may be used to determine when to perform an etch chamber clean (e.g., if defect density exceeds a predetermined threshold). In this manner, an etch chamber need not be cleaned prematurely. This may reduce the number of chamber cleanings (and thus chamber seasonings) that are performed and thus decrease chamber downtime. FIG. 10B(1) and FIG. 10B(2) illustrate exemplary process parameters of an etch process that may be adjusted based on feedforward and feedback information. These process parameters may be adjusted alone or in combination when determining an etch process.

It will be understood that information regarding a patterned masking layer present on a substrate may be used to affect other processing tools such as the lithography tool 104 used to define the patterned masking layer. For example, the module controller 120 (or some other module controller) may adjust, based on feedback information about the patterned masking layer formed by a given lithography process, one or more parameters of the lithography process to affect future patterned masking layer formation. Adjustable process parameters of the lithography tool 104 used to form a patterned masking layer include, for example, soft/hard bake times, dose of a lithographic process, exposure time, development time, masking layer deposition time, spin rates, etc.

Referring again to FIGS. 8A-P, once an etch process has been determined, in step 823, the module controller 120 directs the etch tool 106 to etch the substrate based on the etch process. In step 824, the module controller 120 directs the etch tool 106 to remove the patterned masking layer from the substrate. For example, if the patterned masking layer is formed from photoresist, any conventional technique may be employed to remove the patterned masking layer (e.g., such as the use of an oxygen plasma, often referred to as “ashing”). In general, ashing may be performed in-situ (e.g., within one of the etch chambers 412a-d), or ex-situ (e.g., within a separate ashing chamber (not shown)).

FIG. 9E illustrates the second T2 low K dielectric layer 920 following etching and removal of the patterned masking layer 924 and the BARC layer 922. The BARC layer 922 may be removed by, for example, an O₂ plasma. As shown in FIG. 9E, etched features 920a-c are formed within the second T2 low K dielectric layer 920 which expose the underlying first T2 low K dielectric layer 904. Additionally, when photoresist is employed as the masking layer 924, residual polymeric material (not shown) may remain on the sidewalls of the etched features 920a-c (which may subsequently be removed via the cleaning tool 108 as described further below). Preferably little or no ash residue remains and the defect density of the substrate 902 following ashing is less than fifty 0.16 micron particles per 200 mm wafer. Typical etched features 920a-c may have profiles of 88-90 degrees (e.g., near vertical profiles). Other defect densities or etched feature profiles may be employed.

In step 825, the substrate is transferred from one of the etch chambers 412a-d to the factory interface 404. In step 826 the substrate may be inspected via the integrated inspection system 422. For example, the substrate may be inspected via the defect detection tool 424a to determine the number of defects present on the surface of the substrate following etching and/or may be inspected within the metrology tool 424b to determine the dimensions, profile or other critical dimension information relevant to the features etched within the second T2 low K dielectric layer 920. Information regarding the substrate is communicated to the module controller 120.

In step 827 the module controller 120 determines whether the etched substrate is acceptable (e.g., if the defect level on the surface of the substrate is within an acceptable limit, if the features etched within the second T2 low K dielectric layer 920 have acceptable depths, widths, profiles, etc.). If the etched substrate is not acceptable, in step 828, the module controller 120 marks (e.g., records that) the substrate is defective and the process 800 proceeds to step 829; otherwise following step 827, the process 800 proceeds directly to step 829.

In step 829, the module controller 120 determines if all non-defective substrates in the substrate cassette have been etched. If all non-defective substrates in the substrate cassette have not been etched, the process 800 returns to step 817 to obtain another substrate from the cassette to etch as described previously; otherwise the process 800 proceeds to step 830.

Following etching of all substrates within the substrate cassette, in step 830 the substrate cassette is transferred from the etch tool 106 to the cleaning tool 108 (e.g., via a technician, an automated guided vehicle, an overhead carrier system, etc.). Thereafter, in step 831, the module controller 120 directs the cleaning tool 108 to clean each non-defective substrate within the substrate cassette using conventional cleaning techniques. For example, one or more wet cleaning techniques may be used that employ dilute hydrofluoric acid, Marangoni drying, megasonic cleaning, etc., whether done on a single substrate or on a batch of substrates. The cleaning tool 108 may be employed, for example, to remove any residual polymeric material that remains following removal of the patterned masking layer employed during the etching of each substrate. In at least one embodiment of the invention, the cleaning tool 108 comprises a WPS/AKRION wet bench manufactured by Akrion.

In step 832 the substrate cassette is transferred from the cleaning tool 108 back to the lithography tool 104. Prior to arrival at the lithography tool 104, one or more non-defective substrates within the substrate cassette may be inspected within a stand-alone or integrated metrology and/or defect detection tool (not shown) to determine one or more of defect density, etched feature dimensions/profile, whether all polymeric residue has been removed, etc., following cleaning within the cleaning tool 108. One exemplary stand-alone metrology tool suitable for measuring etched feature dimensions/profile is the SEM 7830SI critical dimension scanning electron microscope (CD-SEM) manufactured by Applied Materials, Inc. One exemplary stand-alone defect detection tool suitable for measuring defect density is the WF736 DUO defect detection system also manufactured by Applied Materials, Inc. Other similar tools may be employed. In step 833, a masking layer is deposited on and is patterned for each non-defective substrate within the substrate cassette.

In at least one embodiment of the invention, in step 833, each non-defective substrate is processed as follows:
1. approximately 800 angstroms of BARC are deposited on the substrate (e.g., a BARC layer 926 in FIG. 9F which fills a portion of each etched feature 920a-c as shown);
2. approximately 7000 angstroms of photoresist (e.g., about 400 angstroms of TOK TGF-Tr2 and about 6600 angstroms of TOK P419 manufactured by TOK or a similar resist) are deposited on the substrate (e.g., a photoresist layer 928 shown patterned in FIG. 9F); and
3. the photoresist is patterned (e.g., exposed and developed) to form one or more patterned masking layer features (e.g., patterned masking layer features 928a-b in FIG. 9F) for subsequent etching of the second T2 low K dielectric layer 920 as described below.
   It will be understood that one or more conventional soft or hard bake or other curing procedures may be employed during patterned masking layer formation. Other lithographic processes also may be employed.

Once each non-defect substrate within the substrate cassette has had a masking layer formed thereon, in step 834, the substrate cassette is transferred to the etch tool 106; and the substrate cassette is loaded into the factory interface 404 of the etch tool 106. For example, the substrate cassette may be loaded into one of the loadports 420a-d of the factory interface 404.

In step 835, a substrate is extracted from the substrate cassette and in step 836, the patterned masking layer (e.g., the patterned masking layer 928 formed on the substrate by the lithography tool 104 as previously described and used to define second regions of the second T2 low K dielectric layer 920 to be etched) is inspected via the integrated inspection system 422. Assuming the etch tool 106 of FIG. 4A is employed within the system 100, steps 835 and 836 may be performed by employing the substrate handler 418 to extract a substrate from the substrate cassette (located within one of the loadports 420a-d), and by transferring the substrate to the metrology tool 424b via the substrate handler 418. Thereafter the metrology tool 424b may inspect the substrate's patterned masking layer and may communicate information about the patterned masking layer 928 to the module controller 120. For example, the metrology tool 424b may communicate information such as pattern density, patterned masking layer feature information (e.g., size, profile or the like), etc., for the features 928a-b of FIG. 9F to the module controller 120.

An integrated metrology tool (not shown) similarly may be coupled to the lithography tool 104 and employed to measure and communicate patterned masking layer information to the module controller 120 in place of or in addition to the metrology tool 424b of the etch tool 106. Likewise, a stand-alone metrology tool (not shown) may also be employed.

After information regarding the substrate's patterned masking layer has been communicated to the module controller 120 (in step 836), in step 837 the module controller 120 determines whether the patterned masking layer formed on the substrate is acceptable. For example, the module controller 120 may determine that the patterned masking layer (e.g., the patterned photoresist layer 928) is overpatterned (e.g., has features 928a-b that will result in second T2 low K dielectric layer 920 features that are too wide) or underpatterned (e.g., has features 928a-b that will result in second T2 low K dielectric layer 920 features that are too narrow). If the patterned masking layer on the substrate is not acceptable, the substrate is returned to the substrate cassette and marked as a defective substrate (step 838) and the process 800 proceeds to step 839; otherwise the process 800 proceeds directly to step 839. Defective substrates, for example, may be sorted and returned to the lithography tool 104 for re-processing after all substrates within the substrate cassette have been processed within the etch tool 106. In at least one embodiment, the target width for the features 928a-b is about 0.33-0.35 microns with a uniformity variation of less than 10%, although any other suitable feature dimensions/uniformity variations may be employed.

In step 839, the substrate is transferred from the factory interface 404 to one of the etch chambers 412a-d (e.g., via the substrate handler 408). In step 840, the module controller 120 determines an etch process to perform on the substrate within the appropriate etch chamber 412a-d based on, for example, the information obtained about the patterned masking layer formed on the substrate (e.g., pattern density information, dimensions and/or profile of features of the patterned masking layer which may influence etched feature dimensions/profile, etc.) as described previously with reference to step 822. It will be understood that the etch process may be determined based on patterned masking layer information (or other feedforward information) at any time after the information is received from the metrology tool 424b (or any other metrology tool).

The etch process alternatively or additionally may be based on, for example, information obtained from the integrated inspection system 422 for a substrate previously etched within one of the etch chambers 412a-d (e.g., information such as etched feature dimensions/profile that resulted for a given etch process) as described previously with reference to step 822. FIG. 10B(1) and FIG. 10B(2) illustrate exemplary process parameters of an etch process that may be adjusted based on feedforward and feedback information. As stated, these process parameters may be adjusted alone or in combination when determining an etch process.

Once an etch process has been determined, in step 841, the module controller 120 directs the etch tool 106 to etch the substrate based on the etch process. In step 842, the module controller 120 directs the etch tool 106 to remove the patterned masking layer from the substrate. For example, if the patterned masking layer is formed from photoresist, any conventional technique may be employed to remove the patterned masking layer (e.g., such as the use of an oxygen plasma to perm ashing). In general, ashing may be performed in-situ (e.g., within one of the etch chambers 412a-d) or ex-situ (e.g., within a separate ashing chamber (not shown)).

FIG. 9G illustrates the second T2 low K dielectric layer 920 following etching and removal of the patterned masking layer 928 and the BARC layer 926. As shown in FIG. 9G, etched features 920d-e (e.g., lines 920d-e) are formed within the second T2 low K dielectric layer 920 in addition to the previously formed etched features 920a-c (e.g., via 920a-c) which expose the underlying first T2 low K dielectric layer 904.

When photoresist is employed as the masking layer 928, residual polymeric material (not shown) may remain on the sidewalls of the etched features 920d-e (which may subsequently be removed via the cleaning tool 108 as described further below). Preferably little or no ash residue remains and the defect density of the substrate 902 following ashing is less than fifty 0.16 micron particles per 200 mm wafer. Typical etched features 920d-e may have profiles of 88-90 degrees (e.g., near vertical profiles). Other defect densities or etched feature profiles may be employed.

In step 843, the substrate is transferred from one of the etch chambers 412a-d to the factory interface 404. In step 844 the substrate may be inspected via the integrated inspection system 422. For example, the substrate may be inspected via the defect detection tool 424a to determine the number of defects present on the surface of the substrate following etching and/or may be inspected within the metrology tool 424b to determine the dimensions, profile or other critical dimension information relevant to the features etched within the second T2 low K dielectric layer 920. Information regarding the substrate is communicated to the module controller 120.

In step 845 the module controller 120 determines whether the etched substrate is acceptable (e.g., if the defect level on the surface of the substrate is within an acceptable limit, if the features etched within the second T2 low K dielectric layer 920 have acceptable depths, widths, profiles, etc.). If the etched substrate is not acceptable, in step 846, the module controller 120 marks (e.g., records that) the substrate is defective and the process 800 proceeds to step 847; otherwise following step 845, the process 800 proceeds directly to step 847.

In step 847, the module controller 120 determines if all non-defective substrates in the substrate cassette have been etched. If all non-defective substrates in the substrate cassette have not been etched, the process 800 returns to step 835 to obtain another substrate from the cassette to etch as described previously; otherwise the process 800 proceeds to step 848.

Following etching of all substrates within the substrate cassette, in step 848 the substrate cassette is transferred from the etch tool 106 to the cleaning tool 108 (e.g., via a technician, an automated guided vehicle, an overhead carrier system, etc.). Thereafter, in step 849, the module controller 120 directs the cleaning tool 108 to clean each non-defective substrate within the substrate cassette using conventional cleaning techniques. For example, one or more wet cleaning techniques may be used that employ dilute hydrofluoric acid, Marangoni drying, megasonic cleaning, etc., whether done on a single substrate or on a batch of substrates. The cleaning tool 108 may be employed, for example, to remove any residual polymeric material that remains following removal of the patterned masking layer employed during the etching of each substrate. In at least one embodiment of the invention, the cleaning tool 108 comprises a WPS/AKRION wet bench manufactured by Akrion.

In step 850 the substrate cassette is transferred from the cleaning tool 108 back to the etch tool 106. Prior to arrival at the etch tool 106, one or more non-defective substrates within the substrate cassette may be inspected within a stand-alone or integrated metrology and/or defect detection tool (not shown) to determine one or more of defect density, etched feature dimensions/profile, whether all polymeric residue has been removed, etc., following cleaning within the cleaning tool 108. As stated, one exemplary stand-alone metrology tool suitable for measuring etched feature dimensions/profile is the SEM 7830SI critical dimension scanning electron microscope (CD-SEM) manufactured by Applied Materials, Inc. One exemplary stand-alone defect detection tool suitable for measuring defect density is the WF736 DUO defect detection system also manufactured by Applied Materials, Inc. Other similar tools may be employed.

At the etch tool 106, the substrate cassette is loaded into the factory interface 404 of the etch tool 106. For example, the substrate cassette may be loaded into one of the loadports 420a-d of the factory interface 404.

In step 851, a substrate is extracted from the substrate cassette and in step 852, rather than employing the previously described stand-alone inspection systems, the substrate may be inspected via the integrated inspection system 422 of the etch tool 106 to determine one or more of defect density, etched feature dimensions/profile, whether all polymeric residue has been removed, etc., following cleaning within the cleaning tool 108. Assuming the etch tool 106 of FIG. 4A is employed within the system 100, steps 851 and 852 may be performed by employing the substrate handler 418 to extract a substrate from the substrate cassette (located within one of the loadports 420a-d), and by transferring the substrate to the metrology tool 424b via the substrate handler 418. Thereafter the metrology tool 424b may inspect the substrate's etched features (e.g., features 920d-e) and may communicate information about the etched features to the module controller 120. For example, the metrology tool 424b may communicate information such as etched feature density, size, profile or the like (following cleaning within the cleaning tool 108). Defect density or classification information may be similarly obtained via the defect detection tool 424a, and communicated to the module controller 120.

After information regarding the substrate has been communicated to the module controller 120 (in step 852), in step 853 the module controller 120 determines whether the substrate is acceptable. For example, the module controller 120 may determine that the etched features are too large or too small, that the substrate has too high of a defect density or was improperly cleaned, etc. If the substrate is not acceptable, the substrate is returned to the substrate cassette and marked as a defective substrate (step 854) and the process 800 returns to step 851; otherwise process 800 proceeds directly to step 855.

In step 855, the substrate is transferred from the factory interface 404 to one of the etch chambers 412a-d (e.g., via the substrate handler 408). In step 856, the module controller 120 determines an etch process to perform on the substrate within the appropriate etch chamber 412a-d in order to remove the first T2 low K dielectric layer 904 exposed by the etched features 920a-c (FIG. 9B). The etch process may be based on, for example, (1) information obtained about the first T2 low K dielectric layer 904 (e.g., feedforward information such as thickness, dielectric constant, uniformity, stress level, index of refraction, density, defect density, etc., of the first T2 low K dielectric layer 904 as provided by the integrated inspection system 330 of the low K dielectric deposition tool 102); (2) information such as the dimensions/profile of the etched features 920a-c and/or 920d-e as provided by the integrated inspection system 422 of the etch tool 106; or (3) based on other feedforward information (in a manner similar to that described with reference to step 822).

The etch process alternatively or additionally may be based on information obtained from the integrated inspection system 422 for a substrate previously etched within one of the etch chambers 412a-d (e.g., information such as etched feature dimensions/profile that resulted for a given etch process), in a manner similar to that described with reference to step 822.

In one exemplary embodiment, a CHF₃, O₂ and Ar etch chemistry (or another fluorine-based chemistry) may be employed to etch the first T2 low K dielectric layer 904. In such an etch process, the module controller 120 may, for example, based on the feedforward information (e.g., about the first T2 low K dielectric layer 904, the etched features 920a-c and/or 920d-e, etc.) and/or feedback information about a previously etched substrate (e.g., etch depth, etch profile, etc., of a previously etched low K dielectric layer) adjust etching of the first T2 low K dielectric layer 904 by adjusting CHF₃, O₂, Ar and/or other gas flow rates and/or ratios, chamber pressure, etch time, source power, substrate bias, etc., during etching. FIG. 10B(1) and FIG. 10B(2) illustrate exemplary process parameters of an etch process that may be adjusted based on feedforward and feedback information. Once an etch process has been determined, in step 857, the module controller 120 directs the etch tool 106 to etch the substrate based on the etch process.

FIG. 9H illustrates the substrate 902 following etching of the first T2 low K dielectric layer 904. As shown in FIG. 9H, following etching, copper plugs 918a, 918b and 918d are exposed.

In step 858, the substrate is transferred from one of the etch chambers 412a-d to the factory interface 404. In step 859 the substrate may be inspected via the integrated inspection system 422. For example, the substrate may be inspected via the defect detection tool 424a to determine the number of defects present on the surface of the substrate following etching and/or may be inspected within the metrology tool 424b to determine the dimensions, profile or other critical dimension information relevant to the features etched within the first T2 low K dielectric layer 904. Information regarding the substrate is communicated to the module controller 120.

In step 860 the module controller 120 determines whether the etched substrate is acceptable (e.g., if the defect level on the surface of the substrate is within an acceptable limit, if the features etched within the first T2 low K dielectric layer have acceptable depths, widths, profiles, etc.). If the etch substrate is not acceptable, in step 861, the module controller 120 marks (e.g., records that) the substrate is defective and the process 800 proceeds to step 862; otherwise following step 860, the process 800 proceeds directly to step 862.

In step 862, the module controller 120 determines if all non-defective substrates in the substrate cassette have been etched. If all non-defective substrates in the substrate cassette have not been etched, the process 800 returns to step 851 to obtain another substrate from the cassette to etch as described previously; otherwise the process 800 proceeds to step 863.

Following etching of all substrates within the substrate cassette, in step 863 the substrate cassette is transferred from the etch tool 106 to the cleaning tool 108 (e.g., via a technician, an automated guided vehicle, an overhead carrier system, etc.).

In step 864, the module controller 120 directs the cleaning tool 108 to clean each non-defective substrate within the substrate cassette using conventional cleaning techniques. For example, one or more wet cleaning techniques may be used that employ an appropriate solvent and/or other chemicals, Marangoni drying, megasonic cleaning, etc., whether done on a single substrate or on a batch of substrates. The cleaning tool 108 may be employed, for example, to remove any residual polymeric material that remains following etching of the first T2 dielectric layer (e.g., layer 904 in FIG. 9H).

In at least one embodiment of the invention, the etch and clean tool 106′ of FIG. 4B may be employed within the inventive system 100. When the etch and clean tool 106′ is employed, any cleaning step following etching (e.g., step 831, 849 and 864 in process 800) may be performed within the cleaning chamber 430 and/or 432, rather than within the cleaning tool 108. In this manner, fewer inter-tool transfer operations (e.g., steps 830, 832, 848, 850, 863 and/or 865) need be performed, thereby increasing system throughput.

In yet another embodiment of the invention, the first T2 low K dielectric layer 904 (exposed by etched features 920a-c) may be etched (opened) immediately after ashing, either within the same chamber used for ashing or within a separate etch chamber of the etch tool 106. In this manner, one or more of steps 850-864 of the process 800 may be eliminated. System throughput thereby may be increased.

Referring again to FIG. 8K, in step 865 the substrate cassette is transferred from the cleaning tool 108 to the anneal furnace 110. As stated, the anneal furnace 110 may be a Canary Furnace manufactured by Canary or any other suitable furnace. In step 866, each non-defective substrate within the substrate cassette is annealed. In at least one embodiment of the invention, the anneal process may comprise an approximately 30 minute argon anneal at 300° C., although another suitable anneal process may be employed (e.g., to degas and dry out the each substrate). In step 867, the substrate cassette is transferred from the annealing furnace to the barrier/seed layer deposition tool 112.

Prior to arrival at the barrier/seed layer deposition tool 112, one or more non-defective substrates within the substrate cassette may be inspected within a stand-alone or integrated metrology and/or defect detection tool (not shown) to determine one or more of defect density, etched feature dimensions/profile, whether all polymeric residue has been removed following cleaning within the cleaning tool 108, etc., as previously described.

In step 868, the substrate cassette is loaded into the factory interface 504 of the barrier/seed layer deposition tool 112. For example, the substrate cassette may be loaded into one of the loadports 522a-d of the factory interface 504.

In step 869, a substrate is extracted from the substrate cassette. Rather than employing the previously described stand-alone inspection systems, in step 870, etched features (e.g., vias and/or lines such as the etched features 920a-e) formed on the substrate by the etch tool 106 and used to define the regions on the substrate where interconnects are to be formed, may be inspected via the integrated inspection system 524 of the barrier/seed layer deposition tool 112. Assuming the barrier/seed layer deposition tool 112 of FIG. 5 is employed within the system 100, steps 869 and 870 may be performed by employing the substrate handler 520 to extract a substrate from the substrate cassette (located within one of the loadports 522a-d), and by transferring the substrate to the metrology tool 524b via the substrate handler 518. Thereafter the metrology tool 524b may inspect the substrate's etched features and may communicate information about the etched features to the module controller 120. For example, the metrology tool 524b may communicate information such as etched feature density, etched feature dimensions (e.g., via and/or line width, depth, profile, etc.) or the like to the module controller 120.

After information regarding the substrate's etched features has been communicated to the module controller 120 (in step 870), in step 871 the module controller 120 determines whether the etched features formed on the substrate are acceptable. For example, the module controller 120 may determine that etched features such as the etched features 920a-e are overpatterned (e.g., have dimensions that will result in interconnects that are too wide) or underpatterned (e.g., have dimensions that will result in interconnects that are too narrow). If the etched features on the substrate are not acceptable, the substrate is returned to the substrate cassette, the substrate is marked as a defective substrate (step 872) and the process 800 returns to step 869 to obtain another substrate; otherwise the process 800 proceeds directly to step 873.

In step 873 the substrate is transferred from the factory interface 504 to a degas chamber (e.g., one of the auxiliary chambers 516a-c) via the substrate handler 508a, and the substrate is degassed. Any suitable degas process may be employed such as a conventional heated wafer chuck or lamp heated degas process.

Once the substrate has been degassed, in step 874 the substrate is transferred to the preclean chamber 511 via the substrate handler 508a, the substrate handler 508b and the pass-through 526 (as previously described) and the substrate is precleaned. Any suitable preclean process may be employed such as a conventional preclean process (e.g., employing Ar, He, H₂ or N₂ sputtering) or a reactive preclean process (e.g., employing a fluorine based reactive species). If desired, the preclean process may be based on information regarding the etched features present on the substrate (e.g., information such as etched feature density, dimensions, profile, etc., measured by the metrology tool 524b of the barrier/seed layer deposition tool 112 or the etch tool 106). For example, sputter yield may be proportional to via size and aspect ratio, and dependent on the type of dielectric in which the via is formed. The preclean process may be adjusted to compensate for these and other factors.

Following precleaning, in step 875 the substrate is transferred to the barrier layer deposition chamber 512 via the substrate handler 508b. The module controller 120 determines a barrier layer deposition process to perform on the substrate within the barrier layer deposition chamber 512 based on the information obtained about the etched features formed on the substrate (e.g., etched feature density information, dimension information, profile information, or other feedforward information). It will be understood that the barrier layer deposition process may be determined based on etched feature information at any time after the information is received from the metrology tool 524b (or from another metrology tool).

The barrier layer deposition process alternatively or additionally may be based on (feedback) information obtained from the integrated inspection system 524 for a barrier layer previously deposited within the barrier layer deposition chamber 512 (e.g., information such as deposited barrier layer thickness for a given deposition process, defect density or the like).

The module controller 120 may determine a barrier layer deposition process (or any other process described herein) in any suitable manner. For example, the module controller 120 may store (e.g., in the data storage device 206) a library of barrier layer deposition processes each of which has been optimized for a particular etched feature density, etched feature dimension, etched feature profile, etc. Based on feedforward information about the etched features on which a barrier layer is to be deposited, and/or based on other feedforward information, the module controller 120 may determine a barrier layer deposition process by selecting the “most optimal” process from the library of stored barrier layer deposition processes. Based on actual etched feature density, dimensions, profile, or other feedforward information, the module controller 120 may adjust various process parameters of a selected barrier layer deposition process to better match the characteristics of the substrate.

Exemplary process parameters that may be adjusted for a barrier layer deposition process include RF bias, DC power, wafer bias, chamber base pressure, processing pressure, processing temperature, processing time, processing power, etc., which may affect one or more of sheet resistance (Rₛ), reflectivity, thickness, defect density and uniformity of the deposited barrier layer.

The module controller 120 may employ one or more algorithms (in addition to or in place of process libraries) for determining appropriate process parameters based on etched feature density, dimensions, profile, or other feedforward information. Likewise one or more process parameters may be adjusted based on feedback information regarding a barrier layer previously deposited on a substrate (e.g., if the previously deposited barrier layer is too thin, too thick, has too high of a defect density, or some other undesirable characteristic). FIG. 10C illustrates exemplary process parameters of a barrier layer deposition process that may be adjusted based on feedforward and feedback information. These process parameters may be adjusted alone or in combination when determining a barrier layer deposition process.

It will be understood that information regarding etched features present on a substrate may be used to affect other processing tools or subsystems such as the lithography tool and etch tool used to form the etched features (e.g., lithography tool 104 and etch tool 106 in FIGS. 1A and 1B). For example, the module controller 120 (or some other module controller) may adjust, based on feedback information about etched features formed by a given process, one or more parameters of the process to affect future etched feature formation. Adjustable process parameters of an etch tool used to etch features include, for example, etch time, etch rate, etch chemistry, etc., which may affect one or more of etched feature depth, critical dimension, uniformity, etc. Lithography dose of a lithographic process used to define etched features, as well as deposition time of a deposition process used to form an interlayer dielectric layer (in which etched features are formed) similarly may be adjusted based on etched feature feedback information.

Once a barrier layer deposition process has been determined, in step 876, the module controller 120 directs the barrier layer deposition chamber 512 to deposit a barrier layer on the substrate based on the process. FIG. 9I illustrates the silicon substrate 902 after a barrier layer 930 has been deposited thereon. In at least one embodiment, the barrier layer 930 comprises a 150-250 angstrom TaN layer or Ta/TaN stack. Exemplary barrier layer properties include a defect density of less than about thirty 0.16 micron particles per 200 mm wafer, a sheet resistance of about 80-87 ohms per square and a uniformity of about 6% or less. Other thicknesses/properties and other materials also may be employed.

In step 877, the substrate is transferred from the barrier layer deposition chamber 512 to the seed layer deposition chamber 514, and the module controller 120 determines a seed layer deposition process to perform on the substrate. The seed layer deposition process may be based on the information obtained about the etched features formed on the substrate (e.g., etched feature density information, dimension information, profile information, etc.), based on information obtained about the barrier layer deposited on the substrate (e.g., barrier layer thickness) or based on other feedforward information.

The seed layer deposition process alternatively or additionally may be based on information obtained from the integrated inspection system 524 for a seed layer previously deposited within the seed layer deposition chamber 514 (e.g., information such as deposited seed layer thickness for a given deposition process), or based on other feedback information.

As with the barrier layer deposition processes, the module controller 120 may store a library of seed layer deposition processes each of which has been optimized for a particular etched feature density, etched feature dimension, etched feature profile, etc. Based on feedforward information about the etched features on which a seed layer is to be deposited, the module controller 120 may determine a seed layer deposition process and/or vary process parameters accordingly. Likewise one or more process parameters may be adjusted based on feedback information regarding a seed layer previously deposited on a substrate (e.g., if the previously deposited seed layer was too thin, too thick, had too high of a defect density or some other desirable characteristics).

Exemplary process parameters that may be adjusted for a seed layer deposition process based on feedforward information (e.g., etched feature information) and/or feedback information (e.g., information about a previously deposited seed layer) include, for example, RF bias, DC power, wafer bias, chamber base pressure, processing pressure processing temperature, processing time, processing power, etc., which may affect one or more of sheet resistance (Rₛ), reflectivity, thickness, defect density and uniformity of a deposited seed layer. The above process parameters may be adjusted alone or in combination when determining a seed layer deposition process to perform. FIG. 10C summarizes these process parameters.

Once a seed layer deposition process has been determined, in step 878, the module controller 120 directs the seed layer deposition chamber 514 to deposit a seed layer on the substrate based on the process.

FIG. 9J illustrates the substrate 902 following deposition of a seed layer 932 (step 878) thereon. In at least one embodiment, the seed layer 932 comprises about 1000-2000 angstroms of copper, although other materials and other thicknesses may be employed. Other exemplary seed layer properties include a resistivity of about 0.12 ohms per square and a uniformity of about 10% or less. Other seed layer property values may be used.

In step 879, the substrate is transferred from the seed layer deposition chamber 514 to the factory interface 504, and the substrate is inspected via the integrated inspection system 524. For example, the substrate may be inspected via the defect detection tool 524a to determine the number of defects present on the surface of the substrate following seed layer deposition and/or may be inspected within the metrology tool 524b to determine the thickness and/or sheet resistance of the barrier layer and/or the seed layer deposited on the substrate. Information regarding the substrate then is communicated to the module controller 120.

In step 880 the module controller 120 determines whether the substrate is acceptable (e.g., if the defect density on the surface of the substrate is within an acceptable limit, if the barrier layer and/or the seed layer have an acceptable thickness, etc.). If the substrate is not acceptable, in step 881, the module controller 120 marks the substrate as defective and the process 800 proceeds to step 882; otherwise following step 880, the process 800 proceeds directly to step 882.

In step 882, the module controller 120 determines if all non-defective substrates in the substrate cassette have been processed. If all non-defective substrates in the substrate cassette have not been processed, the process 800 returns to step 869 to obtain another substrate from the cassette to process as described previously; otherwise the process 800 proceeds to step 883.

Following deposition of a barrier layer and a seed layer on all non-defective substrates within the substrate cassette, in step 883 the substrate cassette is transferred from the barrier/seed layer deposition tool 112 to the electroplating tool 114 (e.g., via a technician, an automated guided vehicle, an overhead carrier system, etc.). The substrate cassette then is loaded into the factory interface 604 of the electroplating tool 114. In step 884, a non-defective substrate is obtained from the substrate cassette (e.g., via the substrate handler 620 or 622) and, in step 885, the substrate is transferred to one of the electroplating chambers 612a-d (e.g., via the substrate handler 608 after being oriented with the orienter 624).

The module controller 120 determines an electroplating process to perform on the substrate based on information obtained from the integrated inspection system 524 of the barrier/seed layer deposition tool 112 (or another tool such as the etch tool 106) and/or based on information obtained from the integrated inspection system 628 or 630 of the electroplating tool 114 for a substrate previously processed within one of the electroplating chambers 612a-d. For example, when step 870 is performed on a substrate, module controller 120 receives information about the density/dimensions/profile of the etched features present on the substrate and stores this information (e.g., with the data storage device 206) for the substrate. Likewise, when step 879 is performed on a substrate (following deposition of a barrier layer and a seed layer on the substrate) as previously described, module controller 120 receives information about the barrier layer and/or seed layer formed on the substrate (e.g., barrier layer thickness, seed layer thickness, defect density, etc.) and stores this information for the substrate. During step 885, the module controller 120 may retrieve this information for the substrate to be processed, and based on the density/dimensions/profile of the etched features present on the substrate, the thickness of the barrier layer and seed layer deposited on the substrate, and/or other feedforward information, the module controller 120 may select the appropriate electroplating process to be performed on the substrate (e.g., a process that deposits a fill layer that adequately fills each etched feature of the substrate). Information about a previously processed substrate similarly may be employed to determine the fill layer process (e.g., information such as defect density, fill layer thickness, etc., for a previously processed substrate).

As with the barrier layer and seed layer deposition processes, the module controller 120 may store a library of electroplating processes each of which has been optimized for a particular etched feature density, etched feature dimension, etched feature profile, barrier layer thickness, barrier layer material, seed layer thickness, seed layer material, etc. Based on feedforward information about the etched features to be electroplated, the deposited barrier layer, the deposited seed layer, and/or the like, the module controller 120 may determine an electroplating process and/or vary process parameters of an electroplating process accordingly. Likewise, one or more process parameters of an electroplating process may be adjusted based on feedback information regarding a fill layer previously formed on a substrate (e.g., if the previously formed fill layer is too thick, too thin, has too high of a defect density or some other undesirable or non-optimized characteristic).

Exemplary process parameters that may be adjusted for an electroplating process based on feedforward information (e.g., etched feature information, barrier layer information, seed layer information, etc.) and/or feedback information (e.g., information about a previously formed fill layer) include, for example:
1. plating process parameters such as flow rate, Z-height (e.g., the distance between anode and substrate), substrate rotation rate, plating current, plating voltage, immersion rotation rate (e.g., the speed with which a substrate is rotated during plating), immersion voltage (e.g., the voltage applied while the substrate is being immersed in the bath), anode amp-hr, contact ring amp-hr, time, etc.;
2. electrolyte/bath process parameters such as bath temperature, chemical acidity, electrolyte/bath chemistry (e.g., organic polymer additive concentrations that affect corner rounding, reduce void formation during via filling and/or reduce delamination of plated material such as leveler, enhancer and/or suppressor concentrations, other additive concentrations, etc.), flow rate, etc.; and
3. anneal process parameters such as temperature uniformity across each substrate, gas flow rates, anneal pressure before, during or after annealing, anneal time, etc.
   The above process parameters may be adjusted alone or in combination when determining an electroplating process to perform, and may affect one or more of the following characteristics of the electroplated fill layer: thickness, sheet resistance (Rₛ), uniformity, reflectivity, fill properties, defect density, contamination on substrate backside, etc. FIG. 10D summarizes these process parameters.

Once an electroplating process has been determined, in step 885, in step 886 the module controller 120 directs the electroplating tool 114 (via one of the electroplating chambers 612a-d) to form a fill layer (e.g., copper) on the substrate (e.g., in accordance with the process determined in step 885). FIG. 9K illustrates the silicon substrate 902 following formation of a fill layer 934 thereon within one of the electroplating chambers 612a-d. In the exemplary embodiment of FIG. 9K, the fill layer 934 comprises approximately 1 micron of copper. The copper fill layer 934 may be formed by any known electroplating technique such as the interaction of a copper sulfide base solution with an H₂SO₄ solution. Other fill layer thicknesses and materials may be employed. Exemplary copper fill layer properties include a defect density of less than fifty 0.16 micron particles per 200 mm wafer, a resistivity of about 0.18-0.02 ohm-cm, a uniformity of about 3% and a reflectivity of greater than 100% when compared to bare silicon. Other property values may be employed.

In step 887, the substrate is transferred from the appropriate electroplating chamber 612a-d to the integrated bevel cleaner 614. The module controller 120 then directs the integrated bevel cleaner 614 to clean the edge of the substrate. In step 888, the substrate is transferred to the spin rinse dryer 616, and the module controller 120 directs the spin rinse dryer 616 to clean/rinse/dry the substrate.

In step 889, the substrate is transferred to one of the anneal chambers 627a, 627b (e.g., via the substrate handler 608 and one of the substrate handlers 620, 622). Assuming the substrate is transferred to the first anneal chamber 627a, the module controller 120 directs the anneal chamber 627a to anneal the substrate as previously described. Alternatively, substrates may be annealed in batch (e.g., within the annealing furnace 110). An exemplary annealing process may comprise an approximately 30 minute argon anneal at 350° C., although other annealing processes may be employed.

In step 890, the substrate is inspected by the integrated inspection system 628 of the factory interface 604 and is returned to the substrate cassette. For example, the defect detection tool 628a may analyze the surface of the fill layer to determine the defect density and/or to characterize or classify defects present on the surface of the fill layer. The metrology tool 628b also may determine the thickness of the electroplated fill layer and/or other material parameters (e.g., film density, film quality, etc., as is known in the art). The above information is communicated to the module controller 120.

In step 891, the module controller 120 determines whether the fill layer formed on the substrate is acceptable (e.g., has the proper thickness, the proper material characteristics, a low enough defect density, etc.). If the fill layer is not acceptable, in step 892 the substrate is marked as defective and the process 800 proceeds to step 893; otherwise the process 800 proceeds directly to step 893 from step 891.

In step 893, the module controller 120 determines if all non-defective substrates in the substrate cassette have been processed. If so, the process 800 proceeds to step 894; otherwise the process 800 returns to step 884 to obtain another non-defective substrate from the substrate cassette for processing within the electroplating tool 114 as previously described.

In step 894, the substrate cassette is transferred from the electroplating tool 114 to the planarization tool 116. In step 895, the substrate cassette is loaded into the factory interface 904 of the planarization tool 116 of FIG. 7A. The substrate cassette alternatively may be transferred to the planarization tool 116′ of FIG. 7B, wherein a process similar to that described below may be performed.

In step 896, a non-defective substrate is obtained from the substrate cassette, and, in step 897, the substrate is transferred to the load cup 716 of the polishing system 712 (e.g., via the substrate handler 724 and the robot 706 as previously described). The module controller 120 then determines a planarization process to perform within the planarization tool 116 based on information obtained from the integrated inspection system 628 or 630 of the electroplating tool 114 for the substrate and/or based on information obtained from the integrated inspection system 728 of the planarization tool 116 for a substrate previously processed within the planarization tool 116. For example, based on information previously received from the integrated inspection system 628 or 630 of the electroplating tool 114 for the substrate to be planarized, the module controller 120 may determine the actual thickness of the fill layer deposited on the substrate via the electroplating tool 114 and may determine an appropriate planarization process based thereon (e.g., an appropriate planarization time). Likewise, based on a planarization process previously performed within the planarization tool 116, the module controller 120 may determine a planarization process.

As with other processes described herein, the module controller 120 may store a library of planarization processes each of which has been optimized for a particular substrate condition (e.g., a particular fill layer thickness or material, a particular polish stop layer, etc.). Based on feedforward information about the fill layer formed on a substrate, other feedforward information, feedback information about a substrate previously processed within the planarization tool 116, or other feedback information, the module controller 120 may select one of the stored planarization processes and/or adjust the process parameters of a planarization process to achieve a desired planarization result.

Exemplary process parameters that may be adjusted for a planarization process include, for example, retaining ring pressure, membrane and/or inner tube pressure, head pressure, other parameters that affect polish uniformity, slurry or rinsing fluid flow rate, slurry type, slurry concentration, head velocity, substrate rotation rate, polish time, rinse time, various cleaning parameters such as scrub time, spin-rinse-dry time, megasonic cleaning time, etc. Adjusting one or more of these process parameters may affect one or more of polish rate, surface profile, surface uniformity, etc. The above process parameters may be adjusted alone or in combination when determining a planarization process to perform. FIG. 10E summarizes these process parameters.

Once a planarization process has been determined, in step 898, the module controller 120 directs the planarization tool 116 to planarize the substrate based on the process determined in step 897. The substrate also may be cleaned within the cleaning system 714 as previously described.

FIG. 9L illustrates the substrate 902 following planarization within the planarization tool 116. As shown in FIG. 9L, following planarization the barrier layer 930, the seed layer 932 and the fill layer 934 form a substantially smooth top surface (with copper features 934a-b). In at least one embodiment the barrier layer 930 is used as a polished stop layer. The barrier layer 930 thereafter may be removed to form the structure shown in FIG. 9L. In at least one embodiment, following polishing the substrate's top (polished) surface has less than about 700 angstroms of dishing in regions with copper, and less than about 500 angstroms of erosion in non-copper regions, has a defect density of less than about seventy-five 0.25 micron sized particles per 200 mm wafer, and has a uniformity variation that is less than about 3%. Other polished surface properties may be employed.

In step 899, the planarized substrate is transferred to the integrated inspection system 728 of the planarization tool 116, is inspected and is returned to the substrate cassette. For example, the substrate may be inspected within the defect detection tool 730a and/or the metrology tool 730b to determine such information as defect density, surface uniformity, etc., and this information may be communicated to the module controller 120.

In step 900, the module controller 120 determines if the planarized substrate is acceptable (e.g., has a low enough defect density, has sufficient surface smoothness/planarity, that all fill layer material to be removed has been removed, etc.). If the planarized substrate is not acceptable, the substrate is marked as defective in step 901 and the process 800 proceeds to step 902; otherwise if the planarized substrate is acceptable the process 800 proceeds directly to step 902.

In step 902 the module controller 120 determines if all non-defective substrates within the substrate cassette have been planarized. If so, the process 800 ends in step 903; otherwise the process 800 returns to step 896 to obtain another non-defective substrate from the substrate cassette and to planarize the substrate within the planarization tool 116 as described previously.

It will be understood that the process 800 is merely exemplary of one low K dielectric interconnect formation process that may be performed within the inventive system 100 of FIGS. 1A and 1B. Other low K dielectric interconnect formation processes also may be performed by the system 100. While in process 800 every substrate processed is inspected following low K dielectric deposition, etching, lithography, barrier/seed layer deposition, electroplating and planarization, it will be understood that fewer than every substrate may be inspected following these steps. Further, the material layers, material layer thicknesses and other material layer properties described herein are merely exemplary and other suitable materials and material layer properties may be similarly employed. Other process conditions may be employed than those described herein.

Numerous other process steps also may be employed such as (1) post CMP stand-alone substrate inspection to determine defect density, planarity, etc., such as via the SEM 7830SI critical dimension scanning electron microscope (CD-SEM) or the WF736 DUO defect detection system both manufactured by Applied Materials, Inc.; (2) post CMP annealing for degas purposes such as within the annealing furnace 110; (3) post CMP electrical testing (e.g., to determine device performance); and/or (4) post testing cleaning (e.g., within one or more conventional cleaning tools).

The EMC's 102a-116a and/or the APC modules 102b-116b may contain computer program code and/or data structures for performing one or more of the steps of process 800 rather than or in addition to the module controller 120. The program 208 also may contain computer program code and/or data structures for performing one or more of the steps of process 800.

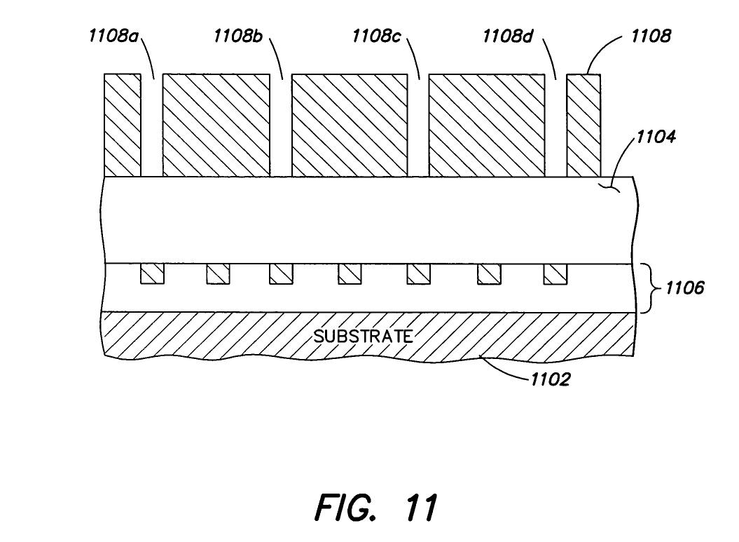

To further aid in understanding the operation of the invention system 100 of FIGS. 1A-B, several examples of the use of feedforward information to affect device fabrication are provided below with reference to FIGS. 11-14C. It will be understood that these are representative examples, and that other operations may be performed within the system 100. Each of these examples may be performed via one or more steps of the process 800 of FIGS. 8A-P or via one or more similar processes and may be implemented within one or more computer program products.

### EXAMPLE 1

FIG. 11 is a cross sectional view of a substrate 1102 having a T2 low K dielectric layer 1104 formed over a T1 structure 1106. A patterned masking layer 1108 having features 1108a-d is formed over the T2 low K dielectric layer 1104 so as to define etchable regions therein. For proper device fabrication, it is important not to under etch the T2 low K dielectric layer 1104 (e.g., so as to avoid forming an open circuit) or over etch the T2 low K dielectric layer 1104 (e.g., so as to avoid damaging any etch stop (not shown) disposed below the T2 low K dielectric layer 1104 and/or the T1 structure 1106).

In accordance with an aspect of the invention, following formation of the T2 low K dielectric layer 1104 within one or more of the low K dielectric deposition chambers 314a-318b of the low K dielectric deposition tool 102, the thickness of the T2 low K dielectric layer 1104 may be (1) measured by the integrated inspection system 330 of the low K dielectric deposition tool 102; and (2) fed forward to the etch tool 106 (e.g., via the module controller 120). This feedforward thickness information may be used by the etch tool 106 to control, among other things, etch time (e.g., to avoid over or under etching the T2 low K dielectric layer 1104).

During formation of line/trench features (e.g., features 920d-e in FIG. 9G) in the T2 low K dielectric layer 1104, an optical rate monitor such as an integrated rate monitor (iRM) manufactured by Applied Materials, Inc. or a similar device may be used to monitor etch depth within the T2 low K dielectric layer 1104. Because line/trench depth impacts sheet resistance, accurate control of line/trench depth is important during device fabrication. In accordance with the present invention, the integrated inspection system 330 of the low K dielectric deposition tool 102 may measure the index of refraction of the T2 low K dielectric layer 1104 and feedforward this information to the etch tool 106. Thereafter, during formation of line/trench features within the T2 low K dielectric layer 1104, the feedforward index of refraction information may be employed by an optical rate monitor associated with the etch tool 106 to achieve accurate depth control of the such features.

### EXAMPLE 2

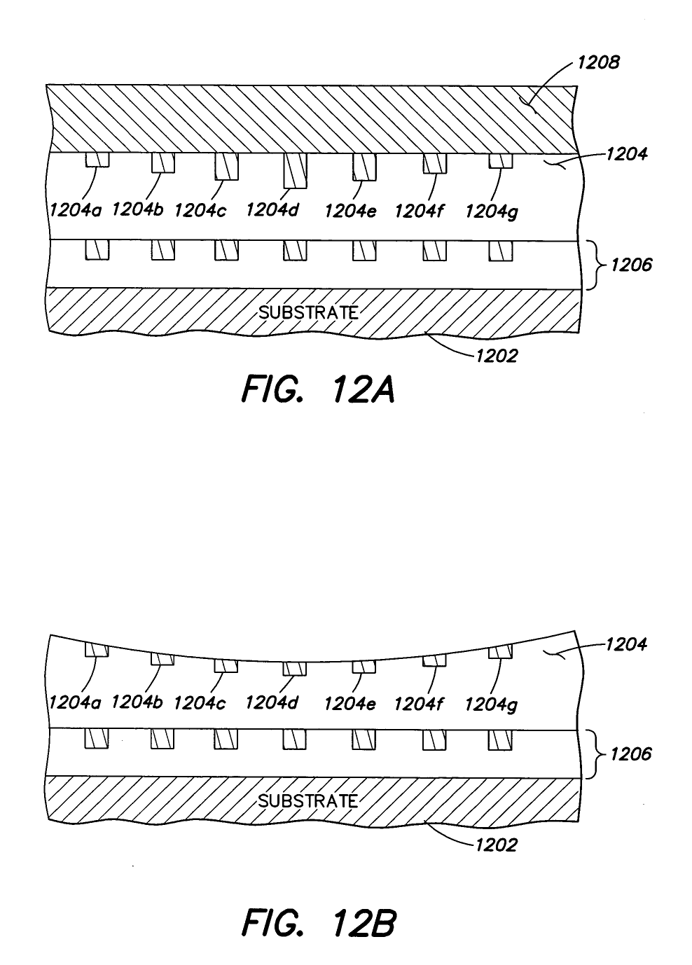

FIG. 12A is a cross sectional view of a substrate 1202 having a T2 low K dielectric layer 1204 formed over a T1 structure 1206. Trench features 1204a-g are formed within the T2 low K dielectric layer 1204 and are filled with a metal fill layer 1208. In the example of FIG. 12A, the trench depth across the substrate 1202 is non-uniform. That is, the trench depth is greater in the center of the substrate such that trenches 1204a and 1204g are the shallowest trenches and trench 1204d is the deepest trench (as shown).

In accordance with an aspect of the invention, following formation of the trenches 1204a-g in the T2 low K dielectric layer 1204 within one or more of the etch chambers 412a-d of the etch tool 106, the depth of the trenches 1204a-g may be (1) measured by the integrated inspection system 422 of the etch tool 106 or by another inspection system; and (2) fed forward to the planarization tool 116 (e.g., via the module controller 120). This feedforward information may be used by the planarization tool 116 to control, among other things, the amount of material removed from the center of the substrate 1202 relative to the edges of the substrate 1202 (e.g., by controlling carrier head pressure during polishing to remove more material from the center of the substrate 1202). A more uniform trench depth thereby may be achieved as shown in FIG. 12B.

### EXAMPLE 3

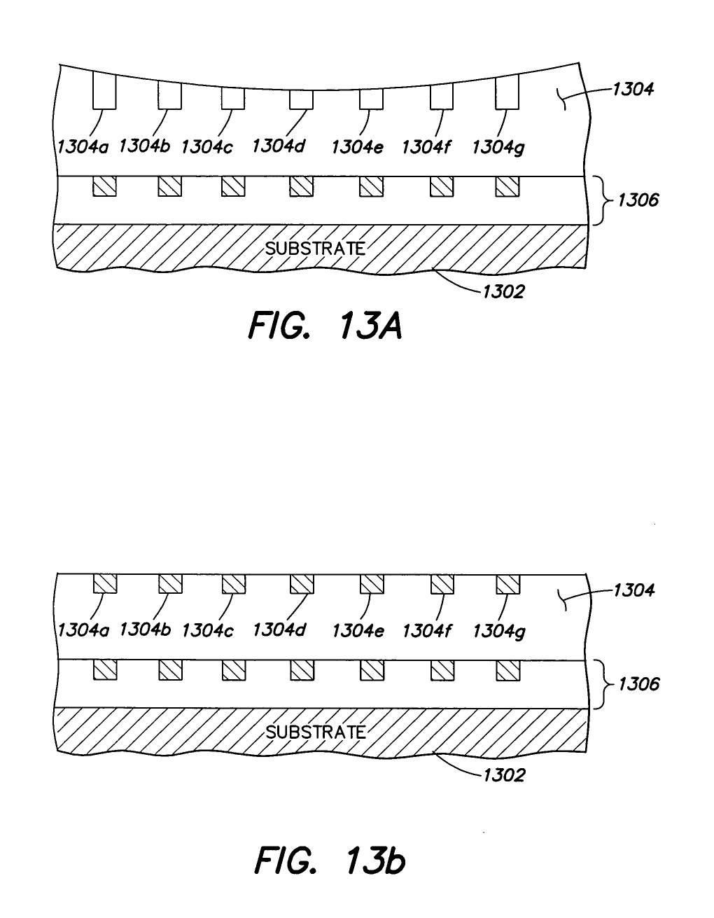

FIG. 13A is a cross sectional view of a substrate 1302 having a T2 low K dielectric layer 1304 formed over a T1 structure 1306. Trench features 1304a-g are formed within the T2 low K dielectric layer 1304. In the example of FIG. 13A, the T2 low K dielectric layer 1304 is non-uniform in thickness (e.g., is “edge thick”).

In accordance with an aspect of the invention, following formation of the T2 low K dielectric layer 1304 within one or more of the low K dielectric deposition chambers 314a-318b of the low K dielectric deposition tool 102, the thickness uniformity of the T2 low K dielectric layer 1304 may be (1) measured by the integrated inspection system 330 of the low K dielectric deposition tool 102; and (2) fed forward to the etch tool 106 (e.g., via the module controller 120). Based on this feedforward information, the etch tool 106 may control formation of the trenches 1304a-g so that the base of each trench has a similar height above the T1 structure 1306 (e.g., so that the trenches on the edge of the substrate 1302 are deeper than in the center of the substrate 1302 as shown). This may be performed, for example, by controlling (etch chamber magnetron) magnetic field strength which is known to change the etch rate ratio of the center of a substrate to the edge of the substrate (e.g., so as to increase the etch rate toward the edge of the substrate 1302). Following trench etching, the depth and/or depth uniformity of the trenches 1304a-g may be (1) measured by the integrated inspection system 422 of the etch tool 106 or by another inspection system; and (2) fed forward to the planarization tool 116 (e.g., via the module controller 120). This feedforward information may be used by the planarization tool 116 to control, among other things, the amount of material removed from the center of the substrate 1302 relative to the edges of the substrate 1302 (e.g., by controlling carrier head pressure during polishing to remove more material from the edges of the substrate 1302). A more uniform trench depth thereby may be achieved as shown in FIG. 13B.

### EXAMPLE 4

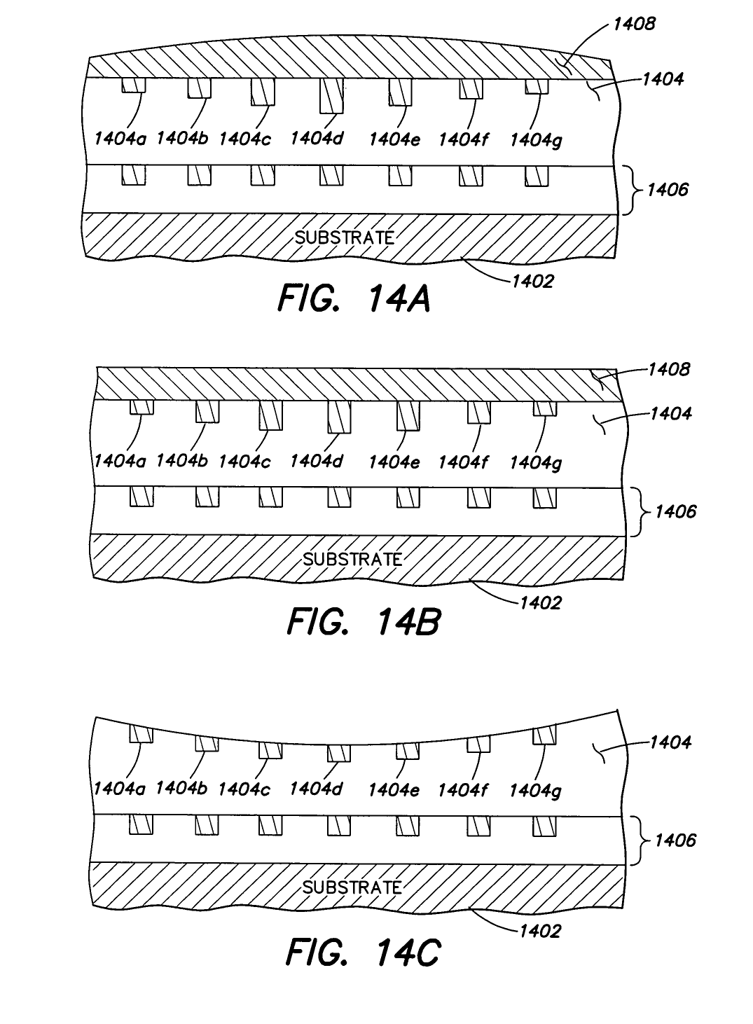

FIG. 14A is a cross sectional view of a substrate 1402 having a T2 low K dielectric layer 1404 formed over a T1 structure 1406. Trench features 1404a-g are formed within the T2 low K dielectric layer 1404 and are filled with a metal fill layer 1408. In the example of FIG. 14A, the trench depth across the substrate is non-uniform. That is, the trench depth is center deep such that trenches 1404a and 1404g are the shallowest trenches and trench 1404d is the deepest trench (as shown). The metal fill layer 1408 is center thick (as shown).

In accordance with an aspect of the invention, following formation of the trenches 1404a-g in the T2 low K dielectric layer 1404 within one or more of the etch chambers 412a-d of the etch tool 106, the depth uniformity of the trenches 1404a-g may be (1) measured by the integrated inspection system 422 of the etch tool 106 or by another inspection system; and (2) fed forward to the planarization tool 116 (e.g., via the module controller 120). Likewise, following formation of the metal fill layer 1408 within one or more of the electroplating chambers 612a-d of the electroplating tool 114, the thickness uniformity of the metal fill layer 1408 may be (1) measured by the integrated inspection system 628 or 630 of the electroplating tool 114; and (2) fed forward to the planarization tool 116 (e.g., via the module controller 120). During a first step of a planarization process, the planarization tool 116 may employ metal fill layer uniformity information to achieve a uniform metal fill layer such as is shown in FIG. 14B (e.g., by adjusting carrier head pressure to remove more metal from the center of the substrate 1402 than from its edges). During a second step of the planarization process, the planarization tool 116 may use trench depth uniformity information to control, among other things, the amount of the T2 low K dielectric layer 1404 removed from the center of the substrate 1402 relative to the edges of the substrate 1402 (e.g., by controlling carrier head pressure during polishing to remove more material from the center of the substrate 1402). A more uniform trench depth thereby may be achieved as shown in FIG. 14C. A similar process may be performed if an edge thick T2 low K dielectric layer (FIG. 13A) and a center thick metal fill layer (FIG. 14A) are deposited on a substrate. Other similar processes may be used to address any combination of center thick and/or center thin layers or trench depths.

The foregoing description discloses only exemplary embodiments of the invention. Modifications of the above disclosed apparatus and method which fall within the scope of the invention will be readily apparent to those of ordinary skill in the art. For instance, other processes than those described herein may be employed during low K dielectric layer, barrier layer, seed layer or fill layer formation, etching, lithography, cleaning, annealing and/or planarization. Other processing tools than those described herein may be similarly configured with integrated inspection systems. During substrate inspection, all or a portion of each substrate may be inspected (e.g., a pre-programmed or predetermined part of a wafer die, 5-10 wafer die, etc.). Separate tools for depositing barrier layers and seed layers may be employed. While FIGS. 10A-E illustrate exemplary process parameters that may be adjusted based on feedforward and feedback information, it will be understood that numerous other process parameters similarly may be adjusted. For example, if a defect density following a process is too high within a certain tool, the module controller 120 and/or one of the EMC's 102a-116a may perform a cleaning process within the tool, or direct an increase in the season time used following tool maintenance so as to reduce defect density.

The module controller 120 and/or the EMC's 102a-116a may be employed to monitor tool health. For example, a software diagnostic tool such as SmartSys™ which monitors equipment signals (e.g., signals from mass flow controllers, throttle valves, radio frequency sources, etc.) and analyzes such signals for drift may be used in conjunction with the module controllers 120, and/or 102a-116a by having the module controllers providing other process drift information to the software diagnostic tool, or by having the module controllers adjust process parameters to compensate for process drift (e.g., by increasing process time, flow rates, chamber pressure, etc.).

Accordingly, while the present invention has been disclosed in connection with exemplary embodiments thereof, it should be understood that other embodiments may fall within the spirit and scope of the invention, as defined by the following claims.

The invention claimed is:

1. A method comprising the steps of:
depositing a dielectric layer on a substrate;
forming both a first trench having a first trench depth and a second trench having a second trench depth in the dielectric layer, wherein the first trench depth is different from the second trench depth;
measuring the first trench depth and the second trench depth with an inspection system;
filling the first trench and the second trench using a fill layer;
planarizing the fill layer with a planarization tool, wherein the step of planarizing includes:
adjusting a pressure of a head of the planarization tool based upon the first trench depth and the second trench depth so that the head planarizes the dielectric layer such that the first trench depth and the second trench depth are approximately the same after the planarization.

2. The method of claim 1 wherein a module controller receives the first trench depth and the second trench depth from the inspection tool and causes the planarization tool to adjust the head pressure based on the first and second trench depths.

3. The method of claim 2 wherein the planarization tool receives the first trench depth and the second trench depth from the module controller.

4. The method of claim 1 wherein the planarization tool receives the first trench depth and the second trench depth from the inspection tool.

5. The method of claim 1 further comprising adjusting a deposition process on a subsequent substrate based on the first and second trench depths.

6. The method of claim 1 further comprising adjusting an etch step on a subsequent substrate based on the first and second trench depths.

7. A system configured to form a layer on a substrate, the system comprising:
a first deposition subsystem which deposits a dielectric layer on a surface of the substrate;
an etch subsystem configured to form a first trench having a first trench depth in the dielectric layer and a second trench having a second trench depth in the dielectric layer, wherein the first and second trench depths are different;
an inspection system configured to measure the first trench depth and the second trench depth;
a second deposition subsystem configured to deposit a fill layer on the substrate such that the first trench and the second trench are filled;
a planarization subsystem configured to adjust a pressure of a head of the planarization subsystem based on the first trench depth and the second trench depth such that the first trench depth and the second trench depth are approximately the same after planarization.

8. The system of claim 7 wherein the inspection system is coupled to the etch subsystem.

9. The system of claim 7 wherein the planarization subsystem is configured to receive the first trench depth and the second trench depth from the inspection system.

10. The system of claim 7 further comprising:
a module controller configured to receive the first trench depth and the second trench depth from the inspection system, wherein the module controller causes the planarization tool to adjust the head pressure based on the first and second trench depths.

11. The system of claim 10 wherein the module controller adjusts a deposition process within the first deposition subsystem for a subsequent-substrate based on the first and second trench depths.

12. The system of claim 10 wherein the module controller adjusts a deposition process within the second deposition subsystem for a subsequent substrate based on the first and second trench depths.

13. The system of claim 10 wherein the module controller adjusts an etch process within the etch subsystem for a subsequent substrate based on the first and second trench depths.
